(19) United States
(12) Patent Application Publication
(10) Pub. No.: US 2012/0222741 A1
(43) Pub. Date: Sep. 6, 2012

(54) SOLAR CELL WITH IMPROVED PERFORMANCE

(75) Inventors: Michael Davies, Ottawa (CA); Junegie Hong, Beaconsfield (CA); Genowefa Jakubowska-Okoniewski, Pierrefonds (CA); Sergiy Navala, Cote Saint-Luc (CA); Xiaoming Yang, Lachine (CA); Ajeet Rohatgi, Marietta, GA (US); Moon Hee Kang, Atlanta, GA (US); Abasifreke Udo Ebong, Marietta, GA (US); Brian Charles Rounsaville, Conyers, GA (US)

(73) Assignee: L'Air Liquide, Societe Anonyme pour I'Etude et I'Exploitation des Procedes Georges Claude, Paris (FR)

(21) Appl. No.: 13/496,708

(22) PCT Filed: Sep. 17, 2010
(86) PCT No.: PCT/CA10/01436

§ 371 Date: May 22, 2012

Related U.S. Application Data
(60) Provisional application No. 61/243,818, filed on Sep. 18, 2009.
(60) Provisional application No. 61/243,809, filed on Sep. 18, 2009.
(60) Provisional application No. 61/246,403, filed on Sep. 28, 2009.
(60) Provisional application No. 61/264,764, filed on Nov. 27, 2009.
(60) Provisional application No. 61/290,056, filed on Dec. 24, 2009.
(60) Provisional application No. 61/299,616, filed on Jan. 29, 2010.
(60) Provisional application No. 61/299,747, filed on Jan. 29, 2010.
(60) Provisional application No. 61/356,755, filed on Jun. 21, 2010.
(60) Provisional application No. 61/380,038, filed on Sep. 3, 2010.

(51) Int. Cl. H01L 31/0232; H01L 31/18

(52) U.S. Cl. 136/259; 438/72; 257/E31.127

(57) ABSTRACT

This application discloses silicon solar cells manifesting enhanced light induced degradation characteristics. The application also discloses silicon solar cells with a silicon-based substrate comprising boron, oxygen and carbon, and an antireflective coating (ARC) containing at least one carbon-containing layer adjacent to the substrate. Also disclosed are methods for preparing solar cells.

### CROSS-REFERENCE TO RELATED APPLICATIONS

This application claims the benefit of:

U.S. Provisional Patent application Ser. No. 61/243,818, entitled SOLAR CELL WITH IMPROVED PERFORMANCE, filed 2009 Sep. 18;
U.S. Provisional Patent application Ser. No. 61/243,809, entitled SOLAR CELL WITH SiCN FILM, filed 2009 Sep. 18;
U.S. Provisional Patent application Ser. No. 61/246,403, entitled SOLAR CELL WITH REDUCED LIGHT INDUCED DEGRADATION, filed 2009 Sep. 28;
U.S. Provisional Patent application Ser. No. 61/264,764, entitled SILICON SOLAR CELLS WITH IMPROVED LIGHT INDUCED DEGRADATION CHARACTERISTICS, filed 2009 Nov. 27;
U.S. Provisional Patent application Ser. No. 61/290,056, entitled SILICON SOLAR CELLS WITH IMPROVED LIGHT INDUCED DEGRADATION CHARACTERISTICS, filed 2009 Dec. 24;
U.S. Provisional Patent application Ser. No. 61/299,616, entitled SUPRESSION OF LIGHT INDUCED DEGRADATION (LID) IN B-DOPED CZ—SI SOLAR CELLS BY POLYMER, filed 2010 Jan. 29;
U.S. Provisional Patent application Ser. No. 61/299,747, entitled SUPRESSION OF LIGHT INDUCED DEGRADATION (LID) IN B-DOPED CZ—SI SOLAR CELLS BY POLYMER SICXNY FILM, filed 2010 Jan. 29;
U.S. Provisional Patent application Ser. No. 61/356,755, entitled SIMPLE AND COST-EFFECTIVE REDUCTION OF LIGHT INDUCED DEGRADATION IN B-DOPED Cz—Si SOLAR CELLS BY SILEXIUM® PECVD SiCN ANTIREFLECTIVE PASSIVATION COATINGS, filed 2010 Jun. 21; and
U.S. Provisional Patent application Ser. No. 61/380,038, entitled SIMPLE AND COST-EFFECTIVE REDUCTION OF LIGHT INDUCED DEGRADATION IN B-DOPED CZ—SI SOLAR CELLS BY SILEXIUM PECVD SICN ANTIREFLECTIVE PASSIVATION COATINGS, filed 2010 Sep. 3;
the contents of which are hereby incorporated by reference.

### FIELD OF THE INVENTION

This invention relates to silicon solar cells manifesting enhanced light induced degradation characteristics. The invention also relates to a silicon solar cell comprising a silicon-based substrate and an antireflective and passivation layer, the substrate comprising boron, oxygen and carbon, and to a method for its preparation.

### BRIEF SUMMARY OF THE INVENTION

According to one aspect of the present invention, there is provided a solar cell comprising a silicon substrate comprising boron, oxygen and carbon, and a frontside antireflective coating, the frontside antireflective coating comprising at least a silicon carbonitride layer adjacent to the substrate, the layer having a carbon concentration of from 1 to 10 at. %, an oxygen concentration of less than 3 at. %, and a hydrogen concentration greater than 14.5 at. %.

According to another aspect of the present invention, there is provided a solar cell comprising a silicon substrate comprising boron, oxygen and carbon, and a frontside antireflective coating, the frontside antireflective coating comprising at least a silicon carbonitride layer adjacent to the substrate, the layer having a carbon concentration greater than 1 at. %, an oxygen concentration of less than 3 at. %, a hydrogen concentration greater than 10 at. %, and a silicon concentration greater than 37 at. %.

According to a further aspect of the present invention, there is provided a solar cell comprising a silicon substrate comprising boron, oxygen and carbon, and a frontside antireflective coating, the frontside antireflective coating comprising at least a first layer adjacent to the substrate and a second layer located on the first layer opposite the substrate; the first layer comprising silicon carbonitride with a carbon concentration of less than 10 at. %; and the second layer comprising silicon nitride; or a silicon carbonitride with a carbon concentration which is lower than the carbon concentration in the first layer and/or a silicon concentration that is higher than a silicon concentration in the first layer.

According to yet another aspect of the present invention, there is provided a solar cell comprising a silicon substrate comprising boron, oxygen and carbon, and a frontside antireflective coating, the frontside antireflective coating comprising at least a first layer adjacent to the substrate and a second layer located on the first layer opposite the substrate; the first layer comprising silicon carbonitride, with a carbon concentration of less than 10 at. % and a hydrogen concentration of less than 14.5 at. %; and the second layer being a hydrogen-containing silicon-based film.

According to yet a further aspect of the present invention, there is provided a solar cell comprising a silicon substrate comprising boron, oxygen and carbon, and a frontside antireflective coating, the frontside antireflective coating comprising at least a first layer adjacent to the substrate and a second layer located on the first layer opposite the substrate; the first layer comprising silicon carbonitride with a carbon concentration of less than 10 at. %; and the second layer comprising silicon carbide, silicon carbonitride, silicon oxycarbide or silicon oxycarbonitride, the carbon concentration in the second layer being greater than the carbon concentration in the first layer.

According to another aspect of the present invention, there is provided a solar cell comprising a silicon substrate comprising boron, oxygen and carbon, and a frontside antireflective coating, the frontside antireflective coating comprising at least a silicon carbonitride layer adjacent to the substrate, the silicon carbonitride layer having a graded carbon concentration with an increasing carbon concentration with increasing distance from the emitter, the first layer having an average carbon concentration of less than 10 at. % within the first 30 nm adjacent to the substrate.

According to another aspect of the present invention, there is provided a solar cell comprising a silicon-based substrate comprising boron, oxygen and carbon, and one or more carbon-containing antireflective and passivation layers, the substrate having two major surfaces and the one or more antireflective and passivation layers being adjacent to one or both of the two major surfaces, and the concentration of carbon in the substrate being greater at the major surface adjacent to the antireflective and passivation layer than it is at a depth within the substrate equidistant from both major surfaces.

According to another aspect of the present invention, there is provided a method for reducing the light induced degradation of a solar cell that has a substrate, comprising providing on the substrate an antireflective coating (ARC) containing carbon and allowing carbon to diffuse from the ARC to the substrate.

According to another aspect of the present invention, there is provided a method for forming an antireflective coating for a solar cell, the method comprising a deposition of a gaseous precursor mixture comprising silane and an organosilane onto a solar cell substrate.

According to another aspect of the present invention, there is provided a method for preparing a silicon solar cell comprising a carbon-doped silicon substrate, the method comprising depositing on the silicon substrate an antireflective and passivation layer comprising silicon and carbon such that carbon diffuses from the layer into the substrate.

According to another aspect of the present invention, there is provided a solar cell having a silicon substrate comprising boron, oxygen and carbon, the solar cell manifesting a reduction from original Internal Quantum Efficiency (IQE), at any given wavelength between 400 and 1000 nm, of no greater than about 5% following illumination of the solar cell for 72 hours at about 1000 W/m².

According to another aspect of the present invention, there is provided a solar cell having a silicon substrate comprising boron, oxygen and carbon, the solar cell manifesting a reduction from original Internal Quantum Efficiency (IQE), at any given wavelength between 400 and 1000 nm, of no greater than about 2% following illumination of the solar cell for 72 hours at about 1000 W/m².

According to another aspect of the present invention, there is provided a solar cell having a silicon substrate comprising boron, oxygen and carbon, the solar cell manifesting a reduction from original Internal Quantum Efficiency (IQE), at any given wavelength between 400 and 900 nm, of no greater than about 2% following illumination of the solar cell for 72 hours at about 1000 W/m².

According to another aspect of the present invention, there is provided a solar cell having a silicon substrate comprising boron, oxygen and carbon, the solar cell manifesting substantially no reduction from original Internal Quantum Efficiency (IQE), at any given wavelength between 400 and 900 nm, following illumination of the solar cell for 72 hours at about 1000 W/m².

The above and other features and advantages of the present invention will become apparent from the following description when taken in conjunction with the accompanying figures which illustrate embodiments of the present invention by way of example.

### BRIEF DESCRIPTION OF THE DRAWINGS

Embodiments of the invention will be discussed with reference to the following Figures:

FIGS. 1a to 1g display the Voc, Jsc, Fill Factor, Rs, ideality factor, and efficiency measured for SiCxNy and SiNx solar cells after varying durations of illumination.

FIG. 2a graphs the measured efficiency of SiCxNy and SiNx solar cells on 0.9 Ω·cm silicon substrates after varying durations of illumination.

FIG. 2b graphs the spectral response of SiCxNy and SiNx solar cells on 0.9 Ω·cm silicon substrates pre- and post-illumination.

FIG. 3a graphs the measured efficiency of SiCxNy and SiNx solar cells on 2 Ω·cm silicon substrates after varying durations of illumination.

FIG. 3b graphs the spectral response of SiCxNy and SiNx solar cells on 2 Ω·cm silicon substrates pre- and post-illumination.

FIGS. 4a and 4b graph the pre- and post-illumination internal quantum efficiency (IQE) of SiCxNy and SiNx solar cells.

FIG. 5 graphs the pre- and post-illumination internal quantum efficiency (IQE) of SiCxNy and SiNx solar cells with a substrate having 1 Ohm·cm bulk resistance, 72 Ohm/sq emitter, and 26.8 ppm oxygen.

FIG. 6 graphs the pre- and post-illumination internal quantum efficiency (IQE) of SiCxNy and SiNx solar cells with a substrate having 3 Ohm·cm bulk resistance, 53 Ohm/sq emitter, and 24.2 ppm oxygen.

FIG. 7 graphs the pre- and post-illumination internal quantum efficiency (IQE) of SiCxNy and SiNx solar cells with a substrate having 5 Ohm·cm bulk resistance, 73 Ohm/sq emitter, and 17.3 ppm oxygen.

FIG. 8 graphs the pre- and post-illumination internal quantum efficiency (IQE) of SiCxNy and SiNx solar cells with a substrate having 0.96 Ohm·cm bulk resistance and a 65 Ohm/sq emitter

FIG. 9 graphs the pre- and post-illumination internal quantum efficiency (IQE) of SiCxNy and SiNx solar cells with a substrate having 3 Ohm·cm bulk resistance and a 60 Ohm/sq emitter.

FIG. 10 displays a FTIR spectrum of a SiCN film deposited on a substrate with a 3MS precursor.

FIG. 11 graphs the pre- and post-illumination internal quantum efficiency (IQE) of SiCxNy and SiNx solar cells with a substrate having 2 Ohm·cm bulk resistance.

FIG. 12 graphs the variation in bulk lifetime of SiCN coated and SiN coated Cz wafers after emitter formation, after a 1^{st} illumination or a resulting solar cell, after a first heating of the cell, after a 2^{nd} illumination of the cell, and after a second heating of the cell.

FIGS. 13a and 13b display the SIMS measurements for SiCxNy and SiNx layers on a silicon substrate.

FIG. 14 displays the estimated carbon content within the SiCxNy and SiNx layers and the silicon substrate on which they are deposited.

FIG. 15 displays the relative efficiency loss of SiCxNy solar cells prepared on different substrates, with respect to the loss observed for SiNx solar cells, following illumination of the cells.

FIG. 6 plots the density and refractive index of various SiCxNy and SiNx films obtained with different processes.

FIG. 17 graphs the absolute change in efficiency after the illumination for SiN and SiCN solar cells on different silicon substrates.

FIG. 18 plots the absolute loss of Voc (median values) after illumination for SiN and SiCN solar cells on different silicon substrates.

FIG. 19 plots the absolute loss of Voc (all values) after illumination for SiN and SiCN solar cells on different silicon substrates.

FIG. 20 plots the Jsc and Voc of SiCxNy and SiNx solar cells prepared with different deposition apparatus.

FIGS. 21a-21d display the surfaces of SiCxNy and SiNx films prepared with different deposition apparatus.

FIGS. 22a-22f display the variation in Voc, Jsc, FF, Efficiency, R series and Rshunt for solar cells with a SiCxNy ARC prepared from trimethylsilane, and for solar cells with a SiNx ARC, after varying durations of illumination.

FIG. 23 graphs the relationship between carbon concentration and hydrogen concentration in SiCN films prepared from organosilicon precursors.

FIG. 24 graphs the relationship between refractive index of SiN and SiCN films and the ratio of silane to methane found in the gaseous precursors used in their preparation.

FIG. 25 graphs the relationship between effective lifetime solar cells with SiN and SiCN antireflective coatings and the ratio of silane to methane found in the gaseous precursors used in their preparation.

FIG. 26 plots the loss of Voc after illumination for SiN solar cells, SiCN solar cells prepared from organosilanes and SiCN solar cells prepared from silane and methane (SiCN*).

FIG. 27 plots the loss of efficiency after illumination for SiN solar cells, SiCN solar cells prepared from organosilanes and SiCN solar cells prepared from silane and methane (SiCN*).

FIGS. 28a-d respectively plot the efficiency, Voc, Jsc, and FF of solar cells prepared with single layer antireflective coatings prepared from tetramethylsilane or from silane, and of solar cells prepared with a double layered antireflective coating prepared from tetramethylsilane and PDMS.

FIGS. 29a-d respectively plot the efficiency, Voc, Jsc, and FF of solar cells prepared with single layer antireflective coatings prepared from tetramethylsilane, from PDMS, or from silane, and of solar cells prepared with a double layered antireflective coating prepared from tetramethylsilane and PDMS.

FIG. 29e provides a comparison of the Joe measurements of solar cells having an antireflective coating prepared from silane or from tetramethylsilane, both prior to and after a firing process.

FIGS. 30a-d respectively plot the efficiency, Voc, Jsc, and FF of solar cells prepared with single layer antireflective coatings prepared from tetramethylsilane, PDMS, from silane, or from a mixture of silane and tetramethylsilane, and of solar cells prepared with a double layered antireflective coating prepared from tetramethylsilane and PDMS.

FIG. 31a-f respectively plot the efficiency, Voc, Jsc, FF, Rseries and Rshunt of solar cells prepared with single layer antireflective coating prepared from silane, and of solar cells prepared with a double layered antireflective coating prepared from tetramethylsilane and PDMS.

FIG. 32 graphs the refractive index and extinction coefficient of solar cells prepared with a single layer antireflective coating prepared from silane, and of solar cells prepared with double layer antireflective coatings prepared from tetramethylsilane (layer 1) and silane (layer 2), tetramethylsilane/methane (layer 1) and silane (layer 2), or silane (layer 1) and tetramethylsilane (layer 2).

FIG. 33a-c respectively plot the Voc, Jsc and efficiency of solar cells, prepared on different silicon substrates, comprising a single layer antireflective coating prepared from silane, or a double layer antireflective coating prepared from tetramethylsilane (layer 1) and silane (layer 2), tetramethylsilane/methane (layer 1) and silane (layer 2), or silane (layer 1) and tetramethylsilane (layer 2).

FIGS. 34a-d plot the Voc, Jsc, Efficiency, and Fill Factor measurements, during illumination, of solar cells prepared on the SC30 silicon substrate with a single layer antireflective coating prepared from silane, or a double layer antireflective coating prepared from tetramethylsilane (layer 1) and silane (layer 2), tetramethylsilane/methane (layer 1) and silane (layer 2), or silane (layer 1) and tetramethylsilane (layer 2).

FIG. 35 plot the Voc, Jsc, and Efficiency, during illumination, of solar cells prepared on the SC40 silicon substrate with a single layer antireflective coating prepared from silane, or a double layer antireflective coating prepared from tetramethylsilane (layer 1) and silane (layer 2), tetramethylsilane/methane (layer 1) and silane (layer 2), or silane (layer 1) and tetramethylsilane (layer 2).

FIG. 36 plots the relationship between carbon concentration and refractive index for antireflective layers prepared from tetramethylsilane (4MS), silane (SiN) or a mixture of tetramethylsilane and silane (hybrid).

FIG. 37 plots the relationship between carbon concentration, hydrogen concentration and refractive index for antireflective layers prepared from tetramethylsilane (4MS), silane (SiN) or a mixture of tetramethylsilane and silane (hybrid).

FIG. 38 plots the relationship between carbon concentration and hydrogen concentration for antireflective layers prepared from tetramethylsilane (4MS), silane (SiN) or a mixture of tetramethylsilane and silane (hybrid).

FIG. 39 graphs the Dark I-V characteristics of SiCxNy and SiNx solar cells.

FIGS. 40a-40d display cross-sectional SEM pictures of Ag contacts formed on solar cells with SiCxNy and antireflective coatings.

FIG. 41 graphs the firing profile for the formation of an Ohmic contact on a solar cell.

### DETAILED DESCRIPTION OF THE INVENTION

Various embodiments of the invention are listed below:

1. A solar cell having a silicon substrate comprising boron, oxygen and carbon, the solar cell manifesting a reduction from original Internal Quantum Efficiency (IQE), at any given wavelength between 400 and 1000 nm, of no greater than about 5% following illumination of the solar cell for 72 hours at about 1000 W/m².

2. A solar cell having a silicon substrate comprising boron, oxygen and carbon, the solar cell manifesting a reduction from original Internal Quantum Efficiency (IQE), at any given wavelength between 400 and 1000 nm, of no greater than about 2% following illumination of the solar cell for 72 hours at about 1000 W/m².

3. A solar cell having a silicon substrate comprising boron, oxygen and carbon, the solar cell manifesting a reduction from original Internal Quantum Efficiency (IQE), at any given wavelength between 400 and 900 nm, of no greater than about 2% following illumination of the solar cell for 72 hours at about 1000 W/m².

4. A solar cell having a silicon substrate comprising boron, oxygen and carbon, the solar cell manifesting substantially no reduction from original Internal Quantum Efficiency (IQE), at any given wavelength between 400 and 900 nm, following illumination of the solar cell for 72 hours at about 1000 W/m².

5. The solar cell according to any one of embodiments 1 to 4, wherein the concentration of boron and the concentration of oxygen are such that in the absence of carbon, boron-oxygen complexes would be formed in the substrate following illumination of the solar cell at about 1000 W/m².

6. The solar cell according to embodiment 5, wherein the boron concentration is about 1×10¹⁵ atoms/cm³ or greater.

7. The solar cell according to embodiment 5, wherein the boron concentration is about 1×10¹⁶ or greater.

8. The solar cell according to embodiment 5, wherein the boron concentration is about 1×10¹⁷ or greater.

9. The solar cell according to embodiment 5, wherein the boron concentration is about 2.5×10¹⁷ or greater.

10. The solar cell according to any one of embodiments 5 to 9, wherein the amount of mobile carbon is sufficient to substantially reduce the formation of boron-oxygen complexes in the substrate following illumination of the solar cell.

11. The solar cell according to any one of embodiments 5 to 9, wherein the amount of mobile carbon is sufficient to reduce the formation of boron-oxygen complexes by 50% or more in the substrate following illumination of the solar cell, based on the amount of complexes that would be formed in the absence of carbon.

12. The solar cell according to any one of embodiments 5 to 9, wherein the amount of mobile carbon is sufficient to reduce the formation of boron-oxygen complexes by 60% or more in the substrate following illumination of the solar cell, based on the amount of complexes that would be formed in the absence of carbon.

13. The solar cell according to any one of embodiments 5 to 9, wherein the amount of mobile carbon is sufficient to reduce the formation of boron-oxygen complexes by 75% or more in the substrate following illumination of the solar cell, based on the amount of complexes that would be formed in the absence of carbon.

14. The solar cell according to any one of embodiments 5 to 9, wherein the amount of mobile carbon is sufficient to substantially eliminate the formation of boron-oxygen complexes in the substrate following illumination of the solar cell.

15. The solar cell according to any one of embodiments 1 to 9, wherein the concentration of mobile carbon in the substrate is substantially equal to, or greater than, half the concentration of boron in substrate

16. The solar cell according to any one of embodiments 1 to 9, wherein the concentration of mobile carbon in the substrate is substantially equal to, or greater than, the concentration of boron in substrate.

17. The solar cell according to any one of embodiments 1 to 9, wherein the concentration of carbon in the substrate is 5×10¹⁵ atoms/cm³ or greater.

18. The solar cell according to any one of embodiments 1 to 9, wherein the concentration of carbon in the substrate is 5×10¹⁸ atoms/cm³ or greater.

19. The solar cell according to any one of embodiments 1 to 9, wherein the concentration of carbon in the substrate is 1×10¹⁷ atoms/cm³ or greater.

20. The solar cell according to any one of embodiments 1 to 9, wherein the concentration of carbon in the substrate is 1×10¹⁸ atoms/cm³ or greater.

21. The solar cell according any one of embodiments 1 to 9, wherein the substrate has two major surfaces, and wherein the concentration of carbon varies with increasing depth within the substrate.

22. The solar cell according to any one of embodiments 1 to 9, wherein the substrate has two major surfaces, and wherein the concentration of carbon decreases with increasing depth within the substrate from at least one of the major surfaces.

23. The solar cell according to embodiment 21 or 22, wherein the concentration of carbon in the substrate progressively decreases, for at least the first 50 nm, with increasing depth within the substrate away from at least one of the major surfaces.

24. The solar cell according to embodiment 21, wherein the carbon concentration in the substrate at one or both of the two major surfaces 1×10¹⁸ atoms/cm³ or greater.

25. The solar cell according to embodiment 21 or 22, wherein the carbon concentration in the substrate at one or both of the two major surfaces is 1×10¹⁹ atoms/cm³ or greater.

26. The solar cell according to embodiment 21 or 22, wherein the carbon concentration in the substrate at one or both of the two major surfaces 1×10²⁰ atoms/cm³ or greater.

27. The solar cell according to any one of embodiments 21 to 26, wherein the carbon concentration in the substrate is greater than 5×10¹⁶ atoms/cm³ at a depth of 300 nm from at least one of the two major surfaces.

28. The solar cell according to any one of embodiments 21 to 26, wherein the carbon concentration is greater than 5×10¹⁶ atoms/cm³ at a depth of 200 nm from at least one of the two major surfaces.

29. The solar cell according to any one of embodiments 21 to 26, wherein the carbon concentration is greater than 5×10¹⁶ atoms/cm³ at a depth of 60 nm from at least one of the two major surfaces.

30. The solar cell according to any one of embodiments 1 to 29, which further comprises an antireflective and passivation layer comprising silicon carbonitride.

31. The solar cell according to embodiment 30, wherein the silicon carbonitride comprises from 0.5 to 15% carbon.

32. The solar cell according to embodiment 30, wherein the silicon carbonitride comprises from 5 to 10% carbon.

33. The solar cell according to embodiment 30, wherein the silicon carbonitride comprises from 6 to 8% carbon.

34. The solar cell according to embodiment 30, wherein the antireflective and passivation layer comprises at least a first silicon carbonitride layer and a second silicon carbonitride layer,
the first silicon carbonitride layer being adjacent to the substrate and having a carbon concentration of less than 10 at % carbon, and
the second silicon carbonitride layer being on top of the first carbonitride layer and having a carbon concentration which is greater than the carbon concentration than the first silicon carbonitride layer.

35. The solar cell according to embodiment 34, wherein the first layer has a thickness less than about 100 nm, for example a thickness of less than about 30 nm, and/or the second layer has a thickness of from about 10 nm to about 100 nm, for example a thickness of about 50 nm.

36. The solar cell according to embodiment 34 or 35, wherein the first silicon carbonitride layer is deposited by PECVD of trimethylsilane or tetramethylsilane.

37. The solar cell according to any one of embodiments 1 to 36, wherein the substrate is free of damage.

38. The solar cell according to any one of embodiments 1 to 36, wherein the substrate is free of ion implantation damage.

39. The solar cell according to any one of embodiments 1 to 38, wherein the substrate has been prepared by a Czochralski process.

40. The solar cell according to any one of embodiments 1 to 38, wherein the substrate is a multicrystalline silicon substrate.

41, The solar cell according to any one of embodiments 1 to 38, wherein the substrate is an upgraded metallurgical grade silicon substrate.

42. The solar cell according to any one of embodiments 1 to 41, wherein the substrate has a bulk resistivity of from 2 to 6 Ω·cm.

43. The solar cell according to any one of embodiments 1 to 41, wherein the substrate has a bulk resistivity of less than 2 Ω·cm.

44. The solar cell according to any one of embodiments 1 to 41, wherein the substrate has a bulk resistivity of less than about 1.5 Ω·cm.

45. The solar cell according to any one of embodiments 1 to 41, wherein the substrate has a bulk resistivity of about 1 Ω·cm.

46. The solar cell according to any one of embodiments 1 to 41, wherein the substrate has a bulk resistivity between about 0.1 to about 1 Ω·cm.

47. The solar cell according to any one of embodiments 30 to 46, wherein the antireflective and passivation layer has a density greater than 2.4 g/cm.

48. The solar cell according to embodiment 47, wherein the antireflective and passivation layer has a density greater than 2.8 g/cm³.

49. The solar cell according to embodiment 47, wherein the antireflective and passivation layer has a density from 2.4 to 3.0 g/cm³.

50. A solar cell comprising
a silicon-based substrate comprising boron, oxygen and carbon, and
one or more carbon-containing antireflective and passivation layers,
   the substrate having two major surfaces and the one or more antireflective and passivation layers being adjacent to one or both of the two major surfaces, and the concentration of carbon in the substrate being greater at the major surface adjacent to the antireflective and passivation layer than it is at a depth within the substrate equidistant from both major surfaces.

51. The solar cell according to embodiment 50, wherein the concentration of carbon in the antireflective and passivation layer at a predetermined distance from a boundary between the antireflective and passivation layer and the substrate is equal to or exceeds the concentration of carbon in the substrate at the same distance from the boundary and wherein the concentration of carbon in the substrate progressively diminishes with increasing depth from the boundary.

52. The solar cell according to embodiment 50 or 51, wherein the concentration of carbon in the substrate progressively decreases, for at least the first 50 nm, with increasing depth within the substrate away from the major surface adjacent to the antireflective and passivation layer.

53. The solar cell according to any one of embodiments 50 to 52, wherein the concentration of boron and the concentration of oxygen are such that in the absence of carbon, boron-oxygen complexes would be formed in the substrate following illumination of the solar cell at about 1000 W/m².

54. The solar cell according to embodiment 53, wherein the boron concentration is about 1×10¹⁵ atoms/cm³ or greater.

55. The solar cell according to embodiment 53, wherein the boron concentration is about 1×10¹⁶ atoms/cm³ or greater.

56. The solar cell according to embodiment 53, wherein the boron concentration is about 1×10¹⁷ atoms/cm³ or greater.

57. The solar cell according to embodiment 53, wherein the boron concentration is about 2.5×10¹⁷ atoms/cm³ or greater.

58. The solar cell according to any one of embodiments 53 to 57, wherein the amount of mobile carbon is sufficient to reduce the formation of boron-oxygen complexes in the substrate following the illumination of the solar cell.

59. The solar cell according to any one of embodiments 53 to 57, wherein the amount of mobile carbon is sufficient to reduce the formation of boron-oxygen complexes by 50% or more in the substrate following illumination of the solar cell, based on the amount of complexes that would be formed in the absence of carbon.

60. The solar cell according to any one of embodiments 53 to 57, wherein the amount of mobile carbon is sufficient to reduce the formation of boron-oxygen complexes by 60% or more in the substrate following illumination of the solar cell, based on the amount of complexes that would be formed in the absence of carbon.

61. The solar cell according to any one of embodiments 53 to 57, wherein the amount of mobile carbon is sufficient to reduce the formation of boron-oxygen complexes by 75% or more in the substrate following illumination of the solar cell, based on the amount of complexes that would be formed in the absence of carbon.

62. The solar cell according to any one of embodiments 53 to 57, wherein the amount of mobile carbon is sufficient to substantially eliminate the formation of boron-oxygen complexes in the substrate following the illumination of the solar cell.

63. The solar cell according to any one of embodiments 50 to 62, wherein the concentration of mobile carbon in the substrate, at a depth of 50 nm, is substantially equal to, or greater than, the concentration of boron in substrate.

64. The solar cell according to any one of embodiments 50 to 63, wherein the concentration of carbon in the substrate at a depth of 30 nm is 5×10¹⁷ atoms/cm³ or greater.

65. The solar cell according to any one of embodiments 50 to 63, wherein the concentration of carbon in the substrate at a depth of 30 nm is 1×10¹⁸ atoms/cm³ or greater.

66. The solar cell according to any one of embodiments 50 to 65, wherein the carbon concentration in the substrate, adjacent to the antireflective and passivation layer, is 1×10¹⁸ atoms/cm³ or greater.

67. The solar cell according to any one of embodiments 50 to 65, wherein the carbon concentration in the substrate, adjacent to the antireflective and passivation layer, is 1×10¹⁹ atoms/cm³ or greater.

68. The solar cell according to any one of embodiments 50 to 65, wherein the carbon concentration in the substrate, adjacent to the antireflective and passivation layer, is 1×10²⁹ atoms/cm³ or greater.

69. The solar cell according to any one of embodiments 50 to 68, wherein the substrate is free of damage.

70. The solar cell according to any one of embodiments 50 to 68, wherein the substrate is free of ion implantation damage.

71. The solar cell according to any one of embodiments 50 to 70, wherein the substrate has been prepared by a Czochralski process.

72. The solar cell according to any one of embodiments 50 to 70, wherein the substrate is a multicrystalline silicon substrate.

73. The solar cell according to any one of embodiments 50 to 70, wherein the substrate is an upgraded metallurgical grade silicon substrate.

74. The solar cell according to any one of embodiments 50 to 73, wherein the substrate has a bulk resistivity of from 2 to 6 Ω·cm.

75. The solar cell according to any one of embodiments 50 to 73, wherein the substrate has a bulk resistivity of less than 2 Ω·cm.

76. The solar cell according to any one of embodiments 50 to 73, wherein the substrate has a bulk resistivity of less than about 1.5 Ω·cm.

77. The solar cell according to any one of embodiments 50 to 73, wherein the substrate has a bulk resistivity of about 1 Ω·cm.

78. The solar cell according to any one of embodiments 50 to 73, wherein the substrate has a bulk resistivity between about 0.1 to about 1 Ω·cm.

79. The solar cell according to any one of embodiments 50 to 78, wherein the silicon carbonitride comprises from 0.5 to 15% carbon.

80. The solar cell according to any one of embodiments 50 to 78, wherein the silicon carbonitride comprises from 5 to 10% carbon.

81. The solar cell according to any one of embodiments 50 to 78, wherein the silicon carbonitride comprises from 6 to 8% carbon.

82. The solar cell according to any one of embodiments 50 to 78, wherein the antireflective and passivation layer comprises at least a first silicon carbonitride layer and a second silicon carbonitride layer,
the first silicon carbonitride layer being adjacent to the substrate and having a carbon concentration of less than 10 at % carbon, and
the second silicon carbonitride layer being on top of the first carbonitride layer and having a carbon concentration which is greater than the carbon concentration than the first silicon carbonitride layer.

83. The solar cell according to embodiment 82, wherein the first layer has a thickness less than about 100 nm, for example a thickness of less than about 30 nm, and/or the second layer has a thickness of from about 10 nm to about 100 nm, for example a thickness of about 50 nm.

84. The solar cell according to embodiment 82 or 83, wherein the first silicon carbonitride layer is deposited by PECVD of trimethylsilane or tetramethylsilane.

85. The solar cell according to any one of embodiments 50 to 84, wherein the antireflective and passivation layer has a density greater than 2.4 g/cm.

86. The solar cell according to embodiment 85, wherein the antireflective and passivation layer has a density greater than 2.8 g/cm³.

87. The solar cell according to embodiment 85, wherein the antireflective and passivation layer has a density from 2.4 to 3.0 g/cm³.

88. The solar cell according to any one of embodiments 50 to 87, which comprises one or more metal contacts from a paste having an effective firing temperature between about 450° C. and about 850° C., for example between about 525° C. and about 725° C.

89. A method for preparing a silicon solar cell comprising a carbon-doped silicon substrate, the method comprising depositing on the silicon substrate an antireflective and passivation layer comprising silicon and carbon such that carbon diffuses from the layer into the substrate.

90. The method according to embodiment 89, wherein the antireflective and passivation layer further comprises oxygen, nitrogen, or both oxygen and nitrogen.

91. The method according to embodiment 89 or 90, wherein the silicon substrate comprises boron and oxygen.

92. The method according to embodiment 91, wherein the concentration of boron and the concentration of oxygen are such that in the absence of carbon, boron-oxygen complexes would be formed in the substrate following illumination of the substrate at about 1000 W/m².

93. The method according to embodiment 91, wherein the boron concentration is about 1×10¹⁵ atoms/cm³ or greater.

94. The method according to embodiment 91, wherein the boron concentration is about 1×10¹⁶ atoms/cm³ or greater.

95. The method according to embodiment 91, wherein the boron concentration is about 1×10¹⁷ atoms/cm³ or greater.

96. The method according to embodiment 91, wherein the boron concentration is about 2.5×10¹⁷ atoms/cm³ or greater.

97. The method according to any one of embodiments 91 to 96, wherein the amount of carbon diffused into the substrate is sufficient to reduce the formation of boron-oxygen complexes in the substrate following the illumination of the substrate at about 1000 W/m².

98. The method according to any one of embodiments 91 to 96, wherein the amount of mobile carbon diffused into the substrate is sufficient to substantially eliminate the formation of boron-oxygen complexes in the substrate following the illumination of the substrate at about 1000 W/m².

99. The method according to any one of embodiments 91 to 96, wherein the amount of diffused carbon is sufficient to reduce the formation of boron-oxygen complexes by 50% or more in the substrate following illumination of the substrate, based on the amount of complexes that would be formed in the absence of carbon.

100. The method according to any one of embodiments 91 to 96, wherein the amount of diffused carbon is sufficient to reduce the formation of boron-oxygen complexes by 60% or more in the substrate following illumination of the substrate, based on the amount of complexes that would be formed in the absence of carbon.

101. The method according to any one of embodiments 91 to 96, wherein the amount of diffused carbon is sufficient to reduce the formation of boron-oxygen complexes by 75% or more in the substrate following illumination of the substrate, based on the amount of complexes that would be formed in the absence of carbon.

102. The method according to any one of embodiments 89 to 101, wherein the substrate has been prepared by a Czochralski process.

103. The method according to any one of embodiments 89 to 101, wherein the substrate is a multicrystalline silicon substrate.

104. The method according to any one of embodiments 89 to 101, wherein the substrate is an upgraded metallurgical grade silicon substrate.

105. The method according to any one of embodiments 89 to 104, wherein the distribution of carbon in the doped-substrate is asymmetric, the concentration of carbon being higher near the surface of the substrate adjacent to the interface between the substrate and the antireflective and passivation layer.

106. The method according to embodiment 105, wherein the concentration of carbon in the substrate progressively decreases, for at least the first 50 nm, with increasing depth within the substrate away from the interface between the substrate and the antireflective and passivation layer.

107. The method according to any one of embodiments 89 to 106, wherein the concentration of carbon in the doped-substrate, at a depth of 50 nm from the interface between the substrate and the antireflective and passivation layer, is substantially equal to, or greater than, the concentration of boron in substrate.

108. The method according to any one of embodiments 89 to 106, wherein the concentration of carbon in the doped-substrate, at a depth of 30 nm from the interface between the substrate and the antireflective and passivation layer, is 5×10¹⁷ atoms/cm³ or greater.

109. The method according to any one of embodiments 89 to 106, wherein the concentration of carbon in the doped-substrate, at a depth of 30 nm from the interface between the substrate and the antireflective and passivation layer, is 1×10¹⁸ atoms/cm³ or greater.

110. The method according to any one of embodiments 89 to 20, wherein the carbon concentration in the doped-substrate, adjacent to the interface between the substrate and the antireflective and passivation layer, is 1×10¹⁸ atoms/cm³ or greater.

111. The method according to any one of embodiments 89 to 110, wherein the carbon concentration in the doped-substrate, adjacent to the interface between the substrate and the antireflective and passivation layer, is 1×10¹⁹ atoms/cm³ or greater.

112. The method according to any one of embodiments 89 to 110, wherein the concentration of diffused carbon in the doped-substrate, adjacent to the interface between the substrate and the antireflective and passivation layer, is 1×10²⁰ atoms/cm³ or greater.

113. The method according to any one of embodiments 89 to 112, wherein the substrate has a bulk resistivity of from 2 to 6 Ω·cm.

114. The method according to any one of embodiments 89 to 112, wherein the substrate has a bulk resistivity of less than 2 Ω·cm.

115. The method according to any one of embodiments 89 to 112, wherein the substrate has a bulk resistivity of about 1 Ω·cm.

116. The method according to any one of embodiments 89 to 112, wherein the substrate has a bulk resistivity between about 0.1 to about 1 Ω·cm.

117. The method according to any one of embodiments 89 to 112, wherein the antireflective and passivation layer comprises silicon carbonitride.

118. The method according to embodiment 117, wherein the antireflective and passivation layer comprises from 0.5 to 15 at. % carbon.

119. The method according to embodiment 117, wherein the antireflective and passivation layer comprises from 5 to 10 at. % carbon.

120. The method according to embodiment 117, wherein the antireflective and passivation layer comprises from 6 to 8 at. % carbon.

121 The method according to any one of embodiments 117 to 120, wherein the antireflective and passivation layer comprises at least a first silicon carbonitride layer and a second silicon carbonitride layer,
the first silicon carbonitride layer being adjacent to the substrate and having a carbon concentration of less than 10 at % carbon, and
the second silicon carbonitride layer being on top of the first carbonitride layer and having a carbon concentration which is greater than the carbon concentration than the first silicon carbonitride layer.

122. The method according to embodiment 121, wherein the first layer has a thickness of less than about 100 nm, for example a thickness of less than about 30 nm, and/or the second layer has a thickness of from about 10 nm to about 100 nm, for example a thickness of about 50 nm.

123. The method according to embodiment 121 or 122, wherein the first silicon carbonitride layer is deposited by PECVD of trimethylsilane or tetramethylsilane.

124. The method according to any one of embodiments 117 to 123, wherein the antireflective and passivation layer has a density greater than 2.4 g/cm.

125. The method according to embodiment 124, wherein the antireflective and passivation layer has a density greater than 2.8 g/cm³.

126. The method according to embodiment 124, wherein the antireflective and passivation layer has a density from 2.4 to 3.0 g/cm³.

127. The method according to any one of embodiments 117 to 120, wherein the layer is deposited by chemical vapour deposition (CDV), for example plasma-enhanced chemical vapour deposition (PECVD).

128. The method according to any one of embodiments 117 to 120, wherein the layer is deposited by hot-wire chemical vapour deposition.

129. The method according to any one of embodiments 117 to 120, wherein the layer is deposited by PECVD of a gaseous mixture comprising a) one or more gaseous mono-silicon organosilanes and b) a nitrogen-containing gas.

130. The method according to embodiment 129, wherein the one or more gaseous mono-silicon organosilane is methylsilane.

131. The method according to embodiment 129, wherein the one or more gaseous mono-silicon organosilane is dimethylsilane.

132. The method according to embodiment 129, wherein the one or more gaseous mono-silicon organosilane is trimethylsilane.

133. The method according to embodiment 129, wherein the one or more gaseous mono-silicon organosilane is tetramethyl silane.

134. The method according to embodiment 129, wherein the one or more gaseous mono-silicon organosilane comprises a mixture of two or more of methylsilane, dimethylsilane, trimethylsilane and tetramethylsilane.

135. The method according to embodiment 129, wherein the gaseous mixture comprises from 1 to 5 wt. % methylsilane, from 40 to 70 wt. % dimethylsilane, from 1 to 5 wt. % trimethylsilane, and from 30 to 70 wt. % hydrogen and 5 to 15 wt. % methane.

136. The method according to embodiment 135, wherein the gaseous mixture further comprises tetramethysilane.

137. The method according to embodiment 134, 135 or 136, wherein the gaseous mixture further comprises gaseous organic di-silicon species

138. The method according to any one of embodiments 129 to 137, wherein the one or more gaseous mono-silicon organosilanes are obtained from pyrolysis of a solid organosilane source.

139. The method according to embodiment 138, wherein the solid organosilane source is polydimethylsilane, polycarbomethylsilane, triphenylsilane, or nonamethyltrisilazane.

140. The method according to any one of embodiments 129 to 139, wherein the nitrogen-containing gas is NH₃ or N₂.

141. The method according to any one of embodiments 129 to 140, wherein the gaseous mixture is formed by combining (a) the one or more gaseous mono-silicon organosilanes and (b) the nitrogen-containing gas in a flow ratio (a:b) of 10:1 to 1:50, for example from 1:5 to 1:15, or from 1:6.6 to 1:15.

142. The method according to any one of embodiments 129 to 141, further comprising the step of combining the gaseous mixture with a reactant gas prior to the deposition.

143. The method according to embodiment 142, wherein the reactant gas is O₂, O₃, CO, CO₂ or a combination thereof.

144. The method according to any one of embodiments 129 to 143, wherein the plasma enhanced chemical vapour deposition is radio frequency plasma enhanced chemical vapour deposition (RF-PECVD), low frequency plasma enhanced chemical vapour deposition (LF-PEVCD), electron-cyclotron-resonance plasma-enhanced chemical-vapour deposition (ECR-PECVD), inductively coupled plasma-enhanced chemical-vapour deposition (ICP-ECVD), plasma beam source plasma enhanced chemical vapour deposition (PBS-PECVD), low-, mid-, or high-frequency parallel plate chemical vapour deposition, expanding thermal plasma chemical vapour deposition, microwave excited plasma enhanced chemical vapour deposition, or a combination thereof.

145. The method according to any one of embodiments 89 to 144, wherein the diffusion is achieved by heating the substrate and the antireflective and passivation layer to a temperature of from about 450° C. to about 1000° C., for example from about 450° C. to about 850° C.

146. The method according to embodiments 145, wherein the heating is maintained for at least 1 minute, for example from 1 to 3 minutes.

147. The method according to any one of embodiments 89 to 144, wherein the solar cell further comprises one or more metal contacts, and wherein the formation of the one or more metal contacts and the diffusion of the carbon from the antireflective and passivation layer into the substrate occurs in a single step.

148. The method according to embodiment 147, wherein formation of the metal contact occurs at a temperature of from about 450° C. to about 850° C., for example from about 575° C. to about 725° C.

149. The method according to embodiment 147 or 148, wherein the contact is formed using a paste comprising aluminum or silver, optionally together with lead.

150. A method for reducing the light induced degradation of a solar cell that has a substrate, comprising providing on the substrate an antireflective coating (ARC) containing carbon and allowing carbon to diffuse from the ARC to the substrate.

151. The method according to embodiment 150, wherein the substrate comprises silicon, boron and oxygen.

152. A solar cell comprising:

a silicon substrate comprising boron, oxygen and carbon, and
a frontside antireflective coating,
the frontside antireflective coating comprising at least a silicon carbonitride layer adjacent to the substrate, the layer having a carbon concentration of from 1 to 10 at. %, an oxygen concentration of less than 3 at. %, and a hydrogen concentration greater than 14.5 at. %.

153. A solar cell according to embodiment 152, wherein the silicon carbonitride layer has a carbon concentration of less than 7 at. %, less than 5 at. %, or less than 4 at. %; and/or a hydrogen concentration of greater than 15 at. %, greater than 15.5 at. %, or greater than 16 at. %; and/or a silicon concentration greater than 30 at. %, greater than 35 at. % or greater than 37 at. %.

154. A solar cell comprising:
a silicon substrate comprising boron, oxygen and carbon, and
a frontside antireflective coating,
   the frontside antireflective coating comprising at least a silicon carbonitride layer adjacent to the substrate, the layer having a carbon concentration greater than 1 at. %, an oxygen concentration of less than 3 at. %, a hydrogen concentration greater than 10 at. %, and a silicon concentration greater than 37 at. %.

155. A solar cell according to embodiment 154, wherein the silicon carbonitride layer has a carbon concentration of less than 50 at. %, less than 40 at. %, less than 30 at. %, less than 20 at. %, less than 10 at. %, less than 7 at. %, less than 5 at. %, or less than 4 at. %; and/or a hydrogen concentration of greater than 12 at. %, greater than 14 at. %, greater than 14.5 at. %, greater than 15 at. %, greater than 15.5 at. %, or greater than 16 at. %.

156. A solar cell comprising
a silicon substrate comprising boron, oxygen and carbon, and
a frontside antireflective coating, the frontside antireflective coating comprising at least a first layer adjacent to the substrate and a second layer located on the first layer opposite the substrate;
the first layer comprising silicon carbonitride with a carbon concentration of less than 10 at. %; and
the second layer comprising silicon nitride; or a silicon carbonitride with a carbon concentration which is lower than the carbon concentration in the first layer and/or a silicon concentration that is higher than a silicon concentration in the first layer.

157. A solar cell according to embodiment 156, wherein
the first layer has a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %; and
the second layer comprises silicon nitride, or a silicon carbonitride with a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %

158. A solar cell comprising:
a silicon substrate comprising boron, oxygen and carbon, and
a frontside antireflective coating, the frontside antireflective coating comprising at least a first layer adjacent to the substrate and a second layer located on the first layer opposite the substrate;
the first layer comprising silicon carbonitride, with a carbon concentration of less than 10 at. % and a hydrogen concentration of less than 14.5 at. %; and
the second layer being a hydrogen-containing silicon-based film.

159. A solar cell according to embodiment 158, wherein
the first layer has a carbon concentration of less than 7 at. %, less than 5 at. %, or less than 4 at. %; a hydrogen concentration of from 10 at. % to 14 at. %; and/or a silicon concentration greater than 30 at. %, greater than 35 at. % or greater than 37 at. %.

160. A solar cell according to embodiment 158 or 159, wherein the second layer comprises, silicon nitride, silicon carbide, silicon carbonitride, silicon oxycarbide, silicon oxycarbonitride, or silicon oxynitride.

161. A solar cell according to any one of embodiments 158 to 160, wherein the hydrogen concentration in the second layer is greater than the hydrogen concentration in the first layer.

162. A solar cell comprising:
a silicon substrate comprising boron, oxygen and carbon, and
a frontside antireflective coating, the frontside antireflective coating comprising at least a first layer adjacent to the substrate and a second layer located on the first layer opposite the substrate;
the first layer comprising silicon carbonitride with a carbon concentration of less than 10 at. %; and
the second layer comprising silicon carbide, silicon carbonitride, silicon oxycarbide or silicon oxycarbonitride, the carbon concentration in the second layer being greater than the carbon concentration in the first layer.

163. A solar cell according to embodiment 162, wherein
the first layer has a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %; and
the second layer has a carbon concentration of less than 50 at. %, less than 40 at. %, less than 30 at. %, less than 20 at. %, less than 10 at. %, less than 7 at. %, less than 5 at. %, or less than 4 at. %; and/or a hydrogen concentration greater than 10 at. %, greater than 12 at. %, greater than 14 at. %, greater than 14.5 at. %, greater than 15 at. %, greater than 15.5 at. %, or greater than 16 at. %.; and/or a silicon concentration greater than 30 at. %, greater than 35 at. % or greater than 37 at. %.

164. A solar cell according to any one of embodiments 152 to 155, wherein the antireflective coating has a thickness of from 10 to 100 nm, from 10 to 80 nm, from 20 to 80 nm, or from 30 to 80 nm.

165. A solar cell according to any one of embodiments 156 to 163, wherein the first layer has a thickness of from 10 to 50 nm, from 20 to 40 nm or about 30 nm; and the second layer has a thickness of from 10 to 100 nm, from 20 to 90 nm, from 30 to 70 nm, from 40 to 60 nm, or about 50 nm.

166. A solar cell comprising
a silicon substrate comprising boron, oxygen and carbon, and
a frontside antireflective coating, the frontside antireflective coating comprising at least a silicon carbonitride layer adjacent to the substrate,
the silicon carbonitride layer having a graded carbon concentration with an increasing carbon concentration with increasing distance from the emitter, the first layer having an average carbon concentration of less than 10 at. % within the first 30 nm adjacent to the substrate

167. A solar cell according to any one of embodiment 152 to 166, wherein the substrate comprises an interfacial matching layer at its surface, adjacent to the antireflective coating.

168. A solar cell according to embodiment 16, wherein the interfacial matching layer has a thickness of about 5 nm or less, and is comprised of aluminum oxide, silicon oxide, silicon nitride, or a combination thereof.

169. A method for forming an antireflective coating for a solar cell, the method comprising a deposition of a gaseous precursor mixture comprising silane and an organosilane onto a solar cell substrate.

170. A method according to embodiment 169, wherein the ratio of silane to organosilane, on a volumetric flow basis, is greater than 4:1, greater than 9:1, or about 19:1.

171. A method according to embodiment 169 or 170, wherein the gaseous precursor further comprises a nitrogen source, such as ammonia or N₂.

172. A method according to any one of embodiments 169 to 171, wherein the organosilane comprises methylsilane, dimethylsilane, trimethylsilane, tetramethylsilane, or a combination thereof.

173. A method according to any one of embodiments 169 to 171, wherein the gaseous precursor mixture comprises silane, tetramethylsilane and ammonia.

174. A method according to any one of embodiments 169 to 173, wherein the deposition is carried out by chemical vapour deposition, or by plasma-based chemical vapour deposition.

175. A method according to embodiment 174, wherein the plasma-based chemical vapour deposition is plasma enhanced chemical vapour deposition (PECVD), radio frequency plasma enhanced chemical vapour deposition (RF-PECVD), electron-cyclotron-resonance plasma-enhanced chemical-vapour deposition (ECR-PECVD), inductively coupled plasma-enhanced chemical-vapour deposition (ICP-ECVD), plasma beam source plasma enhanced chemical vapour deposition (PBS-PECVD), or a combination thereof.

These and other embodiments of the invention are further described below.

### Light Induced Degradation

Light induced degradation (LID) of a solar cell refers to the degradation of carrier lifetimes following illumination of the solar cell, which degradation results in loss of cell performance. LID is, for example, often observed in solar cells comprising silicon substrates which contain boron and oxygen atoms. Without wishing to be bound by theory, it is believed that lifetime degradation is not due to a direct creation of defects by photons, but to the formation of an interstitial boron-oxygen complex under illumination (see e.g. Schmidt et al. Physical Review B 69, 024107 (2004)). LID is thus believed to be correlated to the boron and oxygen concentrations in the material. Enhanced light induced degradation characteristics, as described in the present application, therefore represent a decrease in the loss of cell performance following illumination.

The resistivity of a silicon substrate is tied to the performance of a solar cell prepared therewith. Brody et al. (Bulk Resistivity Optimization for Low-Bulk-Lifetime Silicon Solar Cells, Prog. Photovolt.: Res. Appl. 2001; 9:273-285) show, by way of simulation, that the optimal base doping of Czochralski (Cz) Silicon is 0.2 Ω·cm. For monocrystalline silicon substrates prepared by the Cz process, an increase in boron concentration is normally used to obtain a lower resistivity. However, a large concentration of oxygen in the substrate (e.g. from about 5×10¹⁷ to about 5×10¹⁸) is virtually unavoidable due to the partial dissolution of the silicon crucible during the crystal growth process. As a result, the concentration of boron atoms required to achieve low resistivity is such that, when oxygen atoms are also present in the substrate, significant light induced degradation occurs upon illumination of the produced solar cell.

Based on the understanding above, several methods for reducing the lifetime degradation in Cz—Si solar cells were proposed, the most promising being: (i) replacement of B with another dopant element, like Ga, (ii) reduction of the oxygen concentration in the Cz material and (iii) reduction of the B doping concentration. However, the Ga-doped Si solar cells generally show a less stabilized efficiency than B-doped Si solar cells, and reduced oxygen concentration (which can be obtained by using magnetically grown MCz—Si) requires a higher amount of energy consumption. Accordingly, solar cell production often uses higher resistivity Cz wafers (2-6 Ωcm) (i.e. a reduced boron concentration) to mitigate the LID of the solar cells prepared.

Disclosed herein are silicon solar cells which manifest enhanced LID characteristics, which enhancement is not tied to the reduction or elimination of boron and/or oxygen from the silicon substrate.

It is believed that the presence of carbon in the silicon substrate may be able to reduce the formation of the boron-oxygen complexes, thus reducing the degradation of the solar cell upon illumination. Without wishing to be bound by theory, such a process is believed to operate by the complexation of oxygen by carbon, resulting in direct competition between the formation of a carbon/oxygen complex, and the boron-oxygen complex. Oxygen dimers driven by light exposure diffuse in the Si lattice and can be captured by both carbon and boron to create Cₛ—O₂ᵢ and B—O₂ᵢ complexes. The former is not a recombination center, while the latter is. Thus in the presence of carbon, the formation of B—O₂ᵢ metastable complex can be reduced due to the formation of Cₛ—O₂ᵢ, since the oxygen content is fixed. Since Cₛ—O₂ᵢ formation is in direct competition with the formation of the lifetime limiting B—O₂ᵢ complex, LID is reduced in SiCₓN_{y} coated Si solar cells compared to the SiNₓ coated cells.

Further, it is believed that the nature of the carbon in the silicon substrate may affect the ability of the carbon to complex the oxygen and consequently reduce the formation of the B—O complex. While there can be carbon in the substrate ab initio from the manufacturing process, this carbon is likely substitutional i.e. tetra-valently bonded carbon that substitutes for a Si atom. This type of carbon may not be sufficiently mobile in the substrate to substantially reduce formation of the B—O complex. However, during the deposition of PECVD SiCₓN_{y} films (e.g. at 400-500° C.) followed by contact firing (e.g. at a peak temperature of around 750-850° C.), carbon atoms in the SiCₓN_{y} films are expected to diffuse to the interface (emitter region) and into the bulk (base region) of Si solar cells.

Carbon can diffuse into silicon using an interstitial mechanism (see Scholz et al., APPLIED PHYSICS LETTERS VOLUME 74, NUMBER 3, 18 JANUARY 1999), but diffusion may depend on vacancy concentration. It is noted in the reference that interstitial carbon diffusion can be fast unless there are competing processes, and that significant discrepancies were observed between experimental results and an interstitial diffusion model in the presence of Boron, the discrepancies requiring modelling for the presence of vacancies (Frank-Turnbull mechanism). Without wishing to be bound by theory, it is believed that in order to achieve improved LID, a high concentration of carbon may not be needed as it only has to primarily compete with the residual interstitial oxygen in the junction region as this is where a majority of the minority carriers are generated, i.e. carbon may diffuse deeper within the substrate, but its impact is likely higher near the surface.

From the results provided herewith, the presence of a carbon containing antireflective and passivation coating (herein referred to simply as “ARC”) on the substrate has been found to reduce the LID of resulting solar cells. It is important to recognize that there is no external carbon diffusion into the Si substrate from the conventional SiNₓ films grown from silane and ammonia.

The present application therefore relates, in one aspect, to a solar cell that comprises carbon within the substrate, which carbon is mobile, i.e. less strongly bonded within the silicon substrate lattice. In one embodiment, this mobile carbon is provided by diffusion of a carbon into the substrate, for example by way of the carbon-containing film that is deposited on the silicon substrate. Such diffusion of carbon can be enhanced by proper selection of the carbon-containing film, such that the film contains a sufficient concentration of carbon atoms that are able to diffuse under the heating conditions used to deposit the film and the subsequent firing step used to make the solar cell.

### Characterization of the Enhanced Light Induced Degradation

Enhanced light induced degradation characteristics can be defined with respect to various cell performance parameters. In one embodiment, enhanced light induced degradation characteristics are defined with respect of one or more of the Internal Quantum Efficiency (IQE), External Quantum Efficiency (EQE), V_{OC} ratio, J_{sc}, Jₒ, J_{oE} and Fill Factor. Since the enhanced light induced degradation characteristics are comparative in nature, i.e. they refer to a reduction in the change of a variable from pre- to post-illumination, reference to an “original” parameter, for example, the “original IQE”, refers to the value of the parameter in question measured at the time of construction of the solar cell. Select performance parameters of silicon solar cells are described below.

Conversion Efficiency

A solar cell's energy conversion efficiency is the percentage of power converted (from absorbed light to electrical energy) and collected, when a solar cell is connected to an electrical circuit. Standard test conditions (STC) specify a temperature of 25° C. and an irradiance of 1000 W/m² with an air mass 1.5 (AM1.5) spectrum. These correspond to the irradiance and spectrum of sunlight incident on a clear day upon a sun-facing 37°-tilted surface with the sun at an angle of 41.81° above the horizon. This condition approximately represents solar noon near the spring and autumn equinoxes in the continental United States with surface of the cell aimed directly at the sun. Thus, under these conditions a solar cell of 12% efficiency with a 100 cm² (0.01 m²) surface area can be expected to produce approximately 1.2 watts of power.

The losses of a solar cell may be broken down into reflectance losses, thermodynamic efficiency, recombination losses and resistive electrical loss. The overall efficiency is the product of each of these individual losses. Due to the difficulty in measuring these parameters directly, other parameters are measured instead, such as: Quantum Efficiency, V_{OC} ratio, J_{sc}, Jₒ, J_{oE} and Fill Factor. Reflectance losses are a portion of the Quantum Efficiency under “External Quantum Efficiency”. Recombination losses make up a portion of the Quantum Efficiency, V_{OC} ratio, and Fill Factor (FF). Resistive losses are predominantly categorized under Fill Factor, but also make up minor portions of the Quantum Efficiency and V_{OC} ratio.

In one embodiment of the present application, the solar cell has an efficiency of 14% or greater, 15% or greater, 16% or greater, or 17% or greater.

Quantum Efficiency

When a photon is absorbed by a solar cell it is converted to an electron-hole pair. This electron-hole pair may then travel to the surface of the solar cell and contribute to the current produced by the cell; such a carrier is said to be collected. Alternatively, the carrier may give up its energy and once again become bound to an atom within the solar cell without reaching the surface; this is called recombination, and carriers that recombine do not contribute to the production of electrical current.

Quantum efficiency refers to the percentage of photons that are converted to electric current (i.e., collected carriers) when the cell is operated under short circuit conditions. Quantum efficiency can be quantified by the equation:

Quantum efficiency=J_{sc}·V_{oc}·FF/Pᵢₙ

External quantum efficiency is the fraction of incident photons that are converted to electrical current, while internal quantum efficiency is the fraction of absorbed photons that are converted to electrical current. Mathematically, internal quantum efficiency is related to external quantum efficiency by the reflectance of the solar cell; given a perfect anti-reflection coating, they are the same.

In one embodiment, the enhanced LID of a solar cell of the present invention represents a reduction from original Internal Quantum Efficiency (IQE), at any given wavelength between 400 and 1000 nm, of no greater than about 5% following illumination of the solar cell for 72 hours at about 1000 W/m². In a further embodiment, the enhanced LID represents a reduction from original Internal Quantum Efficiency (IQE), at any given wavelength between 400 and 1000 nm, of no greater than about 2% following illumination of the solar cell for 72 hours at about 1000 W/m². In a still further embodiment, the enhanced LID represents a reduction from original Internal Quantum Efficiency (IQE), at any given wavelength between 400 and 900 nm, of no greater than about 2% following illumination of the solar cell for 72 hours at about 1000 W/m². In yet a further embodiment, the enhanced LID represents the observation of substantially no reduction from original Internal Quantum Efficiency (IQE), at any given wavelength between 400 and 900 nm, following illumination of the solar cell for 72 hours at about 1000 W/m².

V_{OC} Ratio

V_{OC} depends on J_{sc} and J_{oE}, where J_{sc} is the short circuit current density and J_{oE} is the emitter saturation current density. Mathematically, V_{oc}=(kT/q)·ln(J_{sc}/J_{oE}+1). J_{oE} can depend on Auger recombination losses, defects related recombination losses and the level of emitter doping. Due to recombination, the open circuit voltage (V_{OC}) of the cell will be below the band gap voltage (V_{g}) of the cell. Since the energy of the photons must be at or above the band gap to generate a carrier pair, cell voltage below the band gap voltage represents a loss. This loss is represented by the ratio of V_{OC} divided by V_{g}.

Maximum-Power Point

A solar cell may operate over a wide range of voltages (V) and currents (I). By increasing the resistive load on an irradiated cell continuously from zero (a short circuit) to a very high value (an open circuit) one can determine the maximum-power point, the point that maximizes V×I; that is, the load for which the cell can deliver maximum electrical power at that level of irradiation (the output power is zero in both the short circuit and open circuit extremes).

Fill Factor and Rshunt

Another defining term in the overall behaviour of a solar cell is the Fill Factor (FF). This is the ratio of the actual obtainable power (maximum power point) divided by the theoretically obtainable power (based on the open circuit voltage (V_{OC}) and the short circuit current (Isc). The Fill factor is thus defined as (Vₘₚlₘₚ)/(V_{oc}I_{sc}), where Iₘₚ and Vₘₚ represent the current density and voltage at the maximum power point.

Rshunt (R_{SH}) is also indicative of cell performance since, as shunt resistance decreases, the flow of current diverted through the shunt resistor increases for a given level of junction voltage, producing a significant decrease in the terminal current I and a slight reduction in V_{OC}. Very low values of R_{SH} will produce a significant reduction in V_{OC}. Much as in the case of a high series resistance, a badly shunted solar cell will take on operating characteristics similar to those of a resistor. When solar cells are combined to form modules, low cell shunt resistance of individual cells in the module cause degradation of the entire module in the field. Generally, modules with higher shunt resistance cells perform better than normal modules especially under low light & cloudy conditions

High values for Fill Factor, together with high Rshunt values, indicate that quality of the contact formed on the solar cell is high. While quality of the contact will also depend in part on other factors, such as the nature of the p-n emitter and the process used to form the contact, a major contributor to Fill Factor is the nature of the antireflective coating, through which the contact must be made. As an estimate, a 0.5% improvement in Fill Factor leads to ˜0.1% increase in cell efficiency, and such an increase in efficiency can be equated to a substantial increase in profitability for solar cell production.

Ideality Factor

In the equation:

I=I′₀(e^{qV/nkT}−1),

n represent the “ideality factor”. This parameter varies with current level as does I′₀. Particularly, n decreases from 2 at low currents to 1 at higher currents. An additional region where n again approaches 2 can be obtained at high currents when minority carrier concentrations approach those of the majority carriers in some regions of the device.

Passivation

It is beneficial for the long-term stability of the efficiency of a solar cell that the surface passivation capability of the solar cell does not degrade under extended exposure to sunlight. The ARC should therefore be able to passivate defects in the surface or near-surface region of the solar cell due to earlier processing steps (e.g. saw damage; etch damage, dangling bonds, etc. . . . ). Poorly passivated surfaces reduce the short circuit current (Isc), the open circuit voltage (V_{OC}), and the internal quantum efficiency, which in turn reduces the efficiency of the solar cell. The ARC film can reduce the recombination of charge carriers at the silicon surface (surface passivation), which is particularly important for high efficiency and thin solar cells (e.g. cells having a thickness <200 μm). Bulk passivation is also important for multicrystalline solar cells, and it is believed that high hydrogen content in the ARC film can induce bulk passivation of various built-in electronic defects (impurities, grain boundaries, etc.) in the multicrystalline (mc) silicon bulk material. In one embodiment, the SiCₓN_{y} films described herein naturally contain bonded and/or interstitial hydrogen atoms, and they manifest good passivation characteristics.

Dark I-V (Current-Voltage) Characteristics

Dark I-V (i.e. current and voltage measured when the cell is not illuminated) characteristics of solar cells are also important, along with light I-V characteristics. For system applications, solar cells are generally assembled in series, which are then grouped in modules. If an individual solar cell in the series-connected string is shadowed, while the remainder of the string is illuminated, the photocurrent must still flow through the shadowed photocell. In this regard it is noted that the output photocurrent from an illuminated solar cell is in the “reverse” direction for the solar cell diode when it is not illuminated. When current is forced through a shadowed solar cell it may be brought to the reverse breakdown point, often resulting in subsequent degradation in its performance.

The solar cell's dark I-V reverse characteristics resemble those of a diode with high reverse (leakage) current, which is not well controlled during manufacture. However, these characteristics may be important when the cell is driven into reverse by a solar module, as described above, that is generating sufficient power to overheat it. This is in some instances referred to as the “hot-spot” of a solar module. In order to prevent the hot-spot damage, the solar cell's dark IV characteristics are very important. One such characteristic is the reverse saturation (or leakage) current. In addition, a low reverse-leakage current can improve low-light module performance. In one embodiment of the present application, a solar cell with a dark reverse saturation current of less than 1.5 A, at a negative bias of −12 V, is provided.

### Solar Cell Composition

A silicon solar cell, as recited herein, means a wide area electronic device that converts solar energy into electricity by the photovoltaic effect, the device comprising a large-area p-n junction made from silicon. The cell also comprises Ohmic metal-semiconductor contacts which are made to both the n-type and p-type sides of the solar cell, and one or more layers that act as a passivation and antireflective coating. Examples of silicon solar cells include amorphous silicon cells, monocrystalline cells, multicrystalline cells, amorphous silicon-polycrystalline silicon tandem cells, silicon-silicon/germanium tandem cells, string ribbon cells, EFG cells, PESC (passivated emitter solar cell), PERC (passivated emitter, rear cell) cells, and PERL (passivated emitter, rear locally diffused cell) cells.

In one embodiment, the invention also relates to a silicon solar cell comprising a silicon-based substrate and an antireflective and passivation layer, the substrate comprising boron, oxygen and a non-uniform distribution of carbon, and to a method for its preparation. In one embodiment, at least part of the carbon added to the substrate is mobile such that it can complex oxygen atoms, in competition with boron, to reduce the formation of boron-oxygen complexes in the silicon substrate upon illumination.

### Silicon Substrate

In one embodiment, the silicon substrate can be monocrystalline or multicrystalline in nature. Monocrystalline substrates can, for example, be prepared by the Czochralski process. The silicon substrate can also be an upgraded metallurgical grade silicon substrate.

The substrate can have, for example, a bulk resistivity of from 0.1 to 6 Ω·cm, a bulk resistivity of from 2 to 6 Ω·cm, a bulk resistivity of from 3 to 6 Ω·cm, a bulk resistivity of from 2 to 3 Ω·cm, a bulk resistivity of less than 2 Ω·cm, a bulk resistivity of less than about 1.5 Ω·cm, a bulk resistivity of about 1 Ω·cm, or a bulk resistivity between about 0.1 to about 1 Ω·cm.

In a further embodiment, the concentration of boron and the concentration of oxygen within the substrate are such that in the absence of carbon, boron-oxygen complexes would be formed in the substrate following illumination of the solar cell at about 1000 W/m². In yet a further embodiment, the boron concentration can be about 1×10¹⁵ atoms/cm³ or greater, about 1×10¹⁷ or greater, or about 2.5×10¹⁷. The oxygen concentration can, for example, be about 1×10¹⁶ atoms/cm³ to about 1×10¹⁸ atoms/cm³, or about 8×10¹⁷ to about 1×10¹⁸ atoms/cm³.

In one embodiment, the amount and nature of carbon in the substrate is sufficient to substantially reduce the formation of boron-oxygen complexes following illumination of the solar cell. For example, the amount and nature of carbon is sufficient to reduce the formation of boron-oxygen complexes by 50% or more, 60% or more, or 75% or more in the substrate following illumination of the solar cell, based on the amount of complexes that would be formed in the absence of carbon. In another embodiment, the amount and nature of carbon is sufficient to substantially eliminate the formation of boron-oxygen complexes in the substrate following illumination of the solar cell. In a further embodiment, the concentration of mobile carbon in the substrate is substantially equal to, or greater than, half the concentration of boron in substrate, or substantially equal to, or greater than, the concentration of boron in substrate. In yet a further embodiment, the concentration of carbon in the substrate is 5×10¹⁵ atoms/cm³ or greater, 5×10¹⁶ atoms/cm³ or greater, 1×10¹⁷ atoms/cm³ or greater, or 1×10¹⁸ atoms/cm³ or greater.

The distribution of carbon in the substrate can be substantially uniform, or the distribution can be non-uniform. In one embodiment, the concentration of carbon varies with increasing depth within the substrate. In another embodiment, the substrate has two major surfaces, and the concentration of carbon decreases with increasing depth within the substrate from at least one of the major surfaces. In yet another embodiment, the concentration of carbon in the substrate progressively decreases, for at least the first 50 nm, with increasing depth within the substrate away from at least one of the major surfaces. By progressively decreases is meant that the carbon concentration gradually decreases, in a continuous manner, over the stated distance. In further embodiments, the carbon concentration in the substrate at one or both of the two major surfaces is 1×10¹⁸ atoms/cm³ or greater, 1×10¹⁹ atoms/cm³ or greater, or 1×10²⁰ atoms/cm³ or greater. In a still further embodiment, the carbon concentration in the substrate is greater than 5×10¹⁶ atoms/cm³ at a depth of 60, 200, or 300 nm from at least one of the two major surfaces.

In one embodiment, the solar cell comprises a silicon-based substrate comprising boron, oxygen and carbon, and one or more carbon-containing antireflective and passivation layers, the substrate having two major surfaces and the one or more antireflective and passivation layers being adjacent to one or both of the two major surfaces, and the concentration of carbon in the substrate being greater at the major surface adjacent to the antireflective and passivation layer than it is at a depth within the substrate equidistant from both major surfaces. In another embodiment, the concentration of carbon in the antireflective and passivation layer at a predetermined distance from a boundary between the antireflective and passivation layer and the substrate is equal to or exceeds the concentration of carbon in the substrate at the same distance from the boundary and wherein the concentration of carbon in the substrate progressively diminishes with increasing depth from the boundary. In a still further embodiment, the concentration of carbon in the substrate progressively decreases, for at least the first 50 nm, with increasing depth within the substrate away from the major surface adjacent to the antireflective and passivation layer. In yet another embodiment, the concentration of diffused carbon in the substrate, at a depth of 50 nm, is substantially equal to, or greater than, the concentration of boron in substrate. In a further embodiment, the concentration of diffused carbon in the substrate at a depth of 30 nm is 5×10¹⁷ atoms/cm³ or greater, or 1×10¹⁸ atoms/cm³ or greater.

In a further embodiment, the concentration of diffused carbon in the substrate represents a substantial fraction of the oxygen concentration. As the B—O complex concentration has a quadratic dependence on oxygen concentration (Fraunhofer) displacement of small amounts of oxygen by carbon can have a substantial impact on the reduction of the light induced degradation of solar cells.

### Antireflective and Passivation Coating

It has generally been believed that the presence of carbon in the antireflective coating is detrimental to solar cell performance. Particularly, it has been believed that the incorporation of carbon results in an increase in the defect density and a decrease in the mass density, leading to poor surface and bulk passivation, respectively. It is also believed that the incorporation of carbon results in reduction of refractive index from ideal index of 2.1 on Si surface, resulting in poor ARC performance. [Y. Hatanaka et al, Proc. 6th Int. Conf. Silicon Carbide & Related Materials, Kyoto, 1995 (IOP, Bristol, 1996) Conf. Ser. Vo. 142, p. 1055]. For SiCN antireflective coatings, is has been reported [Kang et al., Journal of The Electrochemical Society, 156 (6) pp 495-499, (2009)] that the surface charge density Q_{FB}, which plays a role in controlling the surface passivation and solar cell performance, is lowered when compared to a SiN antireflective coating. This reference further notes that the surface charge density may depend on the carbon concentration in the SiCN, a lower carbon concentration producing a reduction in Q_{FB}. This same reference also shows that the interface trap density (Dit) is increased when a SiCN ARC is used as opposed a SiN ARC, although a lower carbon concentration in the SiCN ARC providing for a lower Dit.

In the present specification, various concentrations for Si, C, N, H and O are stated. Unless stated otherwise, the Si, C, N, and O concentrations are in atomic % as measured by Auger Electron Spectroscopy (referred to herein simply as “Auger”), meaning that the concentration is based on the total content of Si, C, N and O atoms in the sample. Hydrogen values, on the other hand, refer to hydrogen concentration as measured by Elastic Recoil Detection (ERD), meaning that these concentration values are based on the total content of Si, C, N, O and H atoms in the sample.

In one embodiment of the present invention, the passivation and antireflective coating comprises amorphous silicon carbon nitride. The amorphous silicon carbon nitride is referred to herein as SiCₓN_{y} or SiCN, all terms being used interchangeably. Similarly, the terms silicon nitride, SiNx and SiN are used interchangeably herein. The variables x and y are not intended to limit the ratio of Si, C and N, but are present to indicate that variations in these ratios are understood and included within the scope of the application. The silicon carbon nitride and silicon nitride also comprise bonded or interstitial hydrogen atoms, the presence of which is understood in the terms SiCₓN_{y} and SiNₓ. The amorphous silicon carbon nitride can also comprise oxygen, even when its mention is not specifically made. In such cases, the oxygen concentration is understood to be low e.g. less than 3 atomic %.

In one embodiment, the amount of carbon in the SiCN ARC is 0.5 atomic % or greater, for example from 0.5 to 15 atomic %, from 1 to 10 atomic %, from 5 to 10 atomic %, from 1 to 7 atomic %, from 1 to 5 atomic %, from 1 to 4 atomic %, or from 6 to 8 atomic %. As noted above, the nature of the carbon in the coating can also impact the amount of carbon that is diffused from the coating into the substrate. In one embodiment, the concentration of carbon in the coating that is able to diffuse is high enough yield a substantial reduction of the formation of B—O complexes upon illumination of the resulting solar cell.

In one embodiment, the atomic % range for Si in the SiCₓN_{y} ARC is from about 25% to about 70%, for example from about 30% to about 60%, from about 37% to about 50%, from about 37% to about 40%, from about 30 to about 37%, from about 30% to about 35%, or from about 31% to about 34%.

In another embodiment, the atomic % range for H in the SiCₓN_{y} ARC is from about 10 to about 40 at. %, for example from about 10 to about 35 at. %, from about 10 to about 14.5 at. %, from about 14.5 to about 35 at. %, from about 15 to about 35 at. %,from about 20 to about 30 at. % or from about 22 to about 28 at. %.

In another embodiment, the atomic % range for N in SiCₓN_{y} is up to about 70%, for example from about 10% to about 60%, from about 20% to about 40%, or from about 25% to about 35%.

In a further embodiment, the film can also comprise other atomic components as dopants. For example, the doped-film can comprise F, Al, B, Ge, Ga, P, As, O, In, Sb, S, Se, Te, In, Sb or a combination thereof.

The thickness of the film can be selected based on the optical and physical characteristics desired for the prepared ARC. In one embodiment, the thickness is selected in order to obtain a reflection minima at a light wavelength of about 600-650 nm. For example a refractive index of 2.05 with a thickness of 76 nm can, for some uses, be considered optimum, although small variations in thickness may not greatly affect the refractive index. In one embodiment, the SiCₓN_{y} ARC will have thickness from about 10 to 160 nm, for example from about 50 to about 120 nm, from about 10 to about 100 nm, from about 10 to 80 nm, from about 20 to 80 nm, from about 30 to 80 nm, from about 50 to about 100 nm or from about 70 to about 80 nm.

In one embodiment, the antireflective coating adjacent to the silicon substrate comprises only a SiCₓN_{y} layer. In another embodiment, the antireflective coating comprises a multiplicity of layers, at least one of which is a SiCₓN_{y} layer as described herein. In yet another embodiment, the antireflective coating comprises a SiCₓN_{y} layer as described herein, which layer manifests a graded refractive index through its thickness.

In one embodiment, the antireflective layer adjacent to the silicon substrate comprises SiCN and has a carbon concentration of from 1 to 10 at. %, an oxygen concentration of less than 3 at. %, and a hydrogen concentration greater than 14.5 at. %. For example, the layer can have a carbon concentration of less than 7 at. %, less than 5 at. %, or less than 4 at. %; and/or a hydrogen concentration of greater than 15 at. %, greater than 15.5 at. %, or greater than 16 at. %; and/or a silicon concentration greater than 30 at. %, greater than 35 at. % or greater than 37 at. %.

In another embodiment, the antireflective layer adjacent to the silicon substrate comprises SiCN and has a carbon concentration greater than 1 at. %, an oxygen concentration of less than 3 at. %, a hydrogen concentration greater than 10 at. %, and a silicon concentration greater than 37 at. %. For example, the SiCN has a carbon concentration of less than 50 at. %, less than 40 at. %, less than 30 at. %, less than 20 at. %, less than 10 at. %, less than 7 at. %, less than 5 at. %, or less than 4 at. %; and/or a hydrogen concentration of greater than 12 at. %, greater than 14 at. %, greater than 14.5 at. %, greater than 15 at. %, greater than 15.5 at. %, or greater than 16 at. %.

In some embodiments of the present invention, the ARC can comprise a plurality of layers, the first layer adjacent to the silicon substrate comprising carbon. The first layer therefore provides the carbon that can diffuse into the silicon substrates for enhanced LID characteristics, while the second layer can be used to overcome disadvantages that may be inherent to a solar cell having a carbon-containing layer adjacent to the substrate with a carbon concentration sufficient for achieving the LID benefits.

In one embodiment, the first layer has a thickness of from 10 to 50 nm, from 20 to 40 nm or about 30 nm; and the second layer has a thickness of from 10 to 100 nm, from 20 to 90 nm, from 30 to 70 nm, from 40 to 60 nm, or about 50 nm.

In one embodiment, the antireflective coating can comprise at least a first layer adjacent to the substrate and a second layer located on the first layer opposite the substrate, the first layer comprising silicon carbonitride with a carbon concentration of less than 10 at. %; and the second layer comprising silicon nitride; or a silicon carbonitride with a carbon concentration which is lower than the carbon concentration in the first layer and/or a silicon concentration that is higher than a silicon concentration in the first layer. For example, the first layer can have a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %; and the second layer can comprise silicon nitride, or a silicon carbonitride with a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %. The use of a second layer comprising silicon nitride can prove optically advantageous since SiN can have a refractive index which is higher than SiCN as shown in the Examples below. Use of SiN can also provide electronic advantages since, as noted in Kang (supra), SiN provides for a higher surface charge density than SiCN. Accordingly, if the first layer is thin e.g. about 10-15 nm, then presence of SiN in the second layer may provide for an enhanced effective Q_{FB}. The use of a second layer comprising SiCN with a higher silicon concentration may be advantageous for reasons similar to the use of SiN, i.e. for providing for a higher refractive index and possibly an enhanced Q_{FB}. Finally, use of a second layer comprising SiCN with a lower carbon concentration can be advantageous in that SiCN with a lower carbon concentration may provide for a greater transparency.

In another embodiment, the antireflective coating can comprise at least a first layer adjacent to the substrate and a second layer located on the first layer opposite the substrate; the first layer comprising silicon carbonitride, with a carbon concentration of less than 10 at. % and a hydrogen concentration of less than 14.5 at. %; and the second layer being a hydrogen-containing silicon-based coating. For example, the first layer can have a carbon concentration of less than 7 at. %, less than 5 at. %, or less than 4 at. %; a hydrogen concentration of from 10 at. % to 14 at. %; and/or a silicon concentration greater than 30 at. %, greater than 35 at. % or greater than 37 at. %, and the second layer can comprise silicon nitride, silicon carbide, silicon carbonitride, silicon oxycarbide, silicon oxycarbonitride, or silicon oxynitride. As shown in the examples below, advantageous I-V characteristics can be observed for solar cells having antireflective coatings with higher hydrogen concentrations, likely due to improved passivation resulting from a greater diffusion of hydrogen into the substrate. The presence of a hydrogen-containing second layer can be advantageous as it provides for a greater reservoir of hydrogen that can diffuse into the substrate for passivation purposes. The hydrogen concentration within the second layer can be less than, the same or greater than the hydrogen concentration in the first layer.

In yet another embodiment, the antireflective coating can comprise at least a first layer adjacent to the substrate and a second layer located on the first layer opposite the substrate; the first layer comprising silicon carbonitride with a carbon concentration of less than 10 at. %; and the second layer comprising silicon carbide, silicon carbonitride, silicon oxycarbide or silicon oxycarbonitride, the carbon concentration in the second layer being greater than the carbon concentration in the first layer. For example, the first layer can have a carbon concentration of less than 7 at. %, less than 5 at. %, or less than 4 at. %; and/or a hydrogen concentration of greater than 10 at. %, greater than 12 at. %, greater than 14 at. %, greater than 14.5 at. %, greater than 15 at. %, greater than 15.5 at. %, or greater than 16 at. %; and/or a silicon concentration greater than 30 at. %, greater than 35 at. % or greater than 37 at. %; and the second layer can have a carbon concentration of less than 50 at. %, less than 40 at. %, less than 30 at. %, less than 20 at. %, less than 10 at. %, less than 7 at. %, less than 5 at. %, or less than 4 at. %; and/or a hydrogen concentration greater than 10 at. %, greater than 12 at. %, greater than 14 at. %, greater than 14.5 at. %, greater than 15 at. %, greater than 15.5 at. %, or greater than 16 at. %.; and/or a silicon concentration greater than 30 at. %, greater than 35 at. % or greater than 37 at. %. The presence of SiCN with an increased concentration of carbon in the second layer can prove advantageous since, as shown in the Examples below, a greater carbon concentration in SiCN provides for a higher refractive index. The examples also show that an increase in carbon concentration is also usually accompanied with an increase in hydrogen concentration, which provides for better passivation of the substrate. Finally, as taught by Kang (supra), the surface charge density for a SiCN ARC increases with the carbon concentration, meaning that in those embodiments where the first layer is thinner, e.g. from about 10-15 nm, the presence of a higher carbon concentration in the second layer may provide for better effective Q_{FB}.

In another embodiment, the antireflective and passivation coating can comprise at least two silicon carbon nitride layers, the first silicon carbon nitride layer being adjacent to the substrate and having a carbon concentration of less than about 10 at. %, e.g. from about 3 to about 8 at. % carbon, and the second silicon carbon nitride layer being on top of the first carbon nitride layer and having a carbon concentration which is greater than the carbon concentration than the first silicon carbon nitride layer, e.g. from about 10 to about 25 at. %.

In one embodiment, the antireflective and passivation coating comprising carbon is deposited directly onto the silicon substrate. In another embodiment, one or more intervening layers (i.e. films) that do not contain carbon, or do not contain a sufficient amount of carbon that is able to diffuse into the silicon substrate, can be present between the carbon-containing antireflective and passivation coating and the silicon substrate, as long as the nature and thickness of these intervening layers are such that carbon can still sufficiently diffuse from the carbon-containing antireflective and passivation coating to the silicon substrate, upon heating, such that the formation of B—O complexes in the substrate, upon illumination, is reduced. The substrate may also comprise an interfacial matching layer at its surface, adjacent to the antireflective coating. This interfacial matching layer is not considered herein to form a film discrete from the substrate, but to be a part thereof. In one embodiment, the interfacial matching layer has a thickness of about 5 nm or less. In another embodiment, the interfacial matching layer can be comprised of a naturally or a chemically induced oxide, and may be e.g. aluminum oxide, silicon oxide or a combination thereof.

In one embodiment, the SiCxNy ARC can have a refractive index (n) at a wavelength of 630 nm of 1.8 to 2.3, for example a refractive index of 2.05, and an extinction coefficient (k) at a wavelength of 300 nm of less than 0.01, for example less than 0.001.

In one embodiment, the antireflective and passivation layer has a density greater than 2.4 g/cm³, for example a density greater than 2.8 g/cm³ or a density from 2.4 to 3.0 g/cm³. For a solar cell as described in the present application, density of the antireflective and passivation coating can be measured by an x-ray based technique. Such a high density (i.e. greater than 2.4 g/cm³) can be achieved by proper selection of the combination of the gases chosen to make the SiCxNy film, the PECVD platform (indirect/indirect/low frequency/RF frequency/microwave) and the process parameters (substrate temperature/power/gas flows/pressure). In one embodiment, substrate temperature is increased to 450° C. or greater during deposition.

High density films are useful for solar coatings as the film itself contains hydrogen (e.g. ˜10% hydrogen), and some of this hydrogen is not bonded to N or Si (or C) in the film. In one embodiment, during contact formation the atomic hydrogen diffuses into the bulk of the solar cell (in some embodiments hydrogen diffuses rapidly at ˜800° C.) and passivates any traps/dangling bonds in the bulk of the silicon solar cell. This process improves the minority carrier lifetime in the silicon and thereby improves the efficiency of the solar cell.

To facilitate hydrogen diffusion into the silicon and to reduce the dissipation of hydrogen into the region above the cell, the SiCN layer itself can be made relatively impervious to hydrogen diffusion i.e. the SiCN layer can act as both a hydrogen source and as a cap for favouring diffusion of hydrogen into the silicon. Such a “cap” function of the antireflective and passivation coating is promoted by a higher density in the coating. The antireflective coating can also comprise a discrete capping layer opposite the substrate to further reduce the dissipation of hydrogen into the region above the cell. Such a layer should be dense for the reasons mentioned above, and can for example comprise silicon carbide (SiC).

### Metal Contacts

In one embodiment, Ohmic metal-semiconductor contacts are made to both the n-type and p-type sides of the solar cell. Contacts can be formed, for example, by screen printing a metal paste, and by firing the deposited paste. The temperature and duration of firing will depend on the nature of the paste used, and characteristics of the solar cell e.g. the nature and thickness of the antireflective and passivation coating. In some embodiments, particular solar cell parameters, such as the fill factor, may depend on the nature of the paste used.

In one embodiment, screen printed Ag paste metallization is a used for front-side contact formation. Screen-printable Ag pastes can, for example, comprise Ag powder, glass frit, binders, solvent and other additives. Without wishing to be bound by theory, it is believed that during contact firing, the glass frit melts down to etch through the ARC layer and react with the Si surface, which enables Ag crystallites to nucleate at the thin glass/Si interface to form an Ohmic contact with the Si emitter.

Examples of suitable pastes include those sold by Five Star Technologies® (e.g. Ag and Al pastes falling under the trade name Electrospere™, such as Electrosphere S-series pastes, including the S-540 (Ag), S-546 (Ag), S-570 (Ag) and S-680 (Al) pastes, and those sold by Ferro® (e.g. Al pastes such as product CN53-101). In some embodiments, the pastes can also comprise lead, which can provide for better quality contact formation.

### Preparation of the SiCₓN_{y} ARC

In one embodiment, the SiCₓN_{y} antireflective and passivation coating can be prepared by deposition of gaseous species comprising Si, C, N and H atoms.

While it is possible to combine all of the required Si, C, N and H atoms within a single gaseous species, two or more gases, collectively comprising the required atomic species, can be combined and reacted to form the coating.

In one embodiment, the required C and Si atoms are contained in separate gases, while in another embodiment the C and Si atoms are contained in a single gaseous species. For example, the SiCₓN_{y} ARC can be prepared from a mixture of SiH₄, a gaseous source of nitrogen (e.g. NH₃, N₂ or NCl₃), and a gaseous hydrocarbon (e.g. methane, acetylene, propane, butane etc. . . . ), or other carbon containing compounds e.g. methylsilane, dimethylsilane, trimethylsilane, tetramethylsilane, or combinations thereof. A mixture of SiH₄ and a gaseous methylamine (e.g. CH3NH2, (CH3)2NH, (CH3)3N, etc. . . . ), can also be used.

Alternately, a gaseous organosilicon compounds (e.g. one or more organosilane and/or an organopolycarbosilane, such as methylsilane, dimethylsilane, trimethylsilane, tetramethylsilane, hexamethyldisilazane, tri(dimethylamino)silane, tris(dimethylamino)methylsilane, tetrakis(dimethylamino)silane, Si(N(CH₃)₂)₄, and/or polymethylsilazane, dimethylaminotrimethylsilane), is mixed with a gaseous source of nitrogen (e.g. NH₃ or N₂) and deposited to yield the SiCₓN_{y} ARC. The gaseous organosilicon compounds can be obtained commercially in gas form (and admixed if required), they can be obtained in liquid form and volatilized, or they can be prepared (optionally in-situ) from solid precursors. In one embodiment, the gaseous mixture to be deposited is formed by combining (a) the one or more gaseous organosilicon compounds and (b) the nitrogen-containing gas in a flow ratio (a:b) of 10:1 to 1:50, for example from 1:5 to 1:15, or from 1:6.6 to 1:15.

Gaseous Organosilicon Compounds from Solid Precursors

In one embodiment, the gaseous organosilanes and/or organopolycarbosilanes can be obtained from thermal decomposition/rearrangement (i.e. pyrolysis) or volatilisation of a solid organosilane source. The solid organosilane source can be any compound that comprises Si, C and H atoms and that is solid at room temperature and pressure.

The solid organosilane source may, in one embodiment, be a silicon-based polymer comprising Si—C bonds that are thermodynamically stable during heating in a heating chamber. In one embodiment, the silicon-based polymer has a monomeric unit comprising at least one silicon atom and two or more carbon atoms. The monomeric unit may further comprise additional elements such as N, O, F, or a combination thereof. In another embodiment, the polymeric source is a polysilane or a polycarbosilane.

The polysilane compound can be any solid polysilane compound that can produce gaseous organosilicon compounds when pyrolyzed, i.e. chemical decomposition of the solid polysilane by heating in an atmosphere that is substantially free of molecular oxygen. In one embodiment, the solid polysilane compound comprises a linear or branched polysilicon chain (optionally in ring form) wherein each silicon is substituted by one or more hydrogen atoms, C₁-C₆ alkyl groups, phenyl groups or —NH₃ groups. In a further embodiment, the linear or branched polysilicon chain has at least one monomeric unit comprising at least one silicon atom and one or more carbon atoms. In another embodiment, the linear or branched polysilicon chain has at least one monomeric unit comprising at least one silicon atom and two or more carbon atoms.

Examples of solid organosilane sources include silicon-based polymers such as polydimethylsilane (PDMS) and polycarbomethylsilane (PCMS), and other non-polymeric species such as triphenylsilane or nonamethyltrisilazane. PCMS is commercially available (Sigma-Aldrich) and it can have, for example, an average molecular weight from about 800 Daltons to about 2,000 Daltons. PDMS is also commercially available (Gelest, Morrisville, P.A. and Strem Chemical, Inc., Newburyport, M.A.) and it can have, for example, an average molecular weight from about 1,100 Daltons to about 1,700 Dalton. Use of PDMS as a source compound is advantageous in that (a) it is very safe to handle with regard to storage and transfer, (b) it is air and moisture stable, a desirable characteristic when using large volumes of a compound in an industrial environment, (c) no corrosive components are generated in an effluent stream resulting from PDMS being exposed to CVD process conditions, and (d) PDMS provides its own hydrogen supply by virtue of its hydrogen substituents.

In another embodiment, the solid organosilane source may have at least one label component, the type, proportion and concentration of which can be used to create a chemical “fingerprint” in the obtained film that can be readily measured by standard laboratory analytical tools, e.g. Secondary Ion Mass Spectrometry (SIMS), Auger Electron Spectrometry (AES), X-ray photoelectron spectroscopy (XPS). In one embodiment, the solid organosilane source can contain an isotope label, i.e. a non-naturally abundant relative amount of at least one isotope of an atomic species contained in the solid organosilane source, e.g. C¹³ or C¹⁴. This is referred to herein as a synthetic ratio of isotopes.

### Pyrolysis/Volatilization of the Solid Precursor

In one embodiment, the gaseous organosilicon species are formed by pyrolysis of the solid organosilane source in a heating chamber. The solid source may be added to the heating chamber in a batch or continuous manner as a powder, pellet, rod or other solid form. Optionally, the solid organosilane source may be mixed with a second solid polymer in the heating chamber. In batch addition, the solid organosilane source compound may be added, for example, in an amount in the range of from 1 mg to 10 kg, although larger amounts may also be used.

In one embodiment the heating chamber is purged, optionally under vacuum, after the solid organosilane source has been added, to replace the gases within the chamber with an inert gas, such as argon or helium. The chamber can be purged before heating is commenced, or the temperature within the chamber can be increased during, or prior to, the purge. The temperature within the chamber during the purge should be kept below the temperature at which evolution of the gaseous species commences to minimise losses of product.

The pyrolysis step can encompass one or more different types of reactions within the solid. The different types of reactions, which can include e.g. decomposition/rearrangement of the solid organosilane into a new gaseous and/or liquid organosilane species, will depend on the nature of the solid organosilane source, and these reactions can also be promoted by the temperature selected for the pyrolysis step. Control of the above parameters can also be used to achieve partial or complete volatilisation of the solid organosilane source instead of pyrolysis (i.e. instead of decomposition/rearrangement of the organosilane source). The term “pyrolysis”, as used herein, is intended to also capture such partial or complete volatilization. For embodiments where the solid organosilane source is a polysilane, the gaseous species can be obtained through a process as described in U.S. provisional application Ser. No. 60/990,447 filed on Nov. 27, 2007, the disclosure of which is incorporated herein by reference in its entirety.

The heating of the solid organosilane source in the heating chamber may be performed by electrical heating, UV irradiation, IR irradiation, microwave irradiation, X-ray irradiation, electronic beams, laser beams, induction heating, or the like.

The heating chamber is heated to a temperature in the range of, for example, from about 50 to about 700° C., from about 100 to about 700° C., from about 150 to about 700° C., from about 200 to about 700° C., from about 250 to about 700° C., from about 300 to about 700° C., from about 350 to about 700° C., from about 400 to about 700° C., from about 450 to about 700° C., from about 500 to about 700° C., from about 550 to about 700° C., about 600 to about 700° C., from about 650 to about 700° C., from about 50 to about 650° C., from about 50 to about 600° C., from about 50 to about 550° C., from about 50 to about 500° C., from about 50 to about 450° C., from about 50 to about 400° C., from about 50 to about 350° C., from about 50 to about 300° C., from about 50 to about 250° C., from about 50 to about 200° C., from about 50 to about 150° C., from about 50 to about 100° C., from about 100 to about 650° C., from about 150 to about 600° C., from about 200 to about 550° C., from about 250 to about 500° C., from about 300 to about 450° C., from about 350 to about 400° C., from about 475 to about 500° C., about 50° C., about 100° C., about 150° C., about 200° C., about 250° C., about 300° C., about 350° C., about 400° C., about 450° C., about 500° C., about 550° C., about 600° C., about 650° C., or about 700° C. A higher temperature can increase the rate at which the gaseous compounds are produced from the solid organosilane source.

In one embodiment, the heating chamber is heated at a rate of up to 150° C. per hour until the desired temperature is reached, at which temperature the chamber is maintained. In another embodiment, the temperature is increased to a first value at which pyrolysis proceeds, and then the temperature is changed on one or more occasion, e.g. in order to vary the rate at which the mixture of gaseous compound is produced or to vary the pressure within the chamber.

In one embodiment the temperature and pressure within the heating chamber are controlled, and production of the gaseous species can be driven by reducing the pressure, by heating the organosilane source, or by a combination thereof. Selection of specific temperature and pressure values for the heating chamber can also be used to control the nature of the gaseous species obtained.

In the embodiment where the solid organosilane source is a polysilane, one possible pyrolysis reaction leads to the formation of Si—Si crosslinks within the solid polysilane, which reaction usually takes place up to about 375° C. Another possible reaction is referred to as the Kumada rearrangement, which typically occurs at temperatures between about 225° C. to about 350° C., wherein the Si—Si backbone chain becomes a Si—C—Si backbone chain. While this type of reaction is usually used to produce a non-volatile product, the Kumada re-arrangement can produce volatile polycarbosilane oligomers, silanes and/or methyl silanes. While the amount of gaseous species produced by way of the Kumada rearrangement competes with the production of non-volatile solid or liquid polycarbosilane, the production of such species, while detrimental to the overall yield, can prove a useful aspect of the gas evolution process in that any material, liquid or solid, that is left in the heating chamber is in some embodiments turned into a harmless and safe ceramic material, leading to safer handling of the material once the process is terminated.

Gaseous Organosilicon Compounds from Liquid Precursors

In one embodiment, the gaseous organosilanes can be obtained by volatilization of a liquid organosilane precursor such as tetramethylsilane. The liquid precursor can be volatilized by way of one or more vaporizers, or it can be provided by way of an apparatus as described in U.S. Application No. 61/368,857, filed Jun. 17, 2010, the contents of which are hereby incorporated by reference in their entirety.

### Gaseous Organosilicon Species

Generally, the gaseous organosilicon species prepared from solid organosilanes comprise a mixture of volatile fragments of the organosilane. In the embodiment where the solid organosilane precursor is a polysilane, the gaseous species are a mixture of gaseous organosilicon compounds.

In one embodiment, the mixture of gaseous organosilicon compounds substantially comprises one or more gaseous silanes (i.e. gaseous compounds comprising a single silicon atom). These may also be referred to as gaseous mono-silicon organosilanes, examples of such include methyl silane, dimethyl silane, trimethyl silane and tetramethyl silane.

In one embodiment, the gaseous mixture can also optionally comprise small amounts (e.g. less than 10%) of gaseous multi-silicon species, such as gaseous polysilanes, or gaseous polycarbosilanes. By gaseous polysilane is meant a compound comprising two or more silicon atoms wherein the silicon atoms are covalently linked (e.g. Si—Si), and by gaseous polycarbosilane is meant a compound comprising two or more silicon atoms wherein at least two of the silicon atoms are linked through a non-silicon atom (e.g. Si—CH₂—Si). Examples of gaseous polycarbosilanes can have the formula:

Si(CH₃)ₙ(H)ₘ—[(CH₂)—Si(CH₃)ₚ(H)_{q}]ₓ—Si(CH₃)_{n′}(H)_{m′}

wherein n, m, n′ and m′ independently represent an integer from 0 to 3, with the proviso that n+m=3 and n′+m′=3; p and q independently represent an integer from 0 to 2, with the proviso that p+q=2 for each silicon atom; and x is an integer from 0 to 3. Further examples of gaseous polycarbosilanes include [Si(CH₃)(H)₂]—CH₂—[Si(CH₃)₂(H)], [Si(CH₃)₂(H)]—CH₂—[Si(CH₃)₂(H)], [Si(CH₃)₃]—CH₂—[Si(CH₃)₂(H)], [Si(CH₃)₂(H)]—CH₂—[Si(CH₃)₂]—CH₂—[Si(CH₃)₃], [Si(CH₃)(H)₂]—CH₂—[Si(CH₃)₂]—CH₂—[Si(CH₃)(H)₂], [Si(CH₃)(H)₂]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂(H)], [Si(CH₃)₂(H)]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)₂(H)], [Si(CH₃)(H)₂]—CH₂—[Si(CH₃)₂]—CH₂—[Si(CH₃)₂]—CH₂—[Si(CH₃)(H)₂], and [Si(H)₃]—CH₂—[Si(CH₃)₂]—CH₂—[Si(CH₃)₂]—CH₂—[Si(CH₃)(H)₂].

As noted above, the gaseous organosilicon species may also be obtained directly in gaseous form, and/or they can be prepared by vaporization of liquid precursors, such as tetramethysilane. These gaseous organosilicon species may be used alone (i.e. not in admixture with other gaseous organosilicon species) or they can be combined with other gaseous organosilicon species. Further, the silicon containing gaseous species (alone or in combination) can be deposited by themselves, or they can be admixed with further gaseous components. Examples of such further gaseous components include hydrogen and hydrocarbons such as methane, ethane, etc. . . .

In one embodiment, the gaseous species is a mixture comprising, as the silicon containing species, from 20 to 45 wt. % methylsilane, from 35 to 65 wt. % dimethylsilane, from 5 to 15 wt. % trimethylsilane, and optionally up to 10 wt. % gaseous carbosilane species. In another embodiment, the gaseous species comprises only tetramethylsilane as the silicon containing species, an alkane such as methane, ethane, propane etc. . . . and/or hydrogen also being optionally present. In a further embodiment, the gaseous mixture comprises from 1 to 5 wt. % methylsilane, from 40 to 70 wt. % dimethylsilane, from 1 to 5 wt. % trimethylsilane, from 30 to 70 wt. % hydrogen and from 5 to 15 wt. % methane. In yet another embodiment, the gaseous mixture comprises about 3 vol. % methylsilane, about 36 vol. % dimethylsilane, about 2 vol. % trimethylsilane, about 12 vol. % methane, and hydrogen.

In another embodiment, the gaseous precursor deposited can be a mixture comprising silane and an organosilane. The organosilane can for example comprise methylsilane, dimethylsilane, trimethylsilane, tetramethylsilane, or a combination thereof. The gaseous precursor can also comprise a gaseous nitrogen source, e.g. ammonia or N₂. In one particular embodiment, the gaseous precursor comprises silane, tetramethylsilane and ammonia. In one embodiment, the ratio of silane to organosilane in the gaseous precursor is greater than about 4:1, greater than about 9:1, or about 19:1, on a volumetric flow basis (ratio of volume, at standard temperature and pressure, over time). In another embodiment, the ratio of silicon-containing gas (i.e. silane and organosilane) to gaseous nitrogen source (e.g. ammonia) can be from 1:1 to 1:50, for example from 1:4 to 1:20 or from about 1:4 to about 1:9.

### Addition of a Reactant Gas

The gaseous species used to form the SiCₓN_{y} may be mixed with a reactant gas in the deposition chamber, in a gas mixing unit, or when pyrolysis is used to obtain the gaseous species, in the heating chamber. In one embodiment, the reactant gas may be in the form of a gas that is commercially available, and the gas is provided directly to the system. In another embodiment, the reactant gas is produced by heating a solid or liquid source comprising any number of elements, such as O, F, or a combination thereof.

In one example, the reactant gas may be an oxygen-based gas such as CO, O₂, O₃, CO₂ or a combination thereof.

In an embodiment, the reactant gas may also comprise F, Al, B, Ge, Ga, P, As, In, Sb, S, Se, Te, In and Sb in order to obtain a doped SiCₓN_{y} film.

### Deposition Chamber

When it is desired to form a film, a substrate is placed into a deposition chamber, which is evacuated to a sufficiently low pressure, and the gaseous species and optionally a carrier gas are introduced continuously or pulsed. Any pressure can be selected as long as the energy source selected to effect the deposition can be used at the selected pressure. For example, when plasma is used as the energy source, any pressure under which plasma can be formed is suitable. In embodiments of the present invention the pressure can be from about 50 to about 4000 mTorr, from about 100 to about 500 mTorr, from about 150 to about 500 mTorr, from about 200 to about 500 mTorr, from about 200 to about 500 mTorr, from about 250 to about 500 mTorr, from about 300 to about 500 mTorr, from about 350 to about 500 mTorr, from about 400 to about 500 mTorr, from about 450 to about 500 mTorr, from about 50 to about 450 mTorr, from about 50 to about 400 mTorr, from about 50 to about 350 mTorr, from about 50 to about 300 mTorr, from about 50 to about 250 mTorr, from about 50 to about 200 mTorr, from about 50 to about 150 mTorr, from about 50 to about 100 mTorr, from about 100 to about 450 mTorr, from about 150 to about 400 mTorr, from about 200 to about 350 mTorr, from about 250 to about 300 mTorr, from about 50 mTorr to about 5 Torr, from about 50 mTorr to about 4 Torr, from about 50 mTorr to about 3 Torr, from about 50 mTorr to about 2 Torr, from about 50 mTorr to about 1 Torr, about 50 mTorr, about 100 mTorr, about 150 mTorr, about 200 mTorr, about 250 mTorr, about 300 mTorr, about 350 mTorr, about 400 mTorr, about 450 mTorr, about 500 mTorr, about 1 Torr, about 2 Torr, about 3 Torr, about 4 Torr, or about 5 Torr.

The substrate is held at a temperature in the range of, for example, from about 25 to about 500° C., from about 50 to about 500° C., from about 100 to about 500° C., from about 150 to about 500° C., from about 200 to about 500° C., from about 250 to about 500° C., from about 300 to about 500° C., from about 350 to about 500° C., from about 400 to about 500° C., from about 450 to about 500° C., from about 25 to about 450° C., from about 25 to about 400° C., from about 25 to about 350° C., from about 25 to about 300° C., from about 25 to about 250° C., from about 25 to about 200° C., from about 25 to about 150° C., from about 25 to about 100° C., from about 25 to about 50° C., from about 50 to about 450° C., from about 100 to about 400° C., from about 150 to about 350° C., from about 200 to about 300° C., about 25° C., about 50° C., about 100° C., about 150° C., about 200° C., about 250° C., about 300° C., about 350° C., about 400° C., about 450° C., or about 500° C.

Any system for conducting chemical vapour deposition (CVD) may be used for the method of the present invention, and other suitable equipment will be recognised by those skilled in the art. The typical equipment, gas flow requirements and other deposition settings for a variety of deposition tools used for commercial coating solar cells can be found in True Blue, Photon International, March 2006 pages 90-99 inclusive, the contents of which are enclosed herewith by reference.

The deposition can occur by atmospheric CVD, or the energy source in the deposition chamber may be, for example, electrical heating, hot filament processes, UV irradiation, IR irradiation, microwave irradiation, X-ray irradiation, electronic beams, laser beams, plasma, or RF. In a preferred embodiment, the energy source is plasma, and examples of suitable plasma deposition techniques include plasma enhanced chemical vapour deposition (PECVD), radio frequency plasma enhanced chemical vapour deposition (RF-PECVD), low frequency plasma enhanced chemical vapour deposition (LF-PEVCD), electron-cyclotron-resonance plasma-enhanced chemical-vapour deposition (ECR-PECVD), inductively coupled plasma-enhanced chemical-vapour deposition (ICP-PECVD), plasma beam source plasma enhanced chemical vapour deposition (PBS-PECVD), low-, mid-, or high-frequency parallel plate chemical vapour deposition, expanding thermal plasma chemical vapour deposition, microwave excited plasma enhanced chemical vapour deposition, or a combination thereof. Furthermore, other types of deposition techniques suitable for use in manufacturing integrated circuits or semiconductor-based devices may also be used.

For embodiments where the energy used during the deposition is plasma, e.g. for PE-CVD, characteristics of the obtained film may be controlled by suitably selecting conditions for (1) the generation of the plasma, (2) the temperature of the substrate, (3) the power and frequency of the reactor, and (4) the type and amount of gaseous species introduced into the deposition chamber.

### Configuration of Heating and Deposition Chambers

In those embodiments where the gaseous organosilicon species is obtained from the pyrolysis of a solid source, or the volatilization of a liquid source, the process may be carried with a variety of system configurations, such as a heating chamber and a deposition chamber; a heating chamber, a gas mixing unit and a deposition chamber; a heating chamber, a gas mixing unit and a plurality of deposition chambers; or a plurality of heating chambers, a gas mixing unit and at least one deposition chamber. In a preferred embodiment, the deposition chamber is within a reactor and the heating chamber is external to the reactor.

For high throughput configurations, multiple units of the heating chamber may be integrated. Each heating chamber in the multiple-unit configuration may be of a relatively small scale in size, so that the mechanical construction is simple and reliable. All heating chambers may supply common gas delivery, exhaust and control systems so that cost is similar to a larger conventional reactor with the same throughput. In theory, there is no limit to the number of reactors that may be integrated into one system.

The process may also utilize a regular mass flow or pressure controller to more accurately deliver appropriate process demanded flow rates. The gaseous species may be transferred to the deposition chamber in a continuous flow or in a pulsed flow.

The process may in some embodiments utilize regular tubing without the need of special heating of the tubing as is the case in many liquid source CVD processes in which heating the tubing lines is essential to eliminate source vapour condensation, or earlier decomposition of the source.

### Carbon Doping of the Silicon Substrate

In one embodiment, the silicon solar cell comprising a carbon-doped silicon substrate is prepared by depositing on the silicon substrate an antireflective and passivation layer comprising silicon and carbon such that carbon diffuses from the layer into the substrate.

Diffusion of the carbon from the layer to the substrate can be carried out, for example, by heating the substrate and the antireflective and passivation layer following deposition of the layer onto the substrate. Diffusion of carbon may be dictated by the temperature at which the heating is carried out, and the duration the heating is maintained. Accordingly, the proper temperature and duration can be determined for a desired level of carbon diffusion. In one embodiment, diffusion is achieved by heating to a temperature of from about 450° C. to about 1000° C., for example from about 450° C. to about 850° C., or from about 700° C. to 1000° C. In one embodiment, heating is maintained for at least about 1 minute, for example from 1 to 3 minutes, although the time for which a specific temperature is maintained may be less than 1 minute. In some embodiments, the diffusion is achieved by applying different temperatures for different times i.e. diffusion occurs by heating according to a time/temperature profile.

Diffusion of carbon into the substrate by way of the antireflective layer may avoid disadvantages that would be expected from other methods that might be used to introduce carbon into the substrate, such as the substrate damage that would be expected should carbon be introduced by way of an ion implantation procedure, although such an ion implantation procedure may also be included in embodiments of the present application.

In a further embodiment, the solar cell comprises one or more metal contacts, and the formation of the one or more metal contacts and the diffusion of the carbon from the antireflective and passivation layer into the substrate occurs in a single step. It has now been discovered that the time-temperature profile needed to diffuse carbon from a SiCN films can lie within the processing requirements to make metal contacts to the solar cell (see e.g. FIG. 41). The combined contact formation and carbon diffusion can, for example, occur at a temperature of from about 450° C. to about 850° C., e.g. from about 450° C. to about 800° C., or from about 575° C. to about 800° C.

### EXAMPLES

The following examples are provided to illustrate the invention. It will be understood, however, that the specific details given in each example have been selected for purpose of illustration and are not to be construed as limiting the scope of the invention. Generally, the experiments were conducted under similar conditions unless noted.

Unless stated otherwise, the antireflective coatings were deposited using a “Coyote” PECVD system manufactured by Pacific Western. The PECVD deposition was carried out at a substrate temperature of 425° C. to 475° C., a pressure of 2 Torr, a power between 100 and 300 W, and an RF power frequency of 50 kHz. The flow of gaseous organosilicon compound into the PECVD instrument was maintained at 300 sccm (silane equivalent mass flow conditions), and the flow of ammonia was maintained between 1500-4500 sccm.

Optical properties of the dielectric films were characterized by a spectroscopic ellipsometer (Woollam Co.). The composition of the dielectric films was analyzed by XPS (X-ray photoelectron spectroscopy), Auger Electron Spectroscopy (Auger), or Elastic Recoil Detection (ERD). Saw damage on the as-cut wafers was removed by etching in potassium hydroxide (KOH) solution followed by anisotropic etching in the mixture of KOH and isopropyl alcohol (IPA) for texturing. The textured silicon wafers were cleaned in 2:1:1 H₂O:H₂O₂:H₂SO₄ and 2:1:1 H₂O:H₂O₂:HCl solutions followed by phosphorus diffusion in a quartz tube to form the emitters.

For comparative purposes, conventional SiNₓ AR coatings were also prepared. The thickness of the SiNx layer, unless noted otherwise, was about 75 nm and had a refractive index of ˜2.05. The SiNx coating was also deposited in the low-frequency (50 KHz) PECVD reactor (Coyote). The SiNx depositions were made at a SiH₄:NH₃ ratio of 300:3000 sccm.

Unless noted otherwise, silicon carbonitride films from PDMS were prepared using ammonia and gas generated from a solid polydimethylsilane (PDMS) source. The solid source was heated inside a sealed pressure vessel. The gas evolved from the PDMS was supplied to the PECVD reactor via standard silane mass flow controllers (MFC) and flow was controlled assuming the same correction factor as for silane.

The carrier lifetimes in the wafers and emitter saturation current density (J_{oE}) of the diffused emitters were measured using Sinton's quasi-steady-state photoconductance (QSSPC) tool. The charge density in the dielectrics was measured using SemiTest SCA-2500 surface charge analyzer, which allows contactless and non-destructive measurement of the flat band equivalent charge density (Q_{FB}, the total charge density at the flat band condition) in the dielectric of interest. The front and rear contacts were formed by screen-printing appropriate pastes, followed by firing in an IR metal belt furnace.

The hydrogen concentration in the SiCₓN_{y} films was measured by Elastic Recoil Detection (ERD).

The efficiency of the solar cells was measured using a custom-made I-V system, with the solar cell illuminated at 1,000 W/m². The cell was kept at 25° C. The equipment was calibrated with a solar cell obtained from the National Renewable Energy Laboratory of the US Department of Energy.

### Example 1

A SiCxNy front-side passivation and anti-reflection coating (ARC) was deposited on textured 5″ 2 Ω·cm boron doped p-type CZ (Czochralski) mono-crystalline Si solar cells (oxygen concentration of 1.1×10¹⁸/cm³) with 60 Ohm/sq n+POOL emitters. Separate cells were prepared with SiH₄-based SiNx coatings for comparison purposes. Front side contacts for the cells were prepared with a commercially available silver paste (Five star S546B).

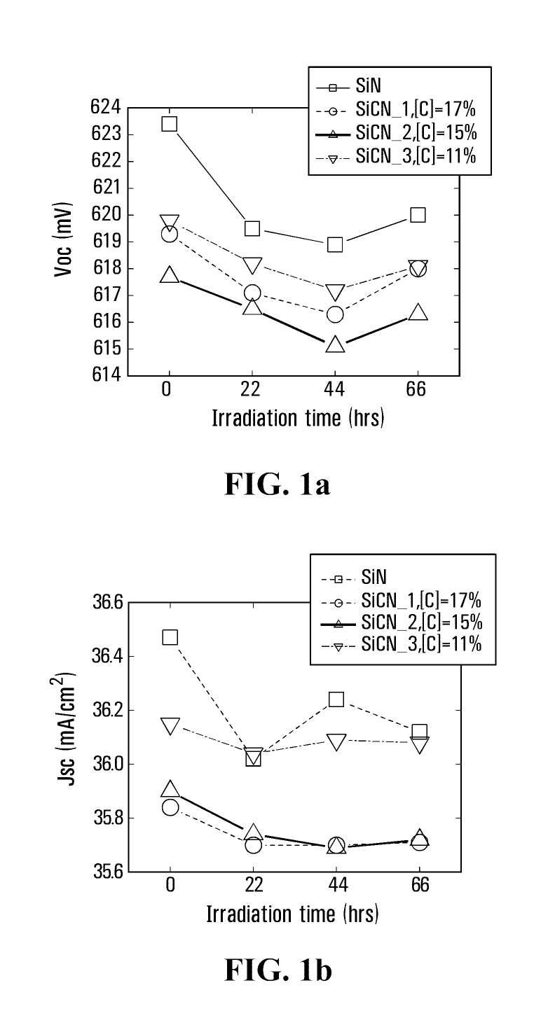

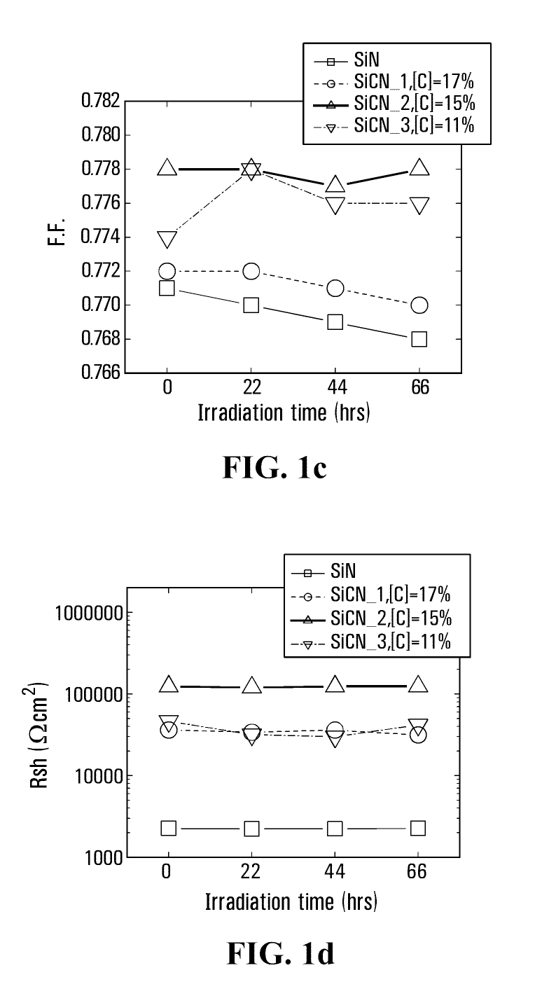

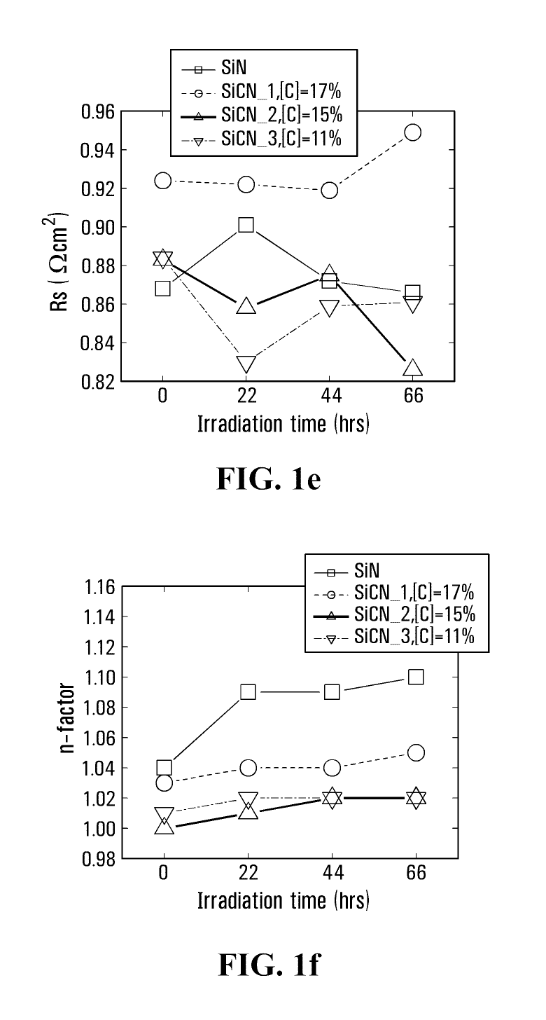

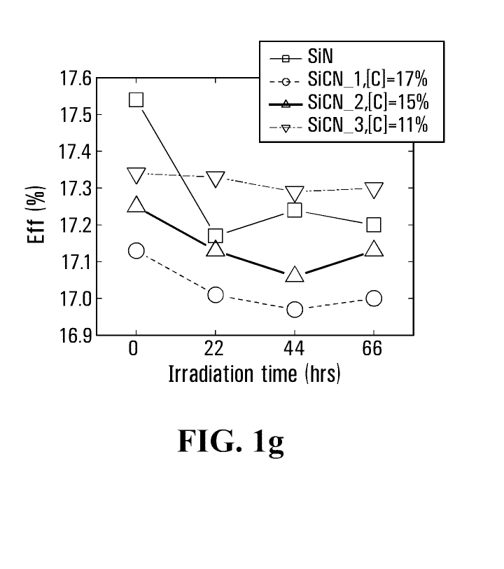

The deposition conditions and film properties are summarized in Table 1, and the cell parameters are shown in Table 2 and in FIGS. 1a-g.

The SiCN(3) ARC was deposited at 475° C. with a precursor gas obtained from thermal decomposition of PDMS (300 sccm) and NH₃ (3750 sccm) to obtain a while SiNₓ was deposited at 425° C. with silane (300 sccm) and NH₃ (3000 sccm). These ARCs were deposited at thicknesses of about 80 nm.

The SiCxNy and SiNx coated cells were exposed, in open air, to 300 W halogen lamps at 6 inch spacing, to give an illumination with light intensity of about 100 mW/cm². Cells were exposed up to 66 hours.

The degradation of Voc (open circuit voltage) after 66 hours of illumination was about 3.4 mV for SiNx coated cell, while Voc degraded only 1.3 to 1.7 mV for the SiCN deposited solar cells.

The degradation of Jsc (short circuit current) after 66 hours of illumination was about 0.35 mA/cm² for SiNx coated cell, while Jsc degraded only 0.07 to 0.18 mA/cm² for SiCN deposited solar cells.

A gradual degradation of FF (Fill Factor) during the 66 hours of illumination was observed for SiNx coated cell, while there was no substantial degradation to FF for SiCN deposited solar cells.

The ideality factor (n-factor) appeared to increase for both SiNx and SiCxNy coated cells upon illumination. However, the relative change in n-factor for SiCxNy coated cells was smaller than that of SiNx coated cell. Higher n-factor values of SiNx coated cell may indicate a higher junction recombination caused by light induced degradation upon illumination. The degradation of solar cell efficiency after 66 hours of illumination was about 0.34% for SiNx coated cell, while efficiency degraded only about 0.04 to 0.13% for SiCxNy deposited solar cells.

Better LID performance was also observed for SiCxNy coatings having a higher density and a lower carbon content.

TABLE 1
Deposition condition and film properties

| | Si-gas | NH3 | | Power | | Auger [C] | Auger [N] | Auger [O] | Auger [Si] | Density |
|---|---|---|---|---|---|---|---|---|---|---|
| Cell name | (sccm) | (sccm) | Temp | (W) | R.I | at. % | at. % | at. % | at. % | (g/cc) |
| SIN | 300 | 3000 | 425 | 100 | 2.03 | 0.1 | 60.4 | 0.6 | 38.9 | 2.54 |
| SICN-1 | 300 | 3000 | 425 | 250 | 1.96 | 17.0 | 50.4 | 0.1 | 32.4 | 2.33 |
| SICN-2 | 300 | 3250 | 475 | 250 | 1.95 | 14.6 | 51.9 | 0.3 | 33.2 | 2.42 |
| SICN-3 | 300 | 3500 | 475 | 250 | 1.94 | 11.4 | 54.6 | 0.2 | 33.8 | 2.64 |

TABLE 2
Post illumination cell parameters

| | Illum. | Area | Voc | Jsc | | | n- | Rseries | Rshunt |
|---|---|---|---|---|---|---|---|---|---|
| Cell Name | (h) | (cm²) | (mV) | (mA/cm²) | FF | Eff (%) | factor | (Ωcm²) | (Ωcm²) |
| SIN | 0 | 149 | 623.4 | 36.47 | 0.771 | 17.54 | 1.04 | 0.868 | 2268 |
| SIN | 22 | 149 | 619.5 | 36.02 | 0.770 | 17.17 | 1.09 | 0.901 | 2230 |
| SIN | 46 | 149 | 618.9 | 36.24 | 0.769 | 17.24 | 1.09 | 0.872 | 2233 |
| SIN | 66 | 149 | 620.0 | 36.12 | 0.768 | 17.20 | 1.10 | 0.866 | 2265 |
| Delta (66h-0h) | | | −3.4 | −0.35 | −0.003 | −0.34 | 0.06 | −0.001 | −3 |
| SICN-1 | 0 | 149 | 619.3 | 35.84 | 0.772 | 17.13 | 1.03 | 0.924 | 36343 |
| SICN-1 | 22 | 149 | 617.1 | 35.70 | 0.772 | 17.01 | 1.04 | 0.922 | 34021 |
| SICN-1 | 46 | 149 | 616.3 | 35.70 | 0.771 | 16.97 | 1.04 | 0.919 | 36168 |
| SICN-1 | 66 | 149 | 618.0 | 35.71 | 0.770 | 17.00 | 1.05 | 0.949 | 31569 |
| Delta (66h-0h) | | | −1.3 | −0.13 | −0.002 | −0.13 | 0.02 | 0.025 | −4774 |
| SICN-2 | 0 | 149 | 617.7 | 35.90 | 0.778 | 17.25 | 1.00 | 0.883 | 124174 |
| SICN-2 | 22 | 149 | 616.5 | 35.74 | 0.778 | 17.13 | 1.01 | 0.858 | 120168 |
| SICN-2 | 46 | 149 | 615.1 | 35.69 | 0.777 | 17.06 | 1.02 | 0.875 | 124177 |
| SICN-2 | 66 | 149 | 616.3 | 35.72 | 0.778 | 17.13 | 1.02 | 0.826 | 124172 |
| Delta (66h-0h) | | | −1.4 | −0.18 | 0.000 | −0.12 | 0.02 | −0.057 | −2 |
| SICN-3 | 0 | 149 | 619.8 | 36.15 | 0.774 | 17.34 | 1.01 | 0.884 | 46565 |
| SICN-3 | 22 | 149 | 618.2 | 36.04 | 0.778 | 17.33 | 1.02 | 0.830 | 31840 |
| SICN-3 | 46 | 149 | 617.2 | 36.09 | 0.776 | 17.29 | 1.02 | 0.859 | 30043 |
| SICN-3 | 66 | 149 | 618.1 | 36.08 | 0.776 | 17.30 | 1.02 | 0.861 | 41856 |
| Delta (66h-0h) | | | −1.7 | −0.07 | 0.002 | −0.04 | 0.01 | −0.023 | −4709 |

### Example 2

SiCxNy front-side passivation and anti-reflection coatings were deposited on textured Cz substrates with 60 Ohm/sq emitters to form Si solar cells. Cells were prepared with high (2 Ω·cm) and low (0.9 Ω·cm) base resistivity Cz—Si wafers. Separate cells were also prepared with SiH₄-based SiNx coatings for comparison purposes.

To study light induced degradation characteristics of these cells, they were illuminated with a light intensity simulated to be close to 1 sun conditions.

Degradation of solar cell conversion efficiency, after 77 hours of illumination, was observed to be about 0.36% for SiNx coated cell, while efficiency degraded only 0.09% for SiCxNy coated cells on the low-resistivity Cz—Si materials (i.e. 0.9 Ω·cm). Spectral response spectra show that for both types of solar cells, LID occurs in the long wavelength response from 800 nm to 1100 nm, suggesting that the degradation is a result of the decrease in the bulk carrier lifetime.

For the 2 Ω·cm substrates, a degradation in conversion efficiency, after 77 hours of illumination, was observed to be about 0.29% for SiNx coated cell, while efficiency degraded only 0.09% for SiCxNy coated cells. The SiCxNy coated solar cell also had less reduction in spectral response after light illumination of 77 hours than SiNx coated cells in the long wavelength from 800 nm to 1100 nm, indicating that the light induced degradation of SiCxNy coated cells is less than that of SiNx coated cells.

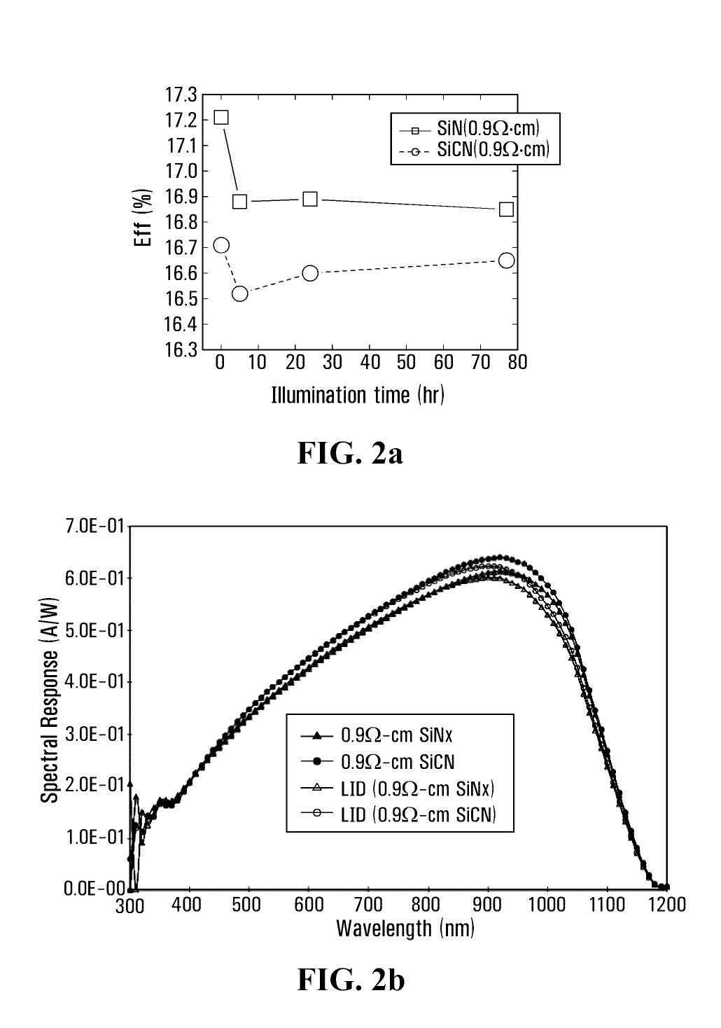

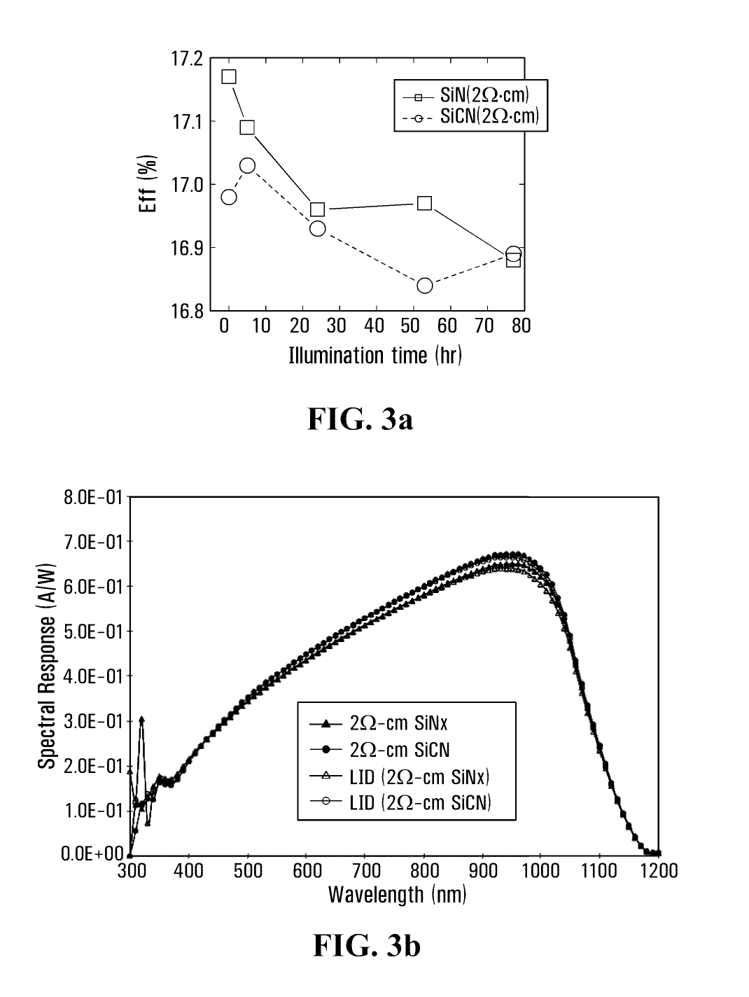

In terms of LID, SiCxNy coated CZ solar cells performed better than SiNx coated CZ Si solar cells for both low resistivity (0.9 Ω·cm) and high resistivity (2 Ω·cm) Cz—Si substrates. The deposition conditions and film properties for the prepared solar cells are provided in Table 3, and the cell parameters following illumination are shown in Table 4 and FIGS. 2a, 2b, 3a, 3b, 3c and 3d.

TABLE 3
Deposition conditions and film properties

| | | | | | | Auger | | | | |
|---|---|---|---|---|---|---|---|---|---|---|
| | Si-Gas | NH3 | | Power | | [C] | Auger | Auger | Auger | Density |
| | (sccm) | (sccm) | Temp | (W) | R.I | at. % | [N] at. % | [O] at. % | [Si] at. % | (g/cc) |
| SIN | 300 | 3000 | 425 | 100 | 2.03 | 0.1 | 60.4 | 0.6 | 38.9 | 2.54 |
| SiCN | 300 | 3750 | 475 | 250 | 1.94 | 11.4 | 54.6 | 0.2 | 33.8 | 2.64 |

TABLE 4
Post illumination solar cell parameters

| | | | | | | | | | Base |
|---|---|---|---|---|---|---|---|---|---|
| Cell | Illum. | Voc | Jsc | | | n | Rseries | Rshunt | resistivity |
| Name | time | (mV) | (mA/cm²) | FF | Eff (%) | factor | (Ωcm²) | (Ωcm²) | (Ωcm) |
| SiN | | | | | | | | | 0.9 |
| (0.9 Ωcm) | | | | | | | | | |
| | 0 | 629.3 | 35.36 | 0.773 | 17.21 | 1.11 | 0.843 | 1367 | |
| | 5 | 623.7 | 34.93 | 0.775 | 16.88 | 1.10 | 0.814 | 1346 | |
| | 24 | 623.2 | 35.03 | 0.774 | 16.89 | 1.10 | 0.815 | 1371 | |
| | 53 | 622.8 | 34.93 | 0.776 | 16.89 | 1.11 | 0.756 | 1361 | |
| | 77 | 623.2 | 34.91 | 0.775 | 16.85 | 1.11 | 0.796 | 1363 | |
| delta (77-0h) | | −6.1 | −0.45 | 0.001 | −0.36 | 0.00 | −0.048 | −4 | |
| SiCN (0.9 Ωcm) | | | | | | | | | 0.9 |
| | 0 | 620.8 | 35.12 | 0.766 | 16.71 | 1.10 | 0.970 | 8297 | |
| | 5 | 617.1 | 34.82 | 0.769 | 16.52 | 1.09 | 0.896 | 8223 | |
| | 24 | 616.9 | 34.93 | 0.770 | 16.60 | 1.09 | 0.898 | 8987 | |
| | 53 | 615.2 | 34.84 | 0.766 | 16.42 | 1.06 | 1.006 | 8142 | |
| | 77 | 617.7 | 34.81 | 0.774 | 16.65 | 1.10 | 0.812 | 8343 | |
| delta (77-0h) | | −3.1 | −0.32 | 0.008 | −0.06 | 0.00 | −0.158 | 46 | |
| SiN-1 (2 Ωcm) | | | | | | | | | 2 |
| | 0 | 623.1 | 35.49 | 0.776 | 17.17 | 1.03 | 0.928 | 2030 | |
| | 5 | 622.4 | 35.51 | 0.774 | 17.09 | 1.05 | 0.909 | 1930 | |
| | 24 | 620.5 | 35.45 | 0.771 | 16.96 | 1.06 | 0.931 | 1944 | |
| | 53 | 619.9 | 35.51 | 0.771 | 16.97 | 1.07 | 0.928 | 1886 | |
| | 77 | 620.0 | 35.48 | 0.768 | 16.88 | 1.07 | 0.973 | 1904 | |
| delta (77-0h) | | −3.1 | −0.01 | −0.009 | −0.29 | 0.04 | 0.044 | −126 | |
| SiN-2 (2 Ωcm) | | | | | | | | | 2 |
| | 0 | 623.1 | 35.85 | 0.778 | 17.37 | 1.03 | 0.817 | 2103 | |
| | 5 | 622.3 | 35.79 | 0.781 | 17.39 | 1.05 | 0.757 | 1988 | |
| | 24 | 620.7 | 35.76 | 0.776 | 17.21 | 1.06 | 0.849 | 1950 | |
| | 53 | 620.0 | 35.75 | 0.771 | 17.10 | 1.08 | 0.854 | 2006 | |
| | 77 | 620.2 | 35.75 | 0.771 | 17.10 | 1.07 | 0.894 | 1959 | |
| Delta (77-0h) | | −2.9 | −0.10 | −0.006 | −0.27 | 0.04 | 0.077 | −144 | |
| SiCN (2 Ωcm) | | | | | | | | | 2 |
| | 0 | 618.8 | 35.35 | 0.776 | 16.98 | 1.03 | 0.886 | 15785 | |
| | 5 | 618.0 | 35.28 | 0.781 | 17.03 | 1.04 | 0.734 | 15051 | |
| | 24 | 616.8 | 35.34 | 0.776 | 16.93 | 1.04 | 0.844 | 18306 | |
| | 53 | 617.2 | 35.38 | 0.771 | 16.84 | 1.05 | 0.905 | 17780 | |
| | 77 | 617.1 | 35.33 | 0.775 | 16.89 | 1.05 | 0.872 | 16196 | |
| delta (77-0h) | | −1.7 | −0.02 | −0.002 | −0.09 | 0.02 | −0.014 | 411 | |

### Example 3

Silicon solar cells were prepared with SiCxNy or SiNx front-side passivation and anti-reflection coatings on 5″ p-type Cz wafers, with diffused emitters of about 65 Ohm/sq. The SiCxNy coatings were deposited by PECVD of a gas mixture obtained from polydimethylsilane (PDMS), while the SiNx coatings were obtained by PECVD of a mixture of silane and methane. Both PECVD depositions were carried out with a Coyote direct plasma system. The efficiency for the cells was about 14%.

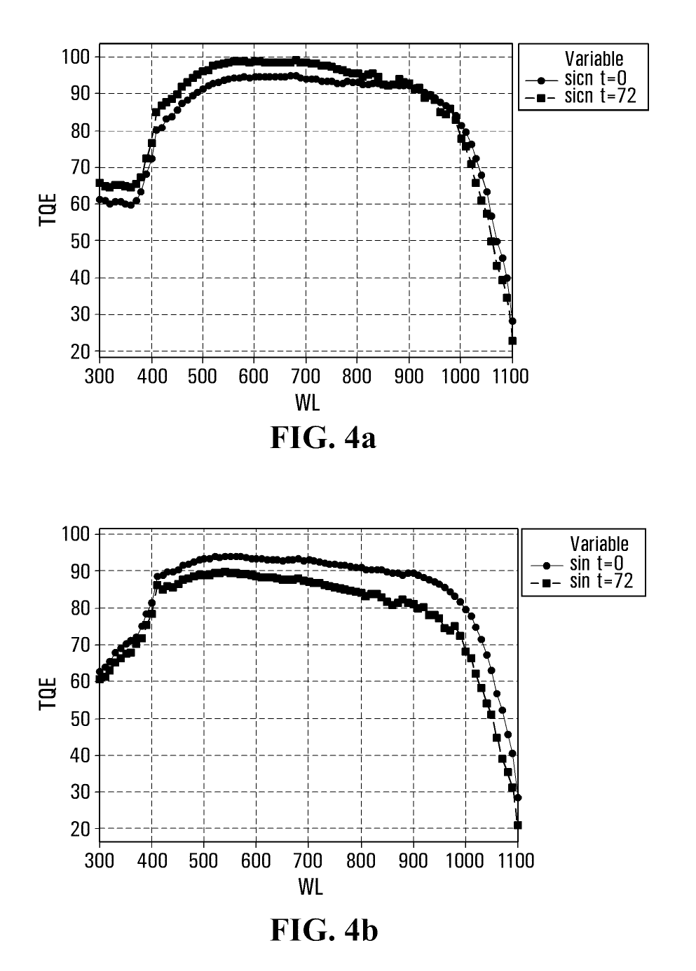

The solar cells were illuminated with an array of six 500 W lamps with a distance of about 40 cm, providing a light intensity of about 1 sun. The cells were also heated to a temperature of 50° C. Illumination was carried out for a period of 72 hours, and the internal quantum efficiency results (pre- and post-illumination) are shown in Table 5 and FIGS. 4a and 4b.

The I-V curves for the solar cells were measured using a model IV16 from PV measurements, Inc., with solar stimulation non-uniformity better than +/−5% over a 16×16 cm region. The solar cell Spectral Response QE measurement system, model QEX7 from PV Measurements was also used for reflectance and IQE measurements at wavelengths of from 300-1100 nm, with results uncertainty of +/−2%. Film characteristics were also measured by SE ellipsometry, mass density (XRR), chemical composition (Auger spectroscopy, SIMS).

From FIGS. 4a and 4b, it can be seen that the internal quantum efficiency (IQE) of the solar cell bearing a SiN ARC decreases following illumination, while the IQE improves for the SiCN ARC bearing solar cell.

TABLE 5
Cell Parameters

| | | Voc | J_{sc} | Fill | Efficiency | Area |
|---|---|---|---|---|---|---|
| Sample | Date | (volts) | (mA/cm2) | factor | (%) | (cm²) |
| CT-SiN-2 | 08-Jul-09 | 0.6223 | 35.85 | 63.97 | 14.27 | 149 |
| CT-SiCN-6 | 08-Jul-09 | 0.6151 | 35.57 | 63.64 | 13.92 | 149 |

TABLE 6
Pre- and post-illumination internal quantum efficiency (IQE) for SiCN

| | SiCN, | SiCN, |
|---|---|---|
| λ (nm) | t = 0 hr | t = 72 hr |
| 300 | 61.1 | 65.8 |
| 310 | 60.7 | 64.7 |
| 320 | 60.1 | 64.6 |
| 330 | 60.5 | 65.0 |
| 340 | 60.5 | 65.1 |
| 350 | 60.0 | 64.9 |
| 360 | 59.7 | 64.5 |
| 370 | 60.9 | 65.5 |
| 380 | 63.4 | 67.2 |
| 390 | 68.1 | 72.2 |
| 400 | 72.2 | 76.4 |
| 410 | 80.0 | 84.8 |
| 420 | 80.7 | 86.6 |
| 430 | 83.0 | 87.8 |
| 440 | 83.7 | 88.6 |
| 450 | 85.4 | 89.7 |
| 460 | 87.2 | 91.9 |
| 470 | 88.3 | 93.0 |
| 480 | 89.4 | 94.4 |
| 490 | 90.3 | 95.2 |
| 500 | 91.3 | 96.0 |
| 510 | 92.0 | 96.5 |
| 520 | 92.9 | 97.4 |
| 530 | 93.1 | 97.7 |
| 540 | 93.7 | 98.2 |
| 550 | 93.9 | 98.4 |
| 560 | 94.1 | 98.6 |
| 570 | 94.2 | 98.8 |
| 580 | 94.4 | 98.8 |
| 590 | 94.4 | 98.5 |
| 600 | 94.4 | 98.7 |
| 610 | 94.7 | 98.8 |
| 620 | 94.4 | 98.5 |
| 630 | 94.4 | 98.6 |
| 640 | 94.5 | 98.6 |
| 650 | 94.5 | 98.3 |
| 660 | 94.7 | 98.4 |
| 670 | 94.7 | 98.5 |
| 680 | 95.0 | 99.0 |
| 690 | 94.2 | 98.4 |
| 700 | 94.1 | 98.5 |
| 710 | 93.9 | 98.3 |
| 720 | 93.8 | 98.1 |
| 730 | 93.4 | 97.6 |
| 740 | 93.5 | 97.4 |
| 750 | 93.2 | 97.2 |
| 760 | 92.9 | 96.7 |
| 770 | 92.7 | 96.4 |
| 780 | 93.3 | 95.8 |
| 790 | 93.1 | 95.6 |
| 800 | 93.1 | 95.3 |
| 810 | 92.5 | 94.4 |
| 820 | 92.6 | 95.2 |
| 830 | 92.9 | 95.5 |
| 840 | 92.8 | 94.5 |
| 850 | 92.4 | 92.6 |
| 860 | 92.0 | 92.1 |
| 870 | 92.3 | 92.5 |
| 880 | 92.1 | 94.0 |
| 890 | 92.2 | 92.9 |
| 900 | 92.2 | 92.7 |
| 910 | 91.5 | 91.2 |
| 920 | 91.0 | 91.7 |
| 930 | 90.4 | 88.9 |
| 940 | 89.7 | 89.4 |
| 950 | 88.8 | 88.2 |
| 960 | 87.6 | 84.9 |
| 970 | 86.6 | 84.5 |
| 980 | 85.7 | 85.8 |
| 990 | 84.0 | 82.9 |
| 1000 | 81.4 | 77.6 |
| 1010 | 79.5 | 75.7 |
| 1020 | 76.1 | 70.6 |
| 1030 | 72.2 | 65.8 |
| 1040 | 67.8 | 61.0 |
| 1050 | 63.3 | 57.1 |
| 1060 | 56.6 | 49.8 |
| 1070 | 49.8 | 43.1 |
| 1080 | 45.2 | 39.2 |
| 1090 | 39.9 | 34.5 |
| 1100 | 28.0 | 22.8 |

TABLE 7
Pre- and post-illumination internal quantum efficiency (IQE) for SiN

| λ (nm) | SiN t = 0 hr | SiN t = 72 hr |
|---|---|---|
| 300 | 62.7 | 60.4 |
| 310 | 63.9 | 61.1 |
| 320 | 65.5 | 62.9 |
| 330 | 67.7 | 65.0 |
| 340 | 69.0 | 66.3 |
| 350 | 70.3 | 67.6 |
| 360 | 71.0 | 67.8 |
| 370 | 72.1 | 70.2 |
| 380 | 74.9 | 71.6 |
| 390 | 78.4 | 75.4 |
| 400 | 81.2 | 78.2 |
| 410 | 88.5 | 86.1 |
| 420 | 88.8 | 85.1 |
| 430 | 89.7 | 85.9 |
| 440 | 89.8 | 85.7 |
| 450 | 90.5 | 86.4 |
| 460 | 91.4 | 87.5 |
| 470 | 91.8 | 87.9 |
| 480 | 92.6 | 88.5 |
| 490 | 93.0 | 88.8 |
| 500 | 93.2 | 88.7 |
| 510 | 93.2 | 89.0 |
| 520 | 93.8 | 89.4 |
| 530 | 93.8 | 89.4 |
| 540 | 94.0 | 89.6 |
| 550 | 94.0 | 89.4 |
| 560 | 94.0 | 89.5 |
| 570 | 94.0 | 89.2 |
| 580 | 93.7 | 89.2 |
| 590 | 93.4 | 88.7 |
| 600 | 93.4 | 88.7 |
| 610 | 93.4 | 88.4 |
| 620 | 93.1 | 88.2 |
| 630 | 93.1 | 88.2 |
| 640 | 93.1 | 87.9 |
| 650 | 92.8 | 87.6 |
| 660 | 93.0 | 87.7 |
| 670 | 93.0 | 87.7 |
| 680 | 93.3 | 87.9 |
| 690 | 92.7 | 87.3 |
| 700 | 93.0 | 87.2 |
| 710 | 92.6 | 86.9 |
| 720 | 92.4 | 86.6 |
| 730 | 92.1 | 86.3 |
| 740 | 92.0 | 85.9 |
| 750 | 91.8 | 85.6 |
| 760 | 91.4 | 85.3 |
| 770 | 91.5 | 84.9 |
| 780 | 91.2 | 84.6 |
| 790 | 91.0 | 84.2 |
| 800 | 90.8 | 84.0 |
| 810 | 90.3 | 83.0 |
| 820 | 90.2 | 83.7 |
| 830 | 90.4 | 83.8 |
| 840 | 90.2 | 83.0 |
| 850 | 89.8 | 81.7 |
| 860 | 89.4 | 80.9 |
| 870 | 89.5 | 81.4 |
| 880 | 88.9 | 82.3 |
| 890 | 89.4 | 81.4 |
| 900 | 89.3 | 81.1 |
| 910 | 88.8 | 79.8 |
| 920 | 88.3 | 80.1 |
| 930 | 87.8 | 77.9 |
| 940 | 87.1 | 77.9 |
| 950 | 86.4 | 77.1 |
| 960 | 85.4 | 74.4 |
| 970 | 84.4 | 73.8 |
| 980 | 83.2 | 74.9 |
| 990 | 81.6 | 72.4 |
| 1000 | 79.4 | 68.0 |
| 1010 | 77.7 | 66.2 |
| 1020 | 74.7 | 62.0 |
| 1030 | 71.3 | 58.2 |
| 1040 | 67.2 | 53.9 |
| 1050 | 63.0 | 50.9 |
| 1060 | 56.6 | 44.5 |
| 1070 | 52.1 | 38.8 |
| 1080 | 45.6 | 35.4 |
| 1090 | 40.4 | 31.2 |
| 1100 | 28.5 | 20.8 |

### Example 4

The light induced degradation of SiCN and SiN films, measured in terms of IQE differential, was investigated with different substrate materials.

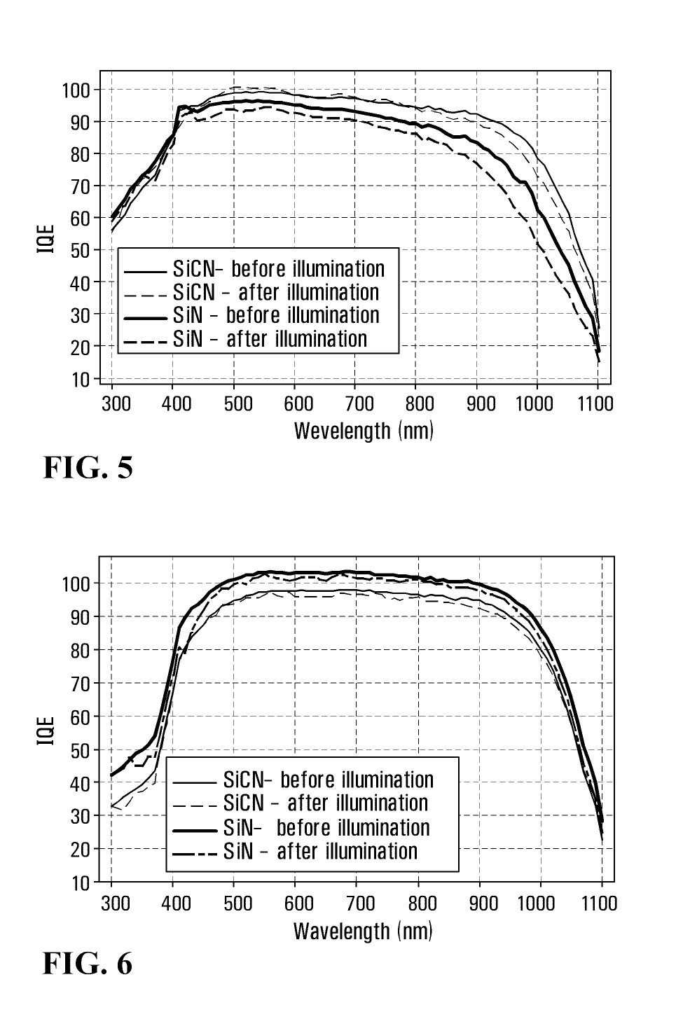

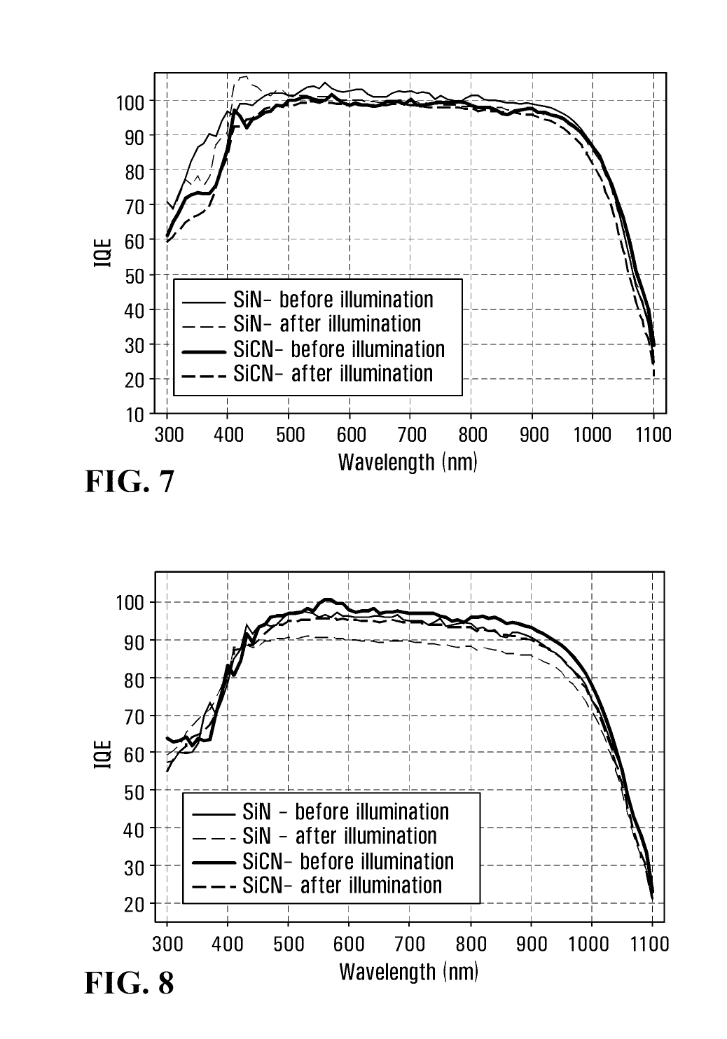

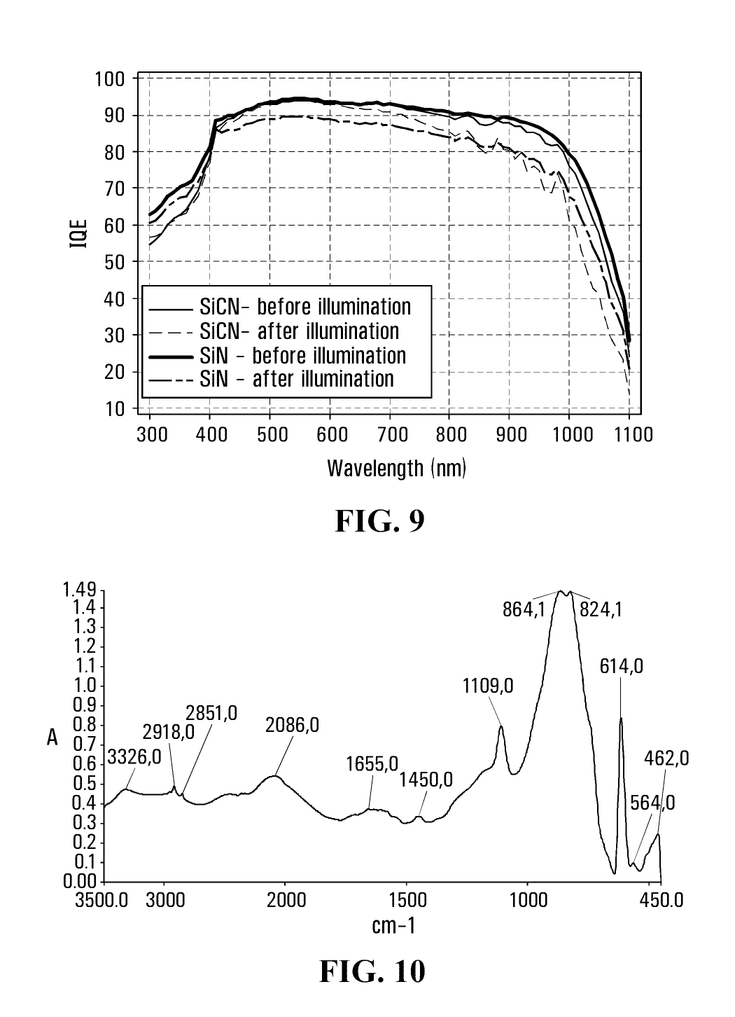

Table 8 provides the characteristics of the silicon substrates. The IQE results are provided in FIGS. 5 to 9.

TABLE 8
Substrate characteristics for FIGS. 5 to 9

| FIG. | Characteristics |
|---|---|
| 5 | Bulk 1 Ohm 19 cm - Emitter 72 Ohm/sq - Oxygen 26.8 ppm |
| 6 | Bulk ~3 Ohm 19 cm - Emitter 53 Ohm/sq - Oxygen 24.2 ppm |
| 7 | Bulk ~5 Ohm 19 cm - Emitter 73 Ohm/sq - Oxygen 17.3 ppm |
| 8 | Bulk ~0.96 Ohm 19 cm - Emitter 65 Ohm/sq |
| 9 | Bulk ~3 Ohm 19 cm - Emitter 60 Ohm/sq |

### Example 5

A SiCN film was deposited on a substrate with a 3MS precursor. A FTIR spectrum of the deposited film is shown in FIG. 10, which spectrum shows the presence of weakly bonded carbon. Characteristics of the deposited film are provided in Table 9.

TABLE 9
SiCN film characteristics

| | Extinction | | | | | |
|---|---|---|---|---|---|---|
| Refractive index | coefficient | Density | [C] | [N] | [O] | [Si] |
| @630 nm | @300 nm | (g/cm³) | at. % | at. % | at. % | at. % |
| 1.96 | 0.016 | 2.7 | 11.2 | 55.7 | 0.8 | 32.3 |

### Example 6

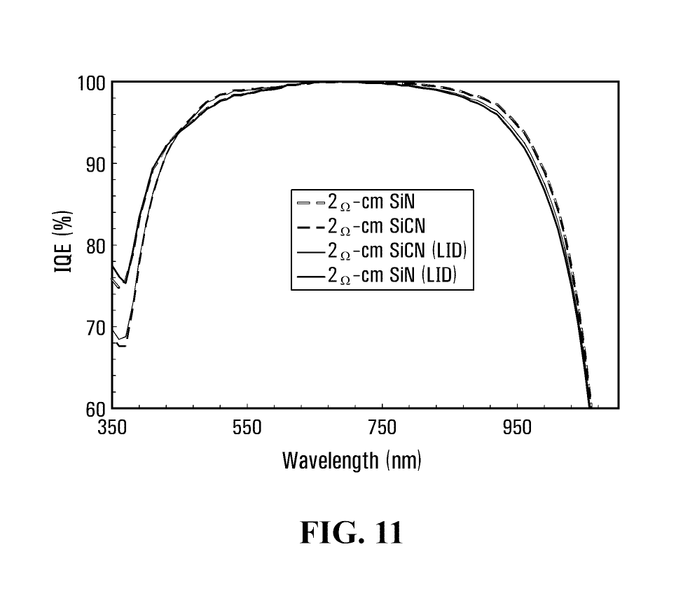

IQE of SiN and SiCN coated solar cells (2 Ω·cm wafers) before and after 72 hours of illumination was measured, and the results are shown in FIG. 11. It is clear, as was shown above, that the long wavelength response degraded after illumination while the short wavelength response is not substantially affect. This is consistent with the assumption that light induced degradation hurts the bulk lifetime. Since LID is a bulk phenomenon shown by IQE, the bulk lifetime of Cz wafers deposited with SiCN and SiN coatings was separately measured.

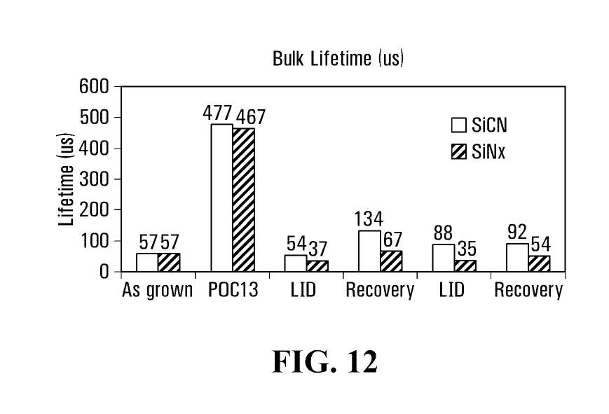

Starting with the same quality wafers, bulk lifetimes were measured. Bulk lifetime was calculated from effective lifetime assuming the surface was well passivated by iodine/methanol immersion. The results are provided in FIG. 12, which shows a variation in bulk lifetime of SiCN coated and SiN coated Cz wafers. The initial lifetime of wafers was about 57 μs and the lifetime significantly increase after POCl₃ diffusion, and then SiCN and SiN films were coated. After a few sequences of illumination of the obtained samples, followed by heating of the sample (to regenerate bulk lifetime values), it is shown that the bulk lifetime of the SiCN coated wafer is higher than that of the SiN coated wafer. The observed trend in bulk lifetime is in line with the observed IQE results, and shows the positive impact of SiCN coating on the bulk lifetime enhancement.

### Example 7

SiCxNy and SiNx passivation and anti-reflection coatings were deposited on textured CZ (Czochralski) mono-crystalline substrates with a base resistivity of 5-7 Ω·cm. The SiCxNy coatings were deposited by PECVD of a gas mixture obtained from the pyrolysis of polydimethylsilane, while the SiNx coatings were obtained by PECVD of a mixture of silane and methane. Deposition of the coatings was carried out using an AK400 PECVD system. Following deposition of the coating, the solar cell was fired at 790° C. for 5 s.

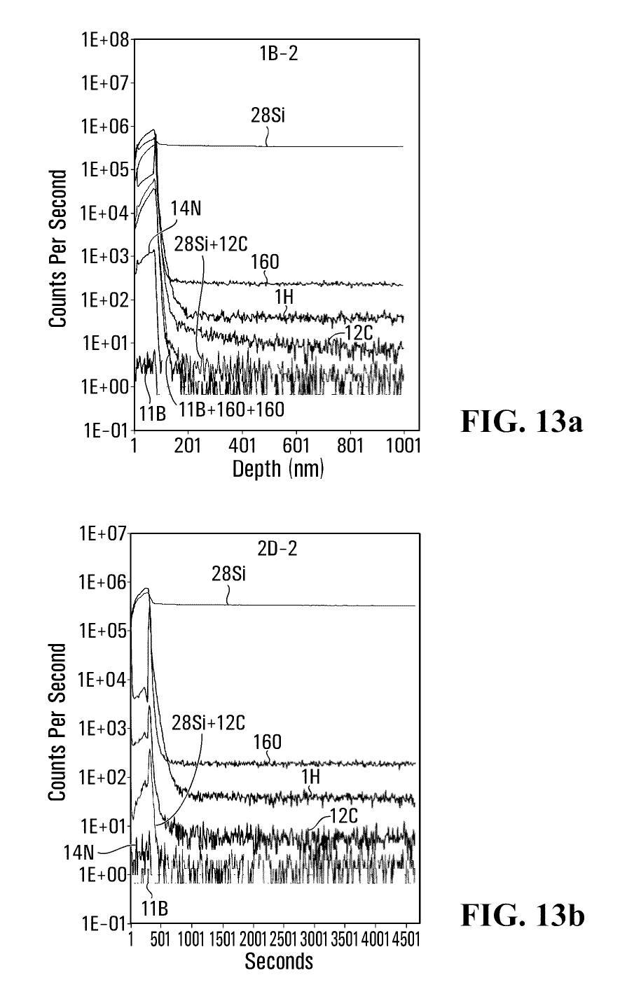

The obtained coated substrates were studied with a dynamic SIMS system, using Caesium beam to evaluate carbon and presence of [C], [B], [O], [N], [Si] elements at particular depths within the cells. The results (FIGS. 13a and 13b) are qualitative and show counts of elements in depth profile. Of the obtained results, the hydrogen concentration signal is believed to be legitimate, the boron concentration signal is low and is believed to be below detection limit (it may suffer from interference), the BO₂ concentration signal is believed to be an artifact, likely a fragment of oxygen with carbon, and the nitrogen signal is not believed to be real, and it is likely a fragment of silicon.

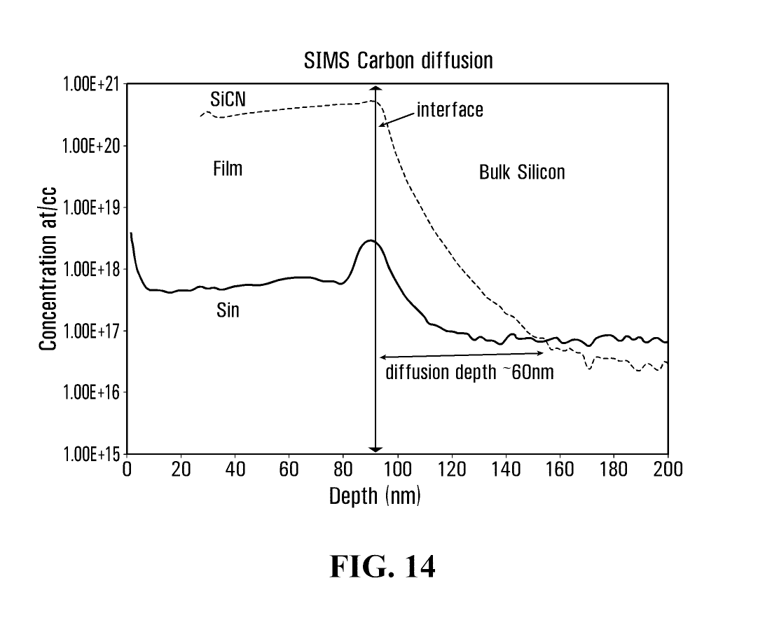

The carbon content inside films and the silicon substrate was estimated based on the obtained SIMS data and is shown in FIG. 14. The results indicate that carbon is diffusing into the silicon substrate from the SiCN film. The carbon concentration profile shows an increase at the interface between the SiCN film and the Si substrate, and then a gradual decrease to at least a depth of about 60 nm.

### Example 8

The light induced degradation of solar cells prepared on different types of silicon substrates (A-E) was studied.

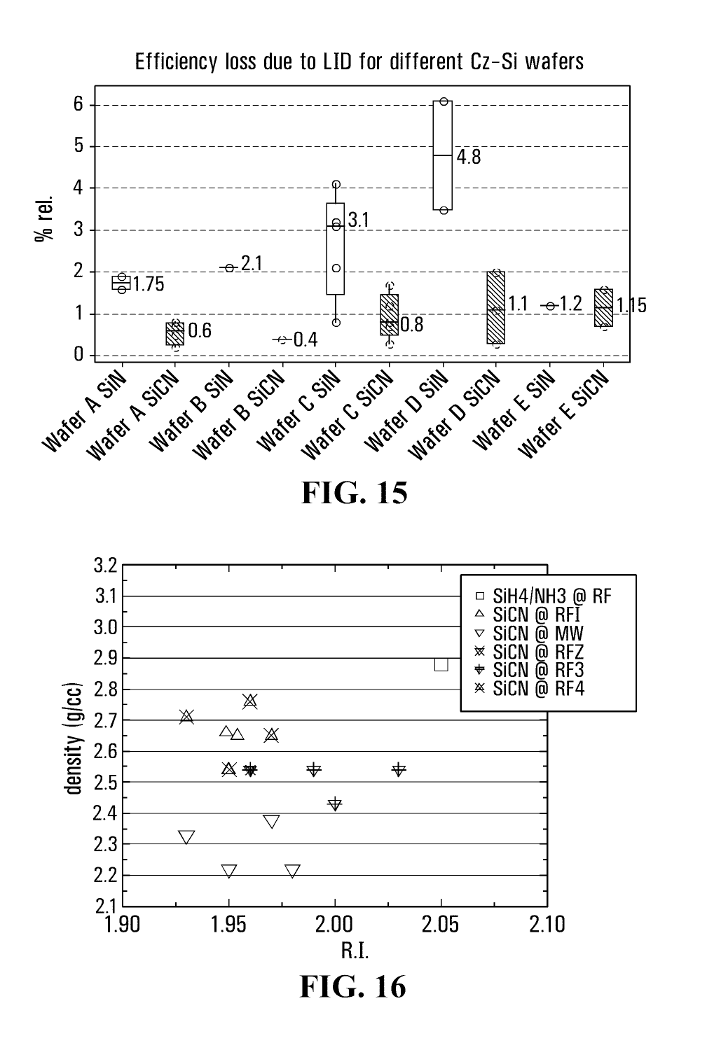

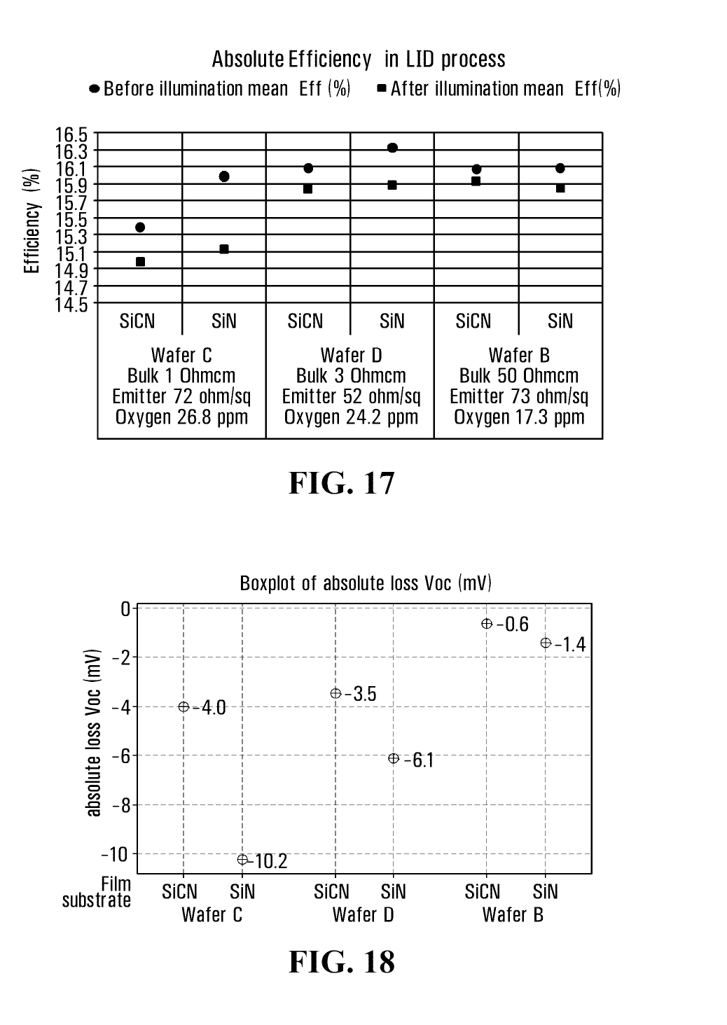

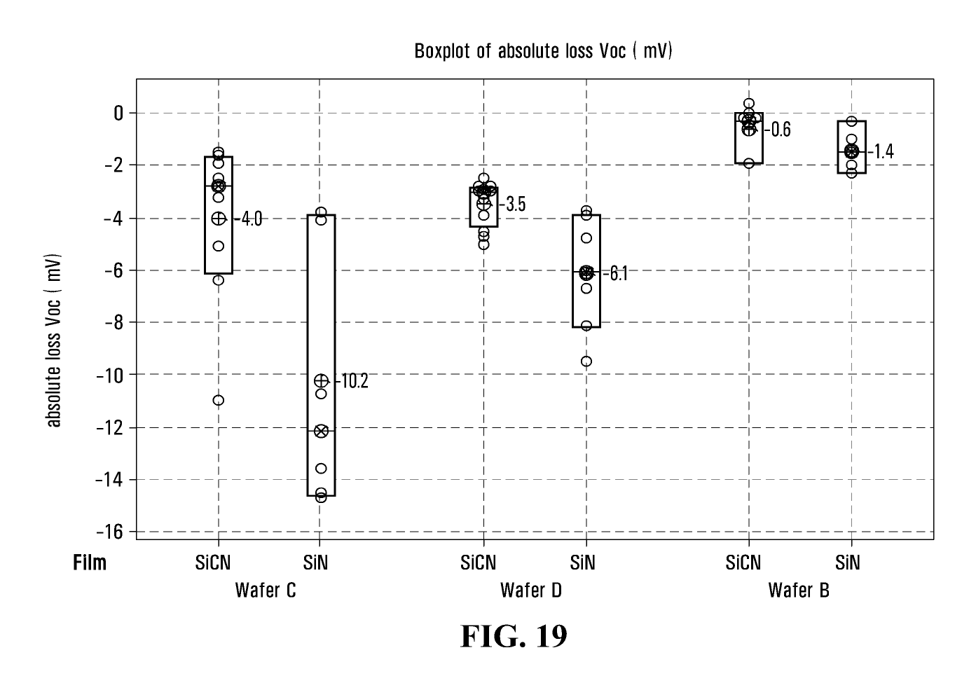

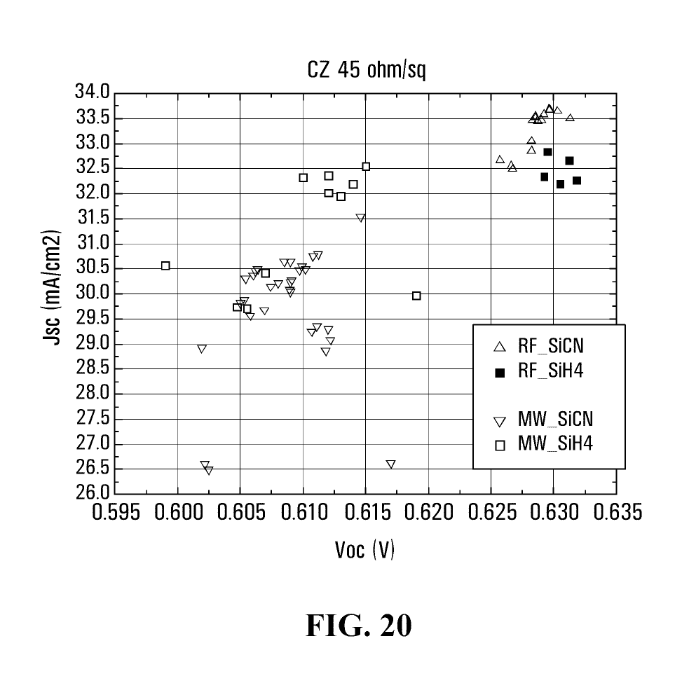

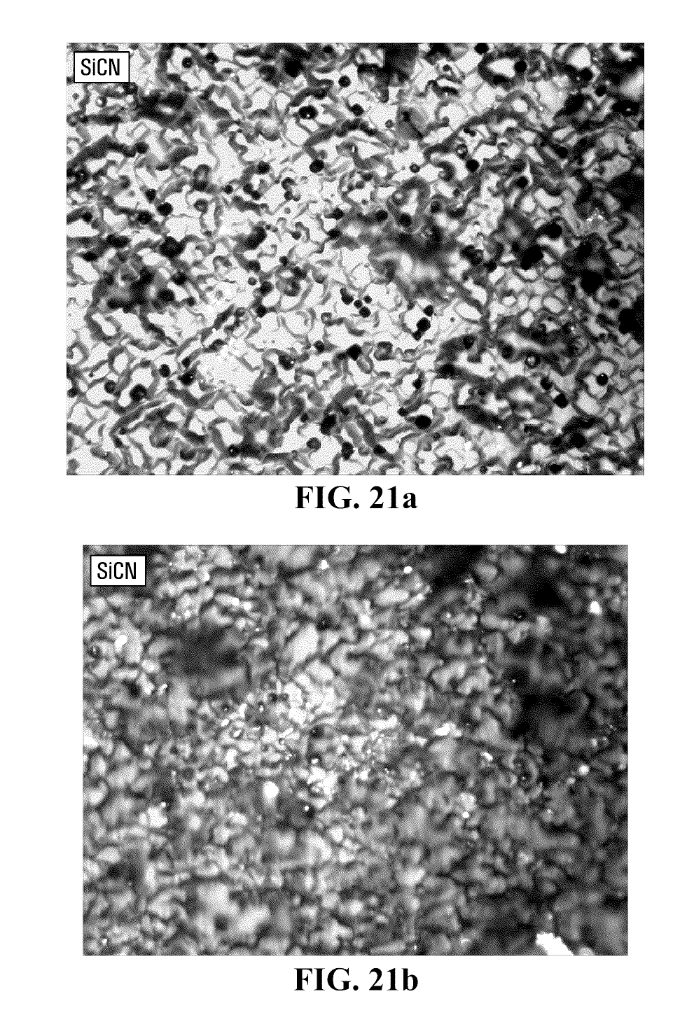

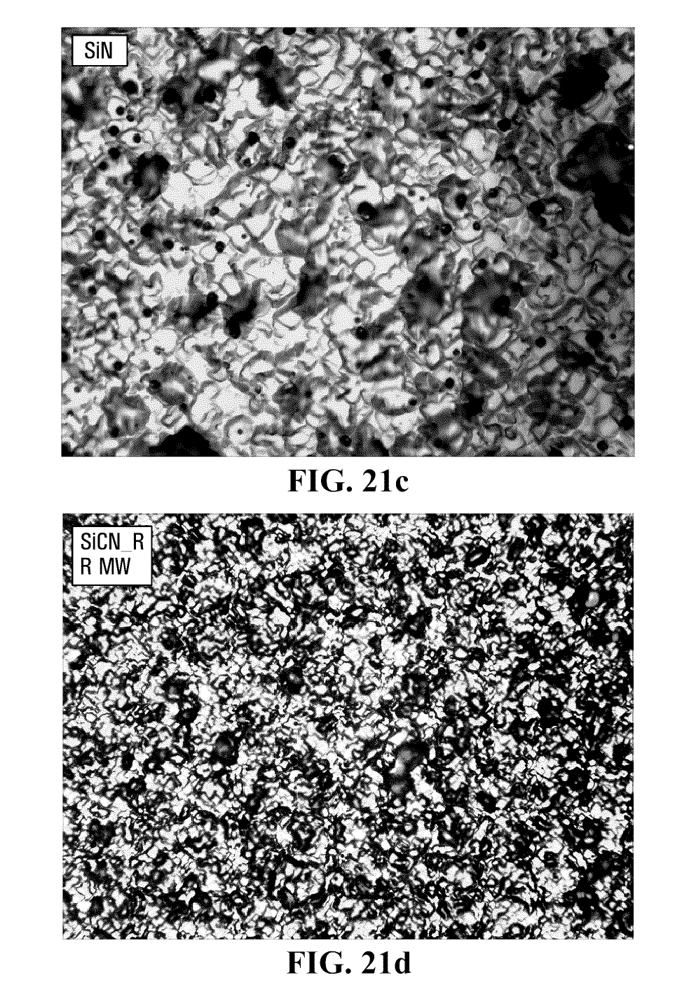

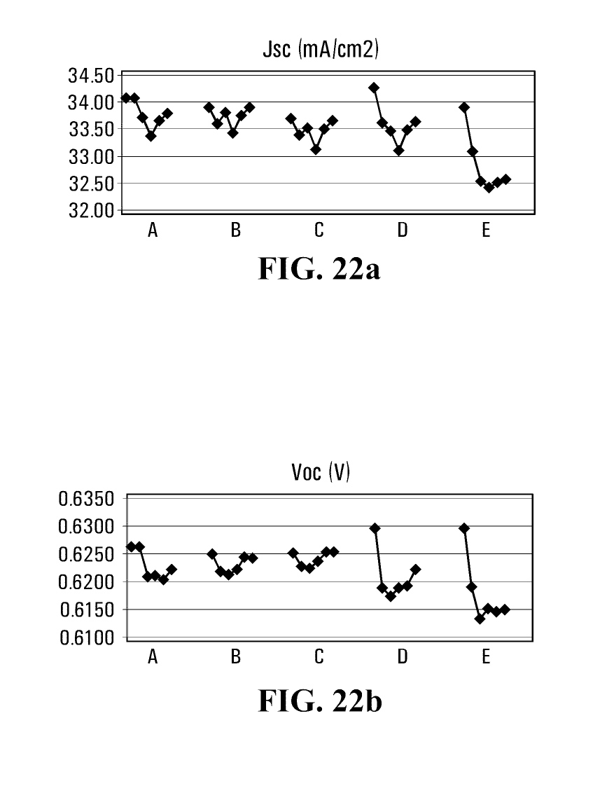

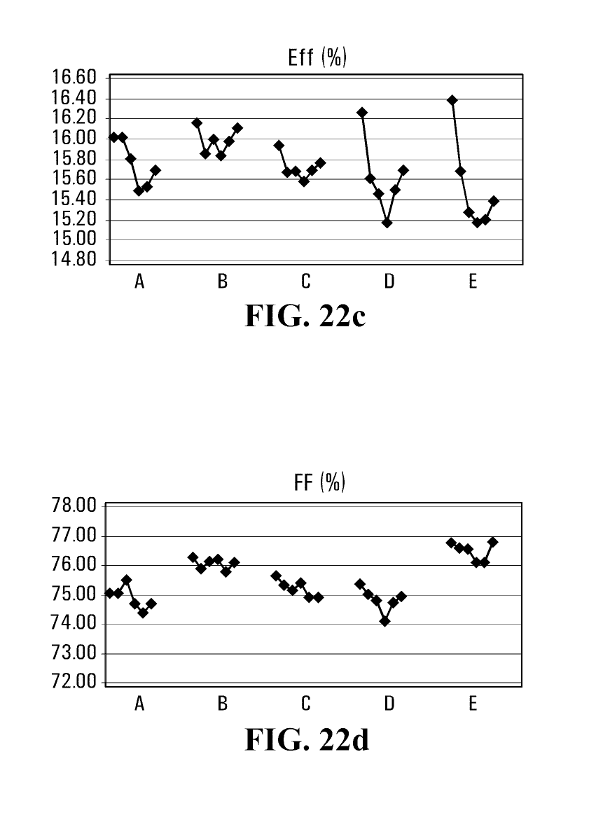

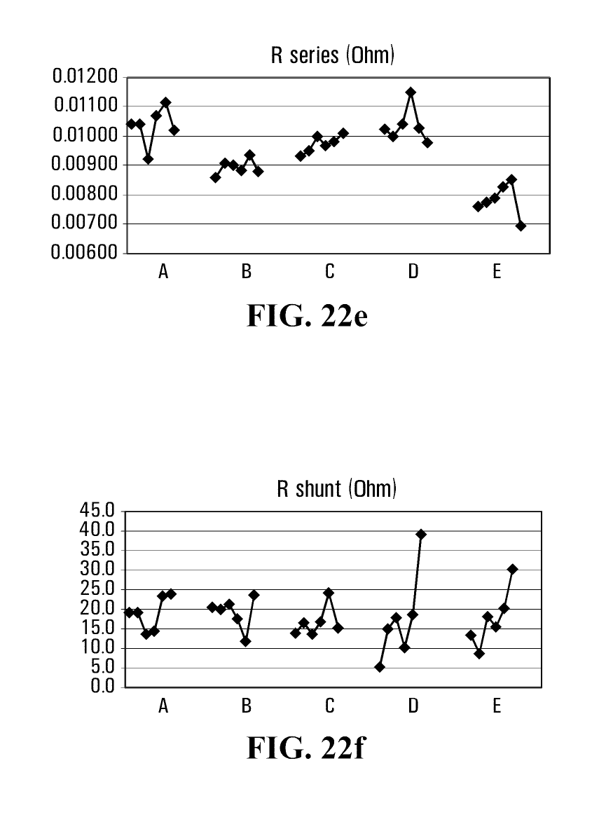

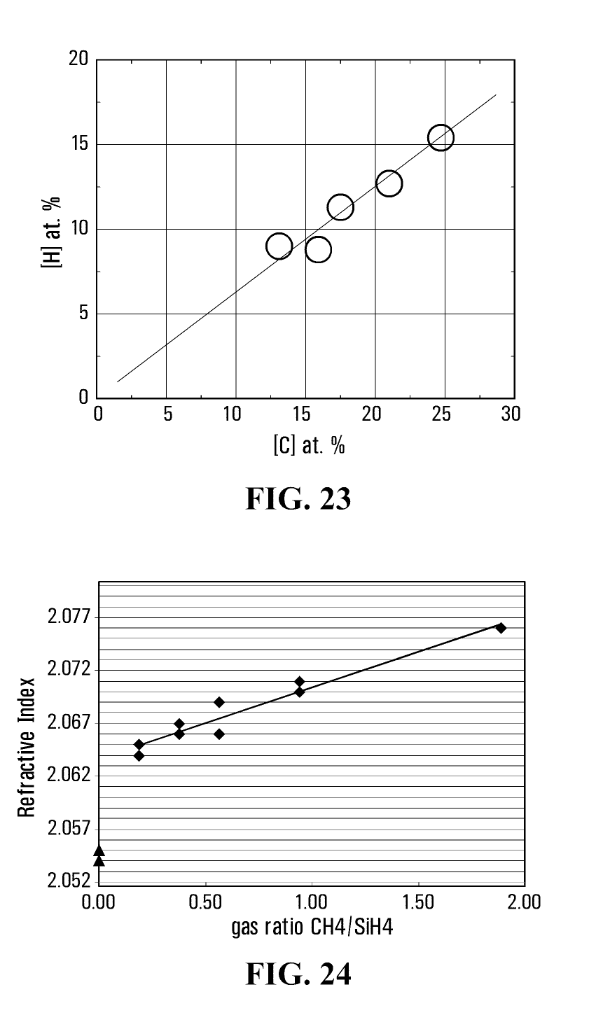

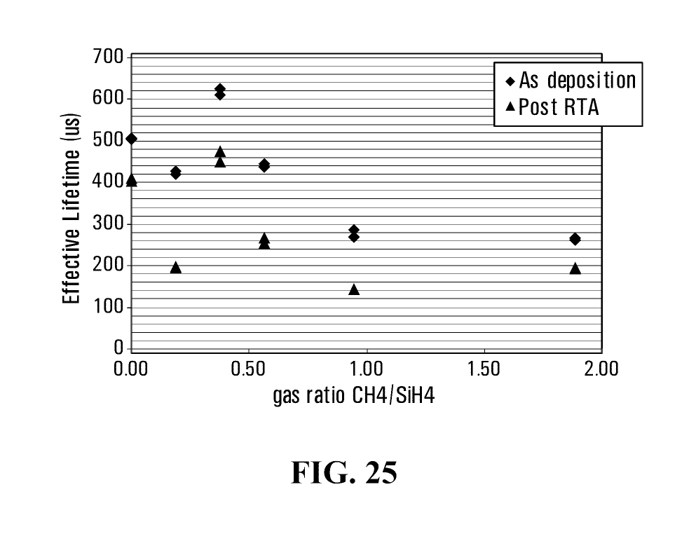

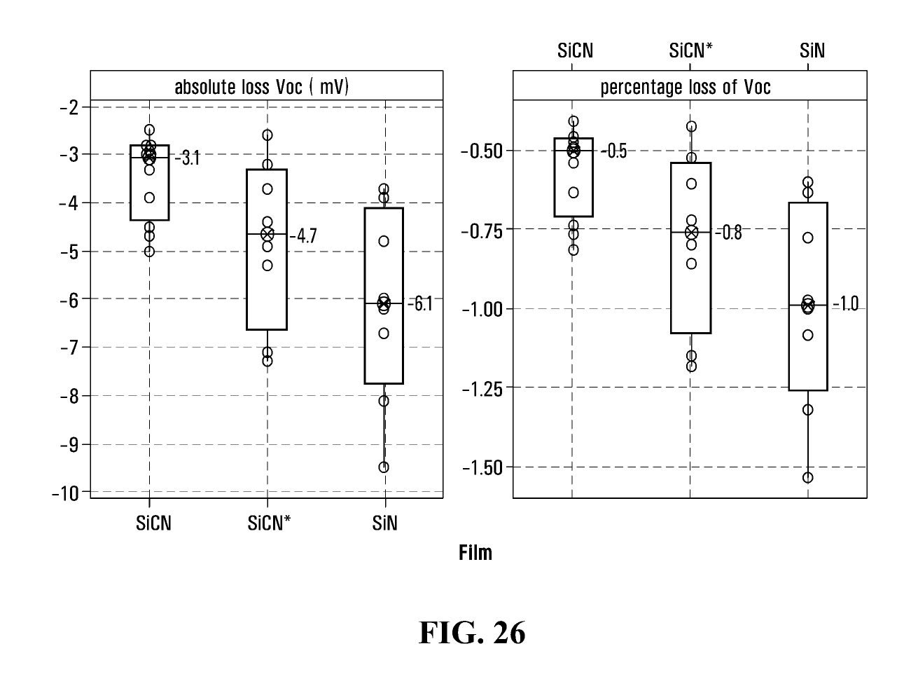

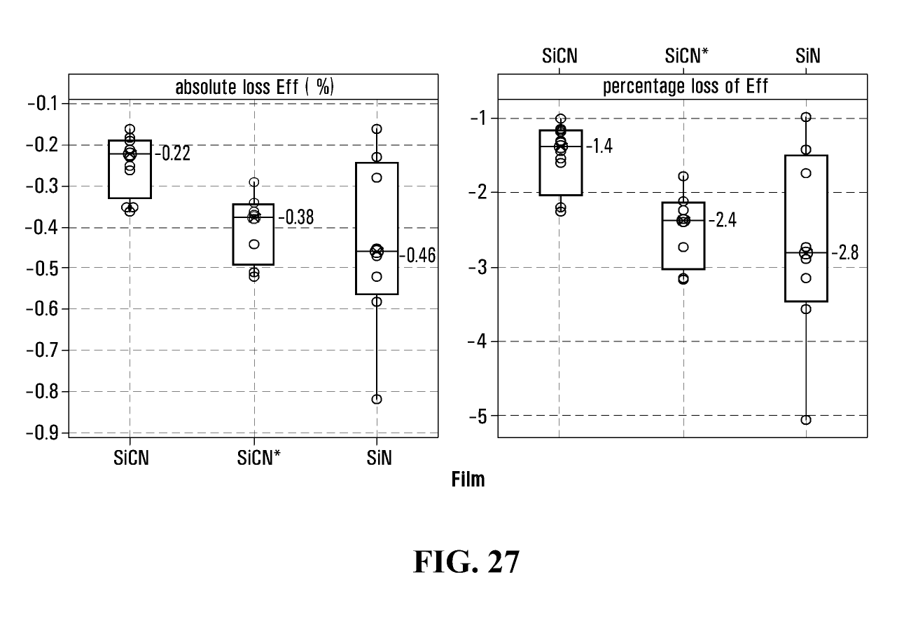

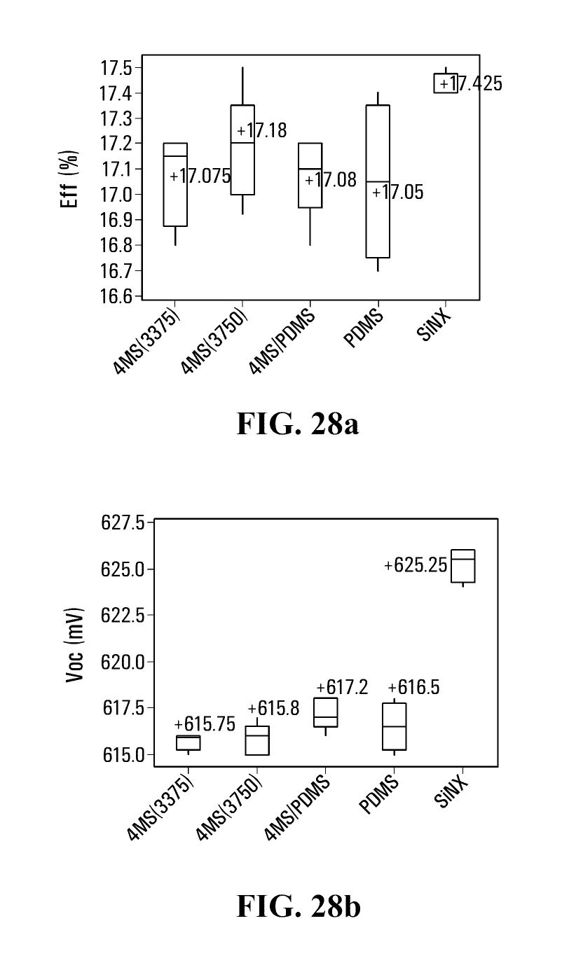

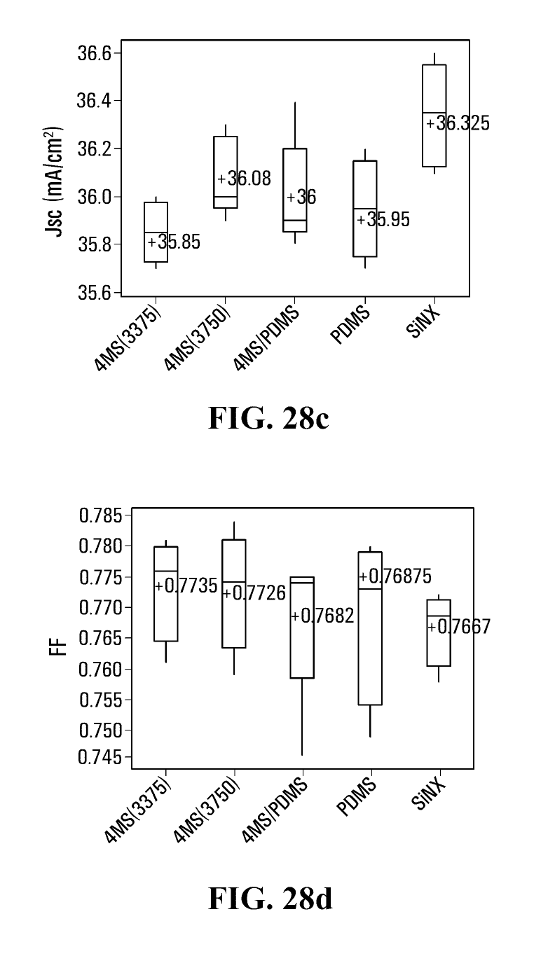

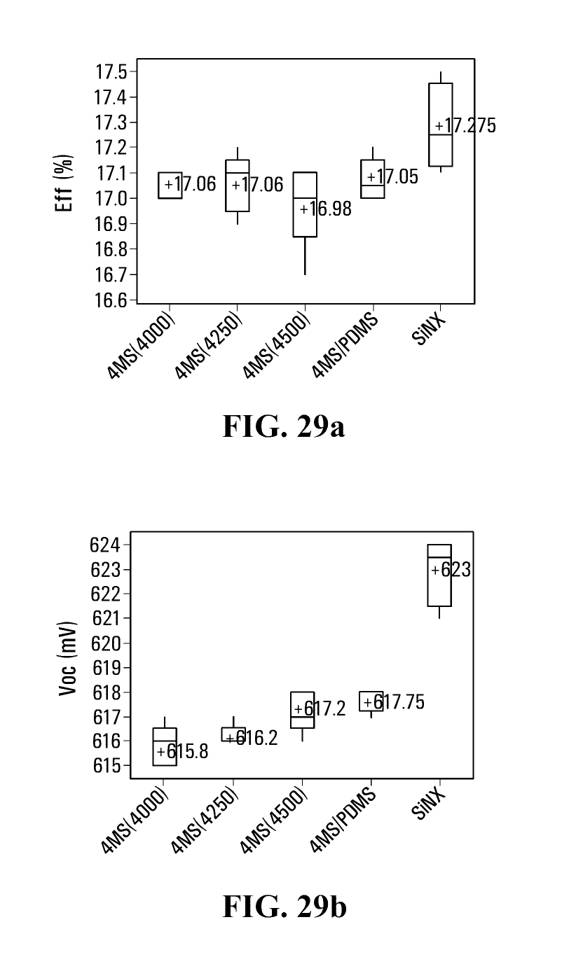

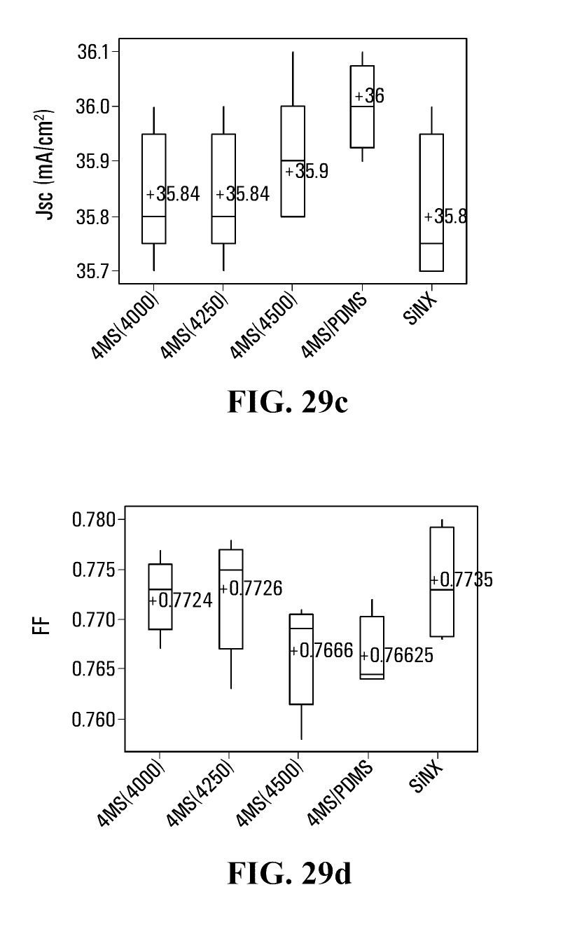

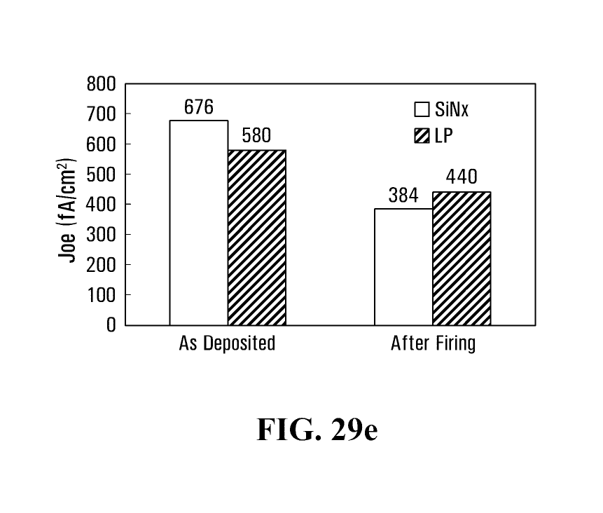

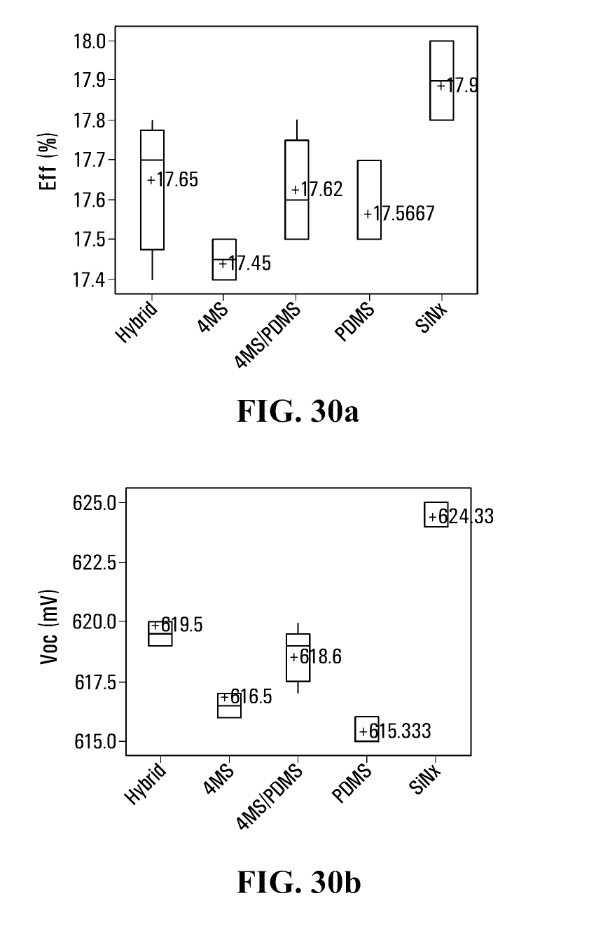

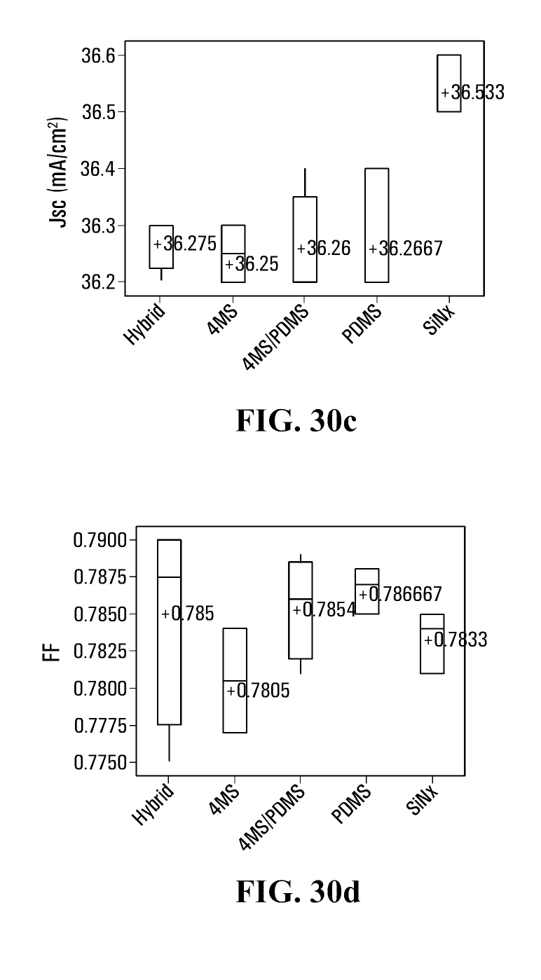

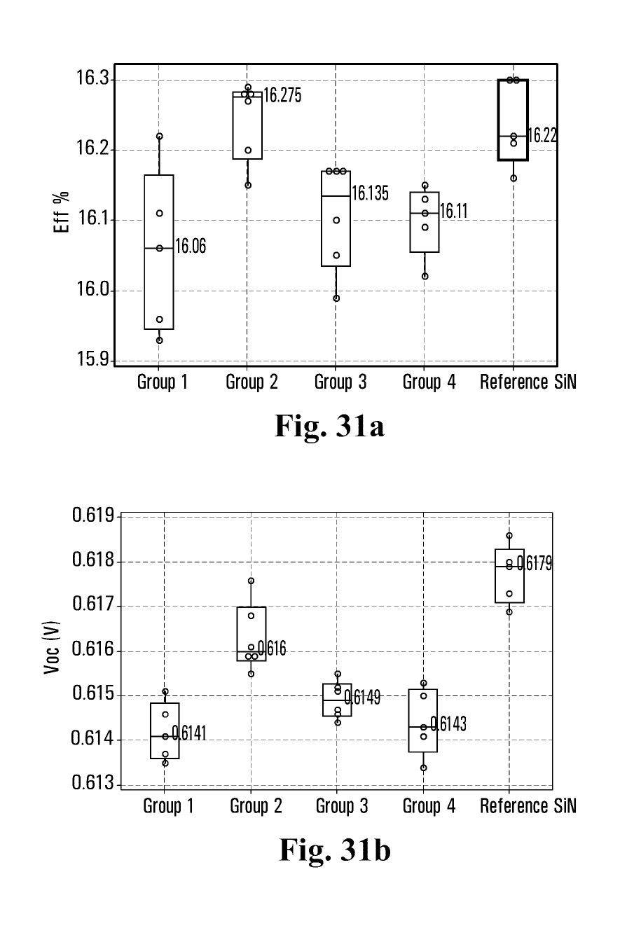

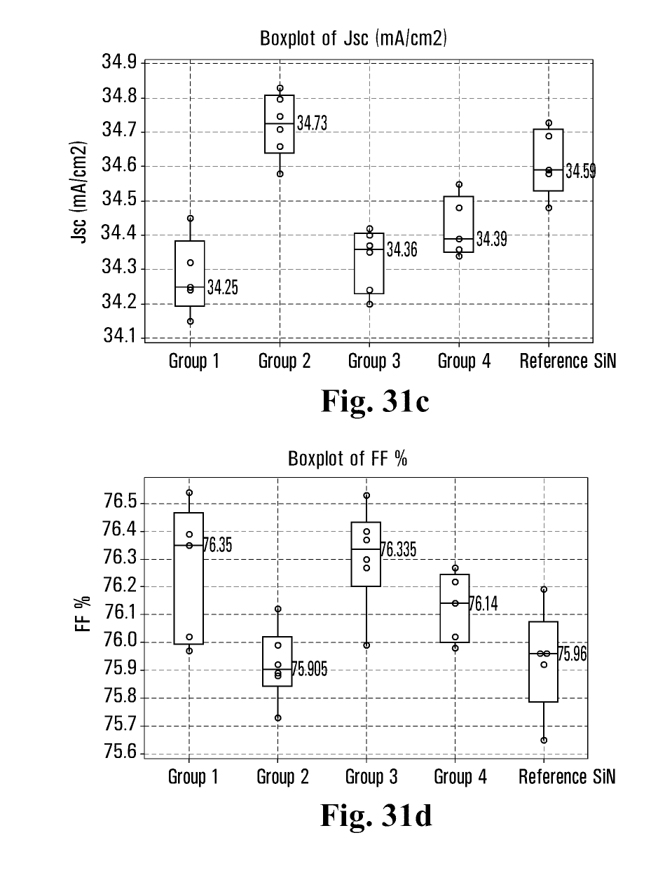

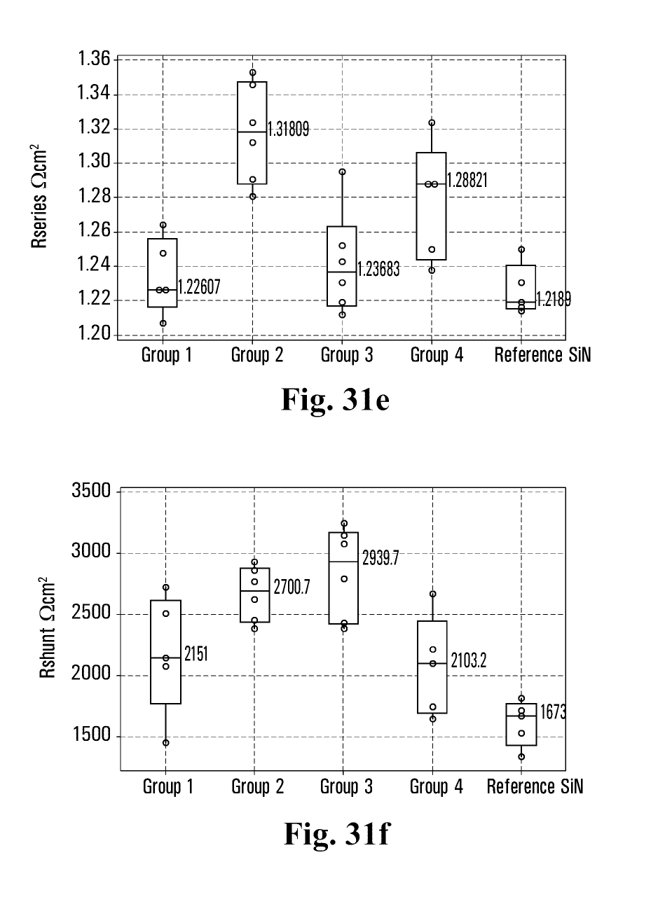

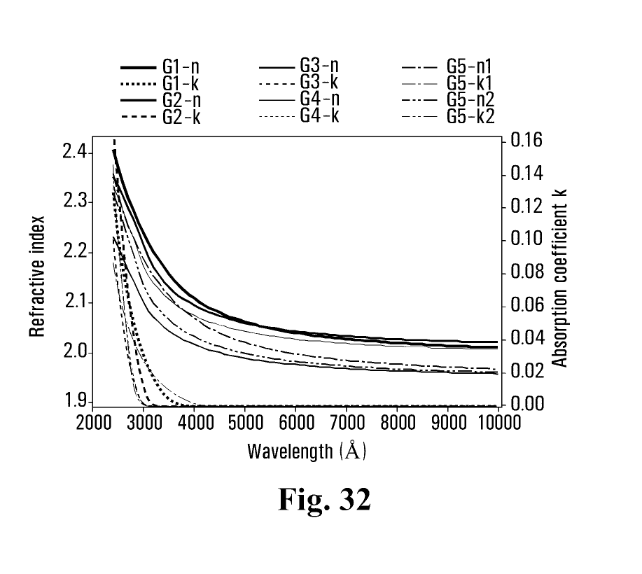

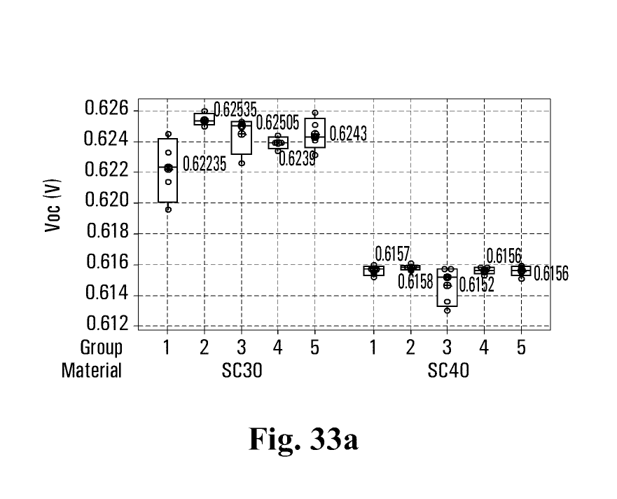

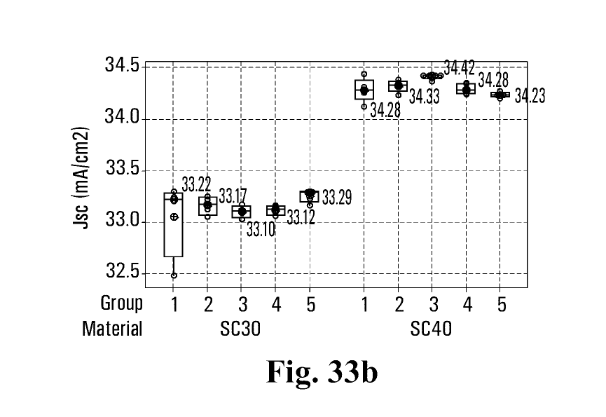

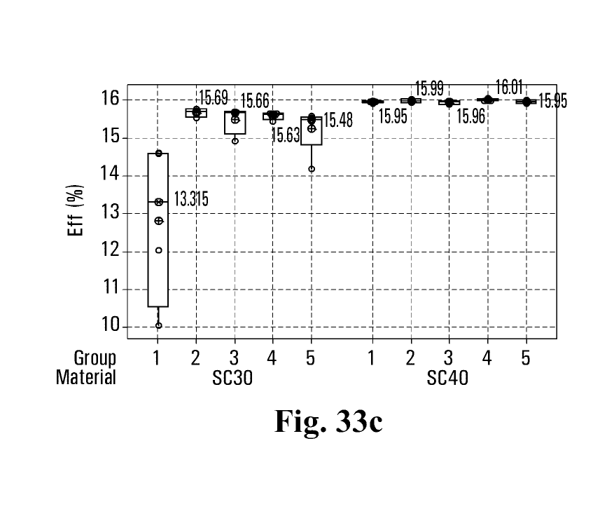

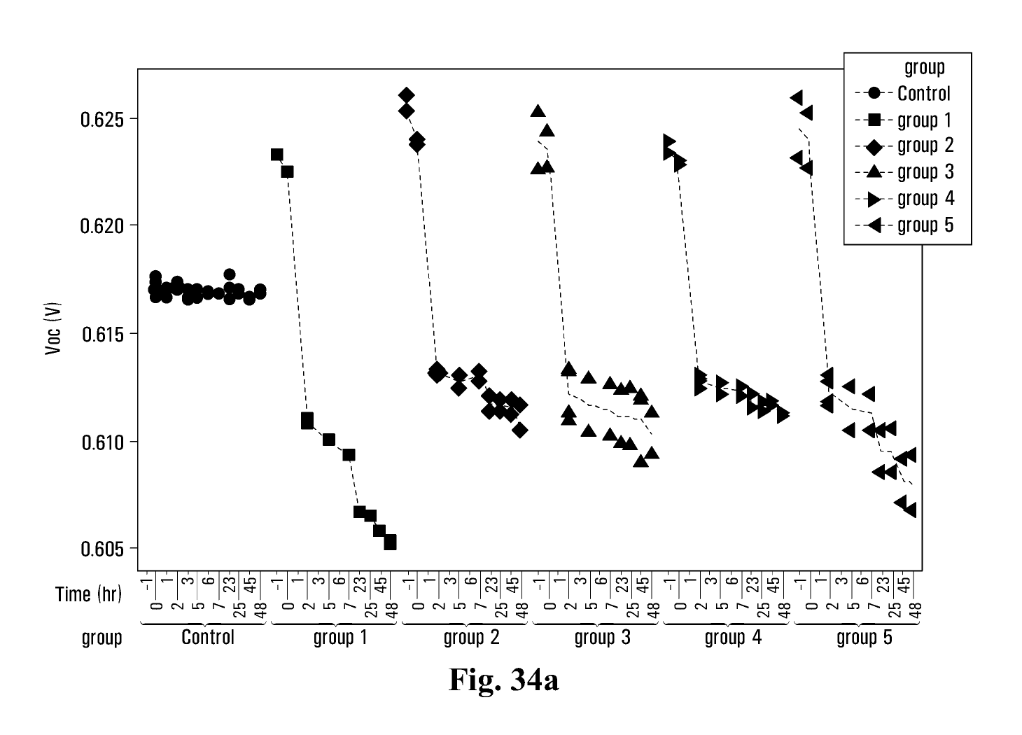

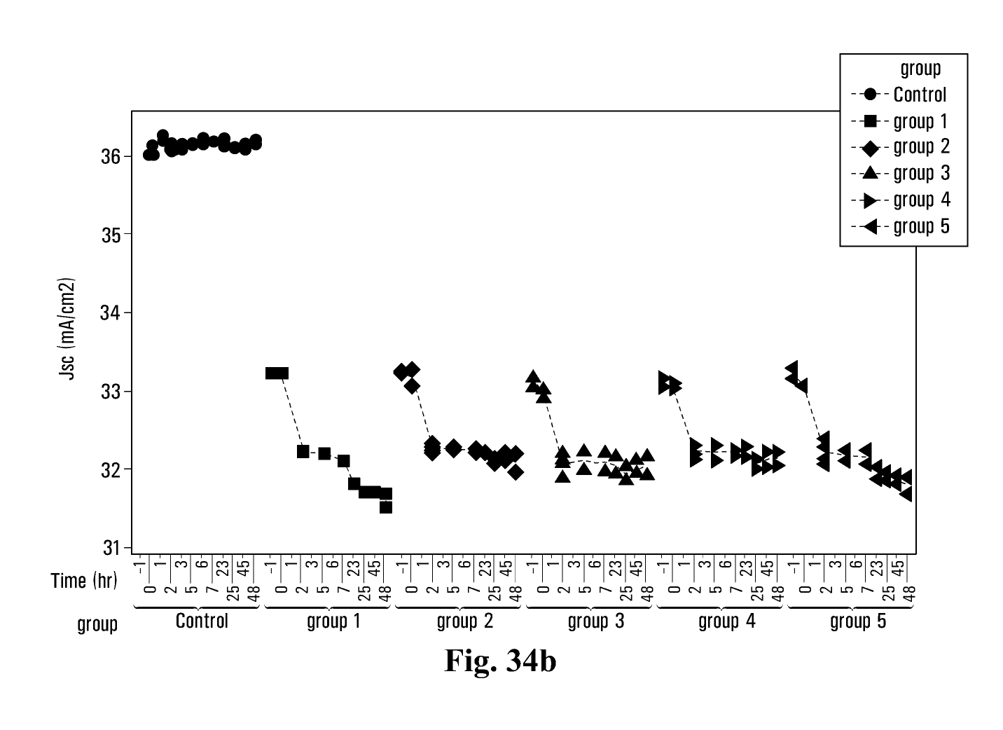

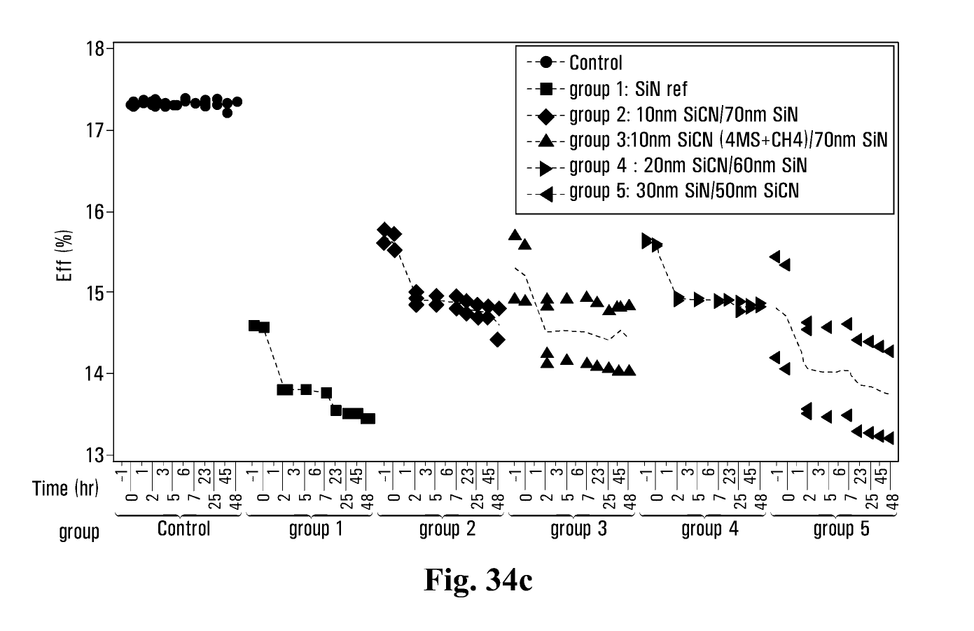

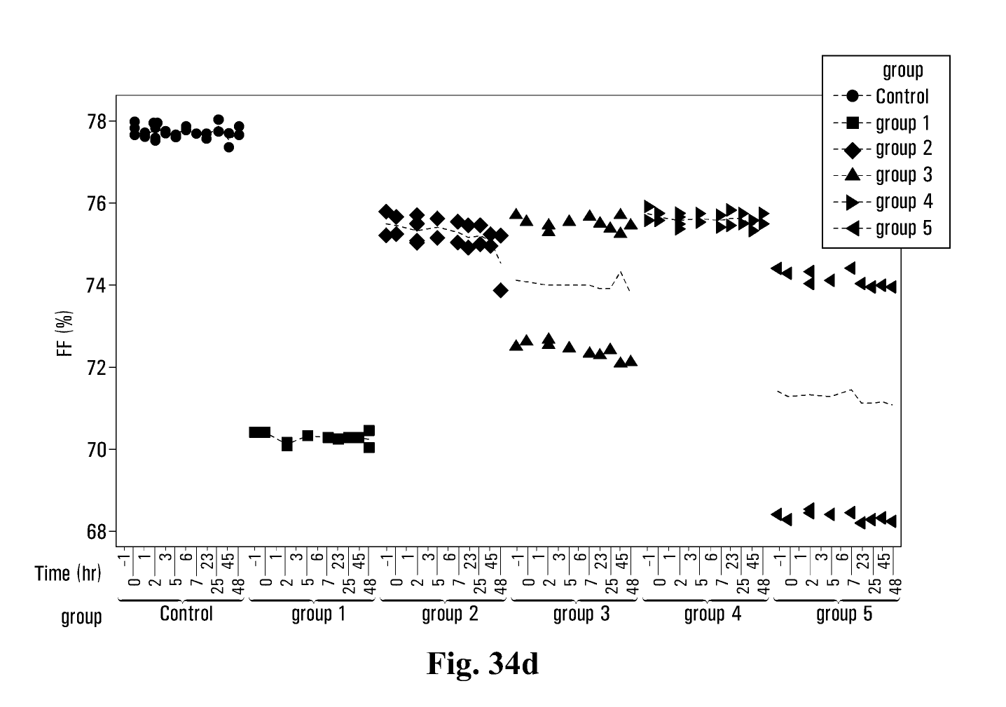

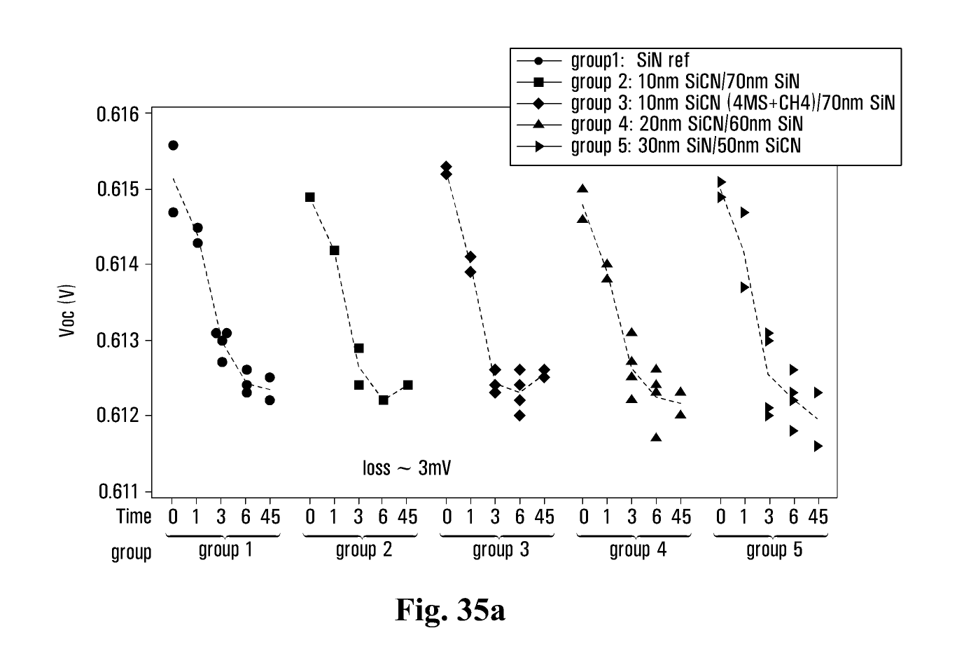

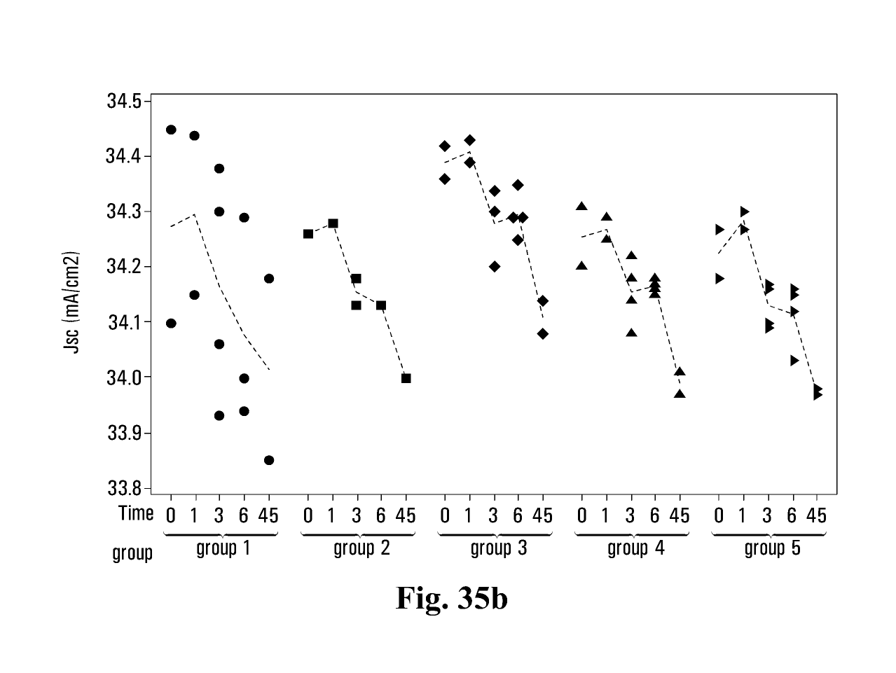

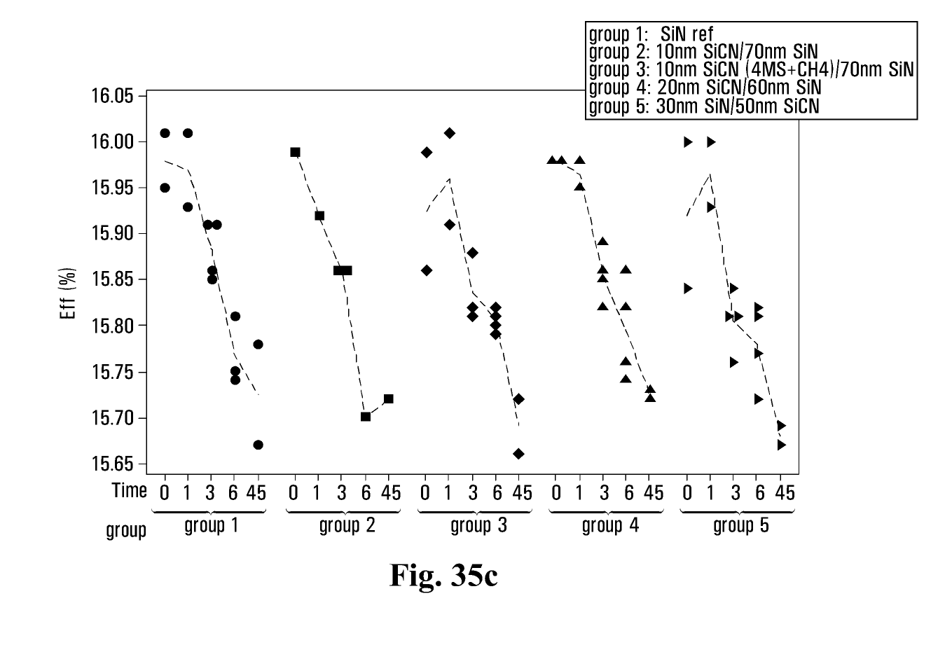

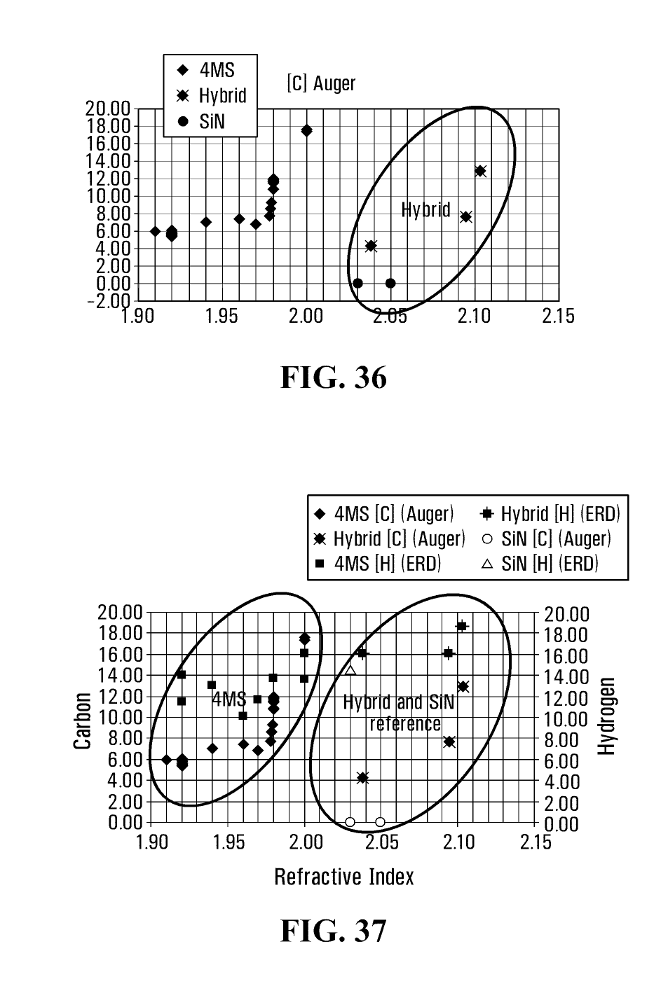

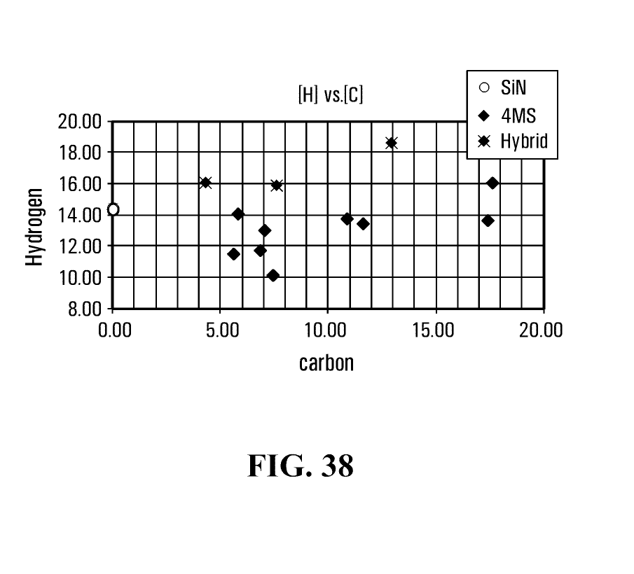

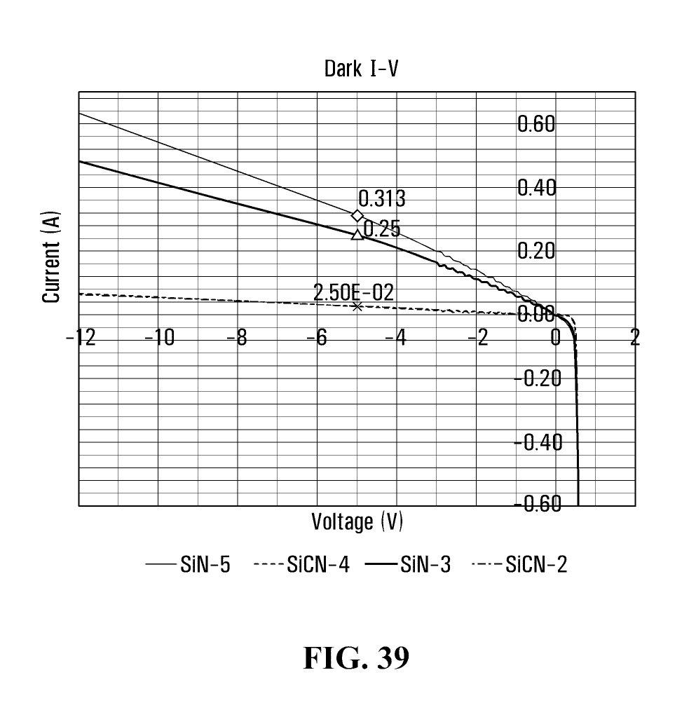

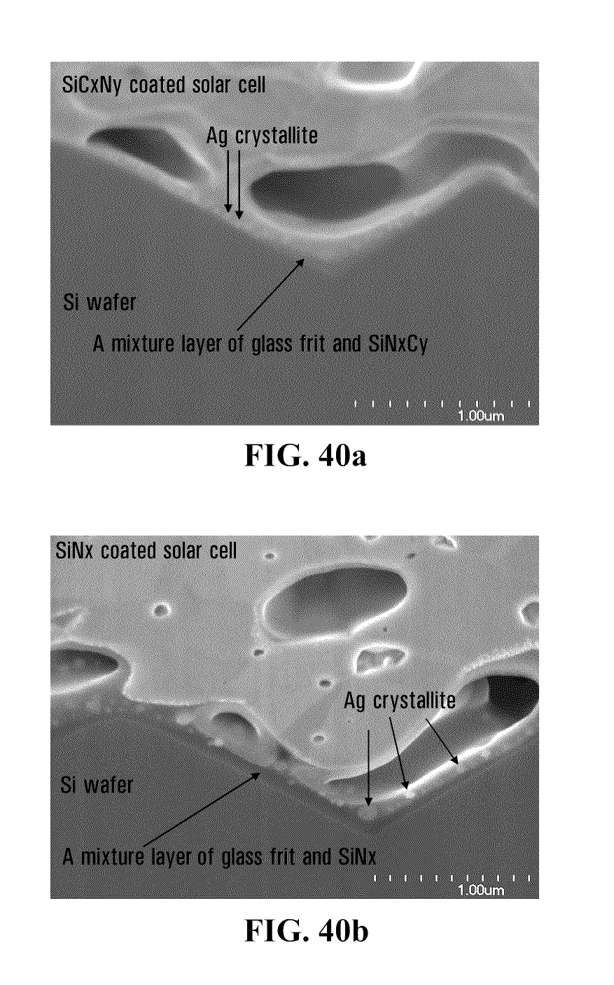

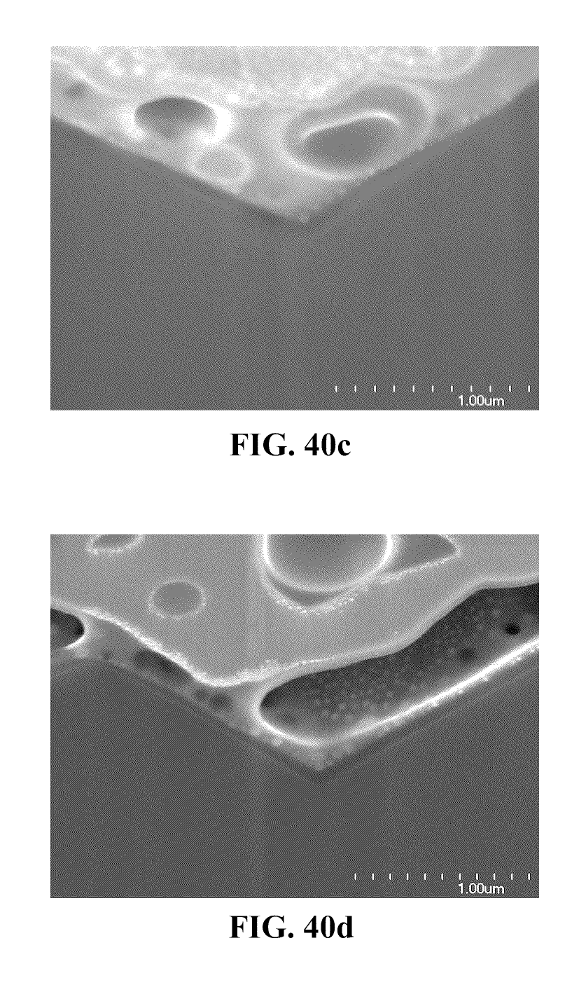

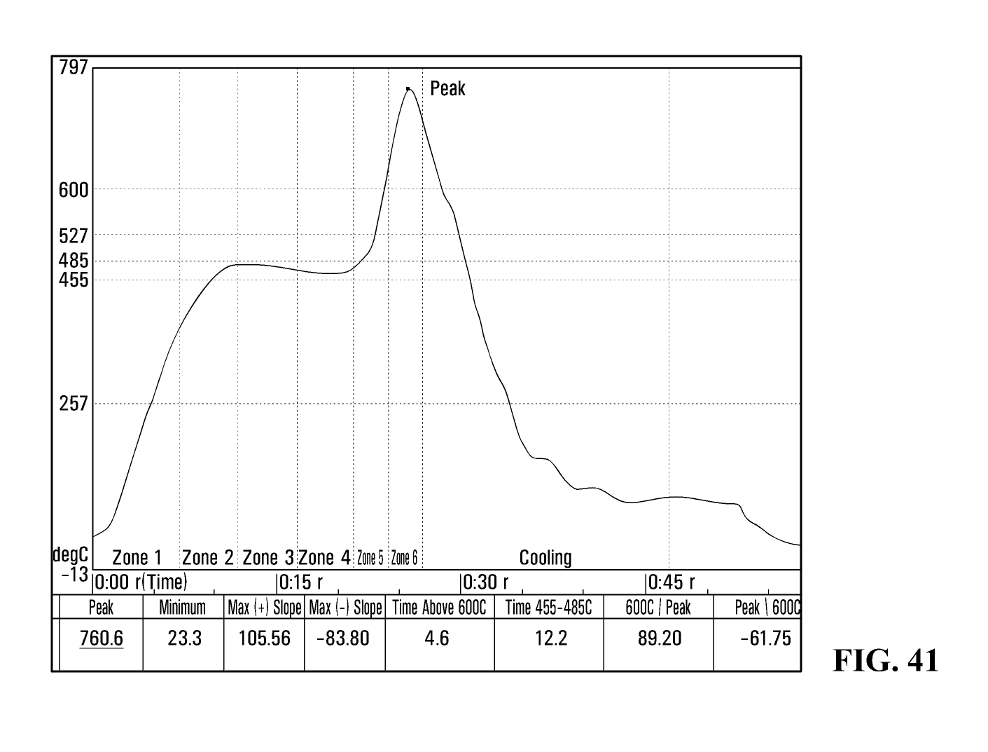

The post-illumination measurements obtained with the various solar cells are set out in Tables 10 to 13, and are summarized in Table 14a and in FIG. 15.

For the various substrates, it was observed that SiCN coated cells have lower LID than SiN coated cells. Looking at the 5 different Cz—Si wafers used, as a whole it was observed that SiCN coated Cz—Si cells had an LID loss in the range from 0.2 to 2.0% rel., while SiN coated Cz—Si cells had losses of 1.2 to 6.1% rel.

From these results, it appears that LID improvement is a generic phenomenon for SiCN coated p-type (Boron doped) Cz—Si solar cells, which is independent from the precursor used for SiCN deposition. However, the degree of improvement varies from wafer to wafer, which is probably due to a different base resistivity (i.e. different Boron dopant concentration) and different oxygen concentration, possibly along with other impurities that may be present in the wafer.

In order to correlate the LID data with B—O complex formation, the boron and oxygen contents of certain Cz wafers were measured using SIMS. Samples were polished to a high quality mirror finish with a diamond (i.e. oxygen free) paste to remove the surface texturization of solar cells. Boron concentration was also measured by ICP-MS as the boron data obtained by SIMS was too close to the noise floor to be accurate. Table 14b shows boron and oxygen concentration values, along with the relative Voc loss associated to the SiN and SiCN antireflective coatings prepared on these substrates. It is observed that a greater LID effect (from SiN to SiCN ARCs) is demonstrated for substrates with increased boron concentration (low resistivity substrates) or oxygen concentration. A particular differential in LID is observed between SiN and SiCN cells when the substrate contains a high concentration of oxygen.

TABLE 10
Results for substrate A wafers

| | Illumination | | | | |
|---|---|---|---|---|---|
| Cell Name | time (h) | Voc (mV) | Jsc (mA/cm²) | FF | Eff (%) |
| SIN-2 | 0 | 623.4 | 36.47 | 0.771 | 17.54 |
| SIN-2 | 22 | 619.5 | 36.02 | 0.770 | 17.17 |
| SIN-2 | 46 | 618.9 | 36.24 | 0.769 | 17.24 |
| SIN-2 | 66 | 620.0 | 36.12 | 0.768 | 17.20 |
| delta | | −3.4 | −0.35 | −0.003 | −0.34 |
| relative | | −0.5 | −1.0 | −0.4 | −1.9 |
| delta (%) | | | | | |
| SICN-5-4 | 0 | 619.3 | 35.84 | 0.772 | 17.13 |
| SICN-5-4 | 22 | 617.1 | 35.70 | 0.772 | 17.01 |
| SICN-5-4 | 46 | 616.3 | 35.70 | 0.771 | 16.97 |
| SICN-5-4 | 66 | 618.0 | 35.71 | 0.770 | 17.00 |
| delta | | −1.3 | −0.13 | −0.002 | −0.13 |
| relative | | −0.2 | −0.4 | −0.2 | −0.8 |
| delta (%) | | | | | |
| SICN-4-7 | 0 | 617.7 | 35.90 | 0.778 | 17.25 |
| SICN-4-7 | 22 | 616.5 | 35.74 | 0.778 | 17.13 |
| SICN-4-7 | 46 | 615.1 | 35.69 | 0.777 | 17.06 |
| SICN-4-7 | 66 | 616.3 | 35.72 | 0.778 | 17.13 |
| delta | | −1.4 | −0.18 | 0.000 | −0.12 |
| relative | | −0.2 | −0.5 | 0.1 | −0.7 |
| delta (%) | | | | | |
| SICN-3-4 | 0 | 619.8 | 36.15 | 0.774 | 17.34 |
| SICN-3-4 | 22 | 618.2 | 36.04 | 0.778 | 17.33 |
| SICN-3-4 | 46 | 617.2 | 36.09 | 0.776 | 17.29 |
| SICN-3-4 | 66 | 618.1 | 36.08 | 0.776 | 17.30 |
| delta | | −1.7 | −0.07 | 0.002 | −0.04 |
| relative | | −0.3 | −0.2 | 0.2 | −0.2 |
| delta (%) | | | | | |

TABLE 11
Results for substrate B wafers

| | | illumination | Voc | Jsc | | | |
|---|---|---|---|---|---|---|---|
| Cell Name | film | time | (mV) | (mA/cm²) | FF | Eff (%) | resistivity |
| SiN1-2 | SiN | 0 | 629.3 | 35.36 | 0.773 | 17.21 | 0.9 Ohm · cm |
| | | 5 | 623.7 | 34.93 | 0.775 | 16.88 | |
| | | 24 | 623.2 | 35.03 | 0.774 | 16.89 | |
| | | 53 | 622.8 | 34.93 | 0.776 | 16.89 | |
| | | 77 | 623.2 | 34.91 | 0.775 | 16.85 | |
| delta (77-0h) | | | −6.1 | −0.45 | 0.001 | −0.36 | |
| rel. delta (%) | | | −1.0 | −1.3 | 0.2 | −2.1 | |
| SiCN1-9 | SiCN | 0 | 620.8 | 35.12 | 0.766 | 16.71 | 0.9 Ohm · cm |
| | | 5 | 617.1 | 34.82 | 0.769 | 16.52 | |
| | | 24 | 616.9 | 34.93 | 0.770 | 16.60 | |
| | | 53 | 615.2 | 34.84 | 0.766 | 16.42 | |
| | | 77 | 617.7 | 34.81 | 0.774 | 16.65 | |
| delta (77-0h) | | | −3.1 | −0.32 | 0.008 | −0.06 | |
| rel. delta (%) | | | −0.5 | −0.9 | 1.0 | −0.4 | |
| SiN2-1 | SiN | 0 | 623.1 | 35.49 | 0.776 | 17.17 | 2 Ohm · cm |
| | | 5 | 622.4 | 35.51 | 0.774 | 17.09 | |
| | | 24 | 620.5 | 35.45 | 0.771 | 16.96 | |
| | | 53 | 619.9 | 35.51 | 0.771 | 16.97 | |
| | | 77 | 620.0 | 35.48 | 0.768 | 16.88 | |
| delta (77-0h) | | | −3.1 | −0.01 | −0.009 | −0.29 | |
| rel. delta (%) | | | −0.5 | 0.0 | −1.1 | −1.7 | |
| SiN2-4 | SiN | 0 | 623.1 | 35.85 | 0.778 | 17.37 | 2 Ohm · cm |
| | | 5 | 622.3 | 35.79 | 0.781 | 17.39 | |
| | | 24 | 620.7 | 35.76 | 0.776 | 17.21 | |
| | | 53 | 620.0 | 35.75 | 0.771 | 17.10 | |
| | | 77 | 620.2 | 35.75 | 0.771 | 17.10 | |
| delta (77-0h) | | | −2.9 | −0.10 | −0.006 | −0.27 | |
| rel. delta (%) | | | −0.5 | −0.3 | −0.8 | −1.6 | |
| SiCN2-8 | SiCN | 0 | 618.8 | 35.35 | 0.776 | 16.98 | 2 Ohm · cm |
| | | 5 | 618.0 | 35.28 | 0.781 | 17.03 | |
| | | 24 | 616.8 | 35.34 | 0.776 | 16.93 | |
| | | 53 | 617.2 | 35.38 | 0.771 | 16.84 | |
| | | 77 | 617.1 | 35.33 | 0.775 | 16.89 | |
| delta (77-0h) | | | −1.7 | −0.02 | −0.002 | −0.09 | |
| rel. delta (%) | | | −0.3 | −0.1 | −0.2 | −0.5 | |

TABLE 12
Results for substrate C wafers

| | Illumination | | Jsc | | |
|---|---|---|---|---|---|
| Wafer ID | time (hr) | Voc (V) | (mA/cm2) | FF (%) | Eff (%) |
| SiCN-10 | 0 | 0.6176 | 35.56 | 72.00 | 15.81 |
| SiCN-10 | 0.5 | 0.6162 | 35.48 | 71.73 | 15.68 |
| SiCN-10 | 1.5 | 0.6166 | 35.43 | 71.53 | 15.63 |
| SiCN-10 | 14.5 | 0.6130 | 35.31 | 71.32 | 15.44 |
| SiCN-10 | 17.0 | 0.6135 | 35.63 | 71.31 | 15.59 |
| SiCN-10 | 20.0 | 0.6146 | 35.57 | 72.13 | 15.77 |
| SiCN-10 | 116.0 | 0.6143 | 35.34 | 72.05 | 15.64 |
| LID degradation | 116 | −0.0033 | −0.22 | 0.05 | −0.17 |
| delta (X₁₁₆-X₀) | | | | | |
| rel. | | −0.5343 | −0.6187 | 0.0694 | −1.0753 |
| delta(%)_116 h | | | | | |
| rel. | | −0.4858 | 0.0281 | 0.1806 | −0.2530 |
| delta(%)_20 h | | | | | |
| avg (20 h-116 h) | | −0.5100 | −0.2953 | 0.1250 | −0.6641 |
| SiCN-13 | 0 | 0.6177 | 35.13 | 74.71 | 16.21 |
| SiCN-13 | 0.5 | 0.6171 | 35.12 | 74.48 | 16.14 |
| SiCN-13 | 1.5 | 0.6165 | 34.88 | 73.06 | 15.71 |
| SiCN-13 | 14.5 | 0.6136 | 34.99 | 73.97 | 15.88 |
| SiCN-13 | 17.0 | 0.6139 | 35.01 | 74.67 | 16.05 |
| SiCN-13 | 20.0 | 0.6136 | 35.09 | 74.55 | 16.05 |
| SiCN-13 | 116.0 | 0.6141 | 35.03 | 75.59 | 16.26 |
| LID degradation | 116 | −0.0036 | −0.10 | 0.88 | 0.05 |
| delta (X₁₁₆-X₀) | | | | | |
| rel. | | −0.5828 | −0.2847 | 1.1779 | 0.3085 |
| delta(%)_116 h | | | | | |
| rel. | | −0.6638 | −0.1139 | −0.2142 | −0.9870 |
| delta(%)_20 h | | | | | |
| avg (20 h-116 h) | | −0.6233 | −0.1993 | 0.4819 | −0.3393 |
| SiCN-3 | 0 | 0.6130 | 35.37 | 69.18 | 15.00 |
| SiCN-3 | 0.5 | 0.6122 | 35.46 | 68.70 | 14.92 |
| SiCN-3 | 1.5 | 0.6115 | 35.32 | 68.95 | 14.89 |
| SiCN-3 | 14.5 | 0.6099 | 35.24 | 66.96 | 14.39 |
| SiCN-3 | 17.0 | 0.6099 | 35.31 | 68.47 | 14.75 |
| SiCN-3 | 20.0 | 0.6174 | 36.00 | 70.56 | 15.68 |
| SiCN-3 | 116.0 | 0.6094 | 35.25 | 69.06 | 14.83 |
| LID degradation | 116 | −0.0036 | −0.12 | −0.12 | −0.17 |
| delta (X₁₁₆-X₀) | | | | | |
| rel. | | −0.5873 | −0.3393 | −0.1735 | −1.1333 |
| delta(%)_116 h | | | | | |
| rel. | | 0.7178 | 1.7812 | 1.9948 | 4.5333 |
| delta(%)_20 h | | | | | |
| avg (20 h-116 h) | | 0.0653 | 0.7209 | 0.9107 | 1.7000 |
| SiCN-7 | 0 | 0.6156 | 35.31 | 74.75 | 16.25 |
| SiCN-7 | 0.5 | 0.6150 | 35.48 | 74.91 | 16.35 |
| SiCN-7 | 1.5 | 0.6144 | 35.29 | 74.25 | 16.10 |
| SiCN-7 | 14.5 | 0.6116 | 35.28 | 74.00 | 15.97 |
| SiCN-7 | 17.0 | 0.6109 | 35.33 | 73.87 | 15.94 |
| SiCN-7 | 20.0 | 0.6121 | 35.34 | 74.89 | 16.20 |
| SiCN-7 | 116.0 | 0.6111 | 35.30 | 74.41 | 16.05 |
| LID degradation | 116 | −0.0045 | −0.01 | −0.34 | −0.20 |
| delta (X₁₁₆-X₀) | | | | | |
| rel. | | −0.7310 | −0.0283 | −0.4548 | −1.2308 |
| delta(%)_116 h | | | | | |
| rel. | | −0.5686 | 0.0850 | 0.1873 | −0.3077 |
| delta(%)_20 h | | | | | |
| avg (20 h-116 h) | | −0.6498 | 0.0283 | −0.1338 | −0.7692 |
| SiCN-8 | 0 | 0.6184 | 35.64 | 72.68 | 16.02 |
| SiCN-8 | 0.5 | 0.6169 | 35.78 | 71.85 | 15.86 |
| SiCN-8 | 1.5 | 0.6163 | 35.55 | 72.46 | 15.88 |
| SiCN-8 | 14.5 | 0.6147 | 35.60 | 71.95 | 15.74 |
| SiCN-8 | 17.0 | 0.6144 | 35.68 | 72.21 | 15.83 |
| SiCN-8 | 20.0 | 0.6142 | 35.68 | 72.30 | 15.84 |
| SiCN-8 | 116.0 | 0.6151 | 35.59 | 72.25 | 15.82 |
| LID degradation | 116 | −0.0033 | −0.05 | −0.43 | −0.20 |
| delta (X₁₁₆-X₀) | | | | | |
| rel. | | −0.5336 | −0.1403 | −0.5916 | −1.2484 |
| delta(%)_116 h | | | | | |
| rel. | | −0.6792 | 0.1122 | −0.5228 | −1.1236 |
| delta(%)_20 h | | | | | |
| avg (20 h-116 h) | | −0.6064 | −0.0140 | −0.5572 | −1.1860 |
| SiN-3 | 0 | 0.6240 | 36.07 | 72.40 | 16.30 |
| SiN-3 | 0.5 | 0.6219 | 36.22 | 71.24 | 16.05 |
| SiN-3 | 1.5 | 0.6237 | 36.05 | 73.84 | 16.61 |
| SiN-3 | 14.5 | 0.6186 | 35.82 | 72.54 | 16.07 |
| SiN-3 | 17.0 | 0.6196 | 36.10 | 73.65 | 16.47 |
| SiN-3 | 20.0 | 0.6191 | 36.08 | 72.00 | 16.09 |
| SiN-3 | 116.0 | 0.6200 | 36.11 | 70.64 | 15.82 |
| LID degradation | 116 | −0.0040 | 0.04 | −1.76 | −0.48 |
| delta (X₁₁₆-X₀) | | | | | |
| rel. | | −0.6410 | 0.1109 | −2.4309 | −2.9448 |
| delta(%)_116 h | | | | | |
| rel. | | −0.7853 | 0.0277 | −0.5525 | −1.2883 |
| delta(%)_20 h | | | | | |
| avg (20 h-116 h) | | −0.7131 | 0.0693 | −1.4917 | −2.1166 |
| SiN-4 | 0 | 0.6244 | 36.19 | 73.93 | 16.71 |
| SiN-4 | 0.5 | 0.6232 | 36.34 | 73.55 | 16.65 |
| SiN-4 | 1.5 | 0.6214 | 36.16 | 73.32 | 16.48 |
| SiN-4 | 14.5 | 0.6189 | 35.91 | 72.74 | 16.17 |
| SiN-4 | 17.0 | 0.6191 | 35.96 | 73.12 | 16.28 |
| SiN-4 | 20.0 | 0.6199 | 36.26 | 73.50 | 16.52 |
| SiN-4 | 116.0 | 0.6216 | 36.25 | 73.74 | 16.62 |
| LID degradation | 116 | −0.0028 | 0.06 | −0.19 | −0.09 |
| delta (X₁₁₆-X₀) | | | | | |
| rel. | | −0.4548 | 0.1658 | −0.2570 | −0.5386 |
| delta(%)_116 h | | | | | |
| rel. | | −0.7271 | 0.1934 | −0.5816 | −1.1370 |
| delta(%)_20 h | | | | | |
| avg (20 h-116 h) | | −0.5909 | 0.1796 | −0.4193 | −0.8378 |
| SiN-5 | 0 | 0.6238 | 35.93 | 74.85 | 16.78 |
| SiN-5 | 0.5 | 0.6227 | 36.04 | 74.85 | 16.80 |
| SiN-5 | 1.5 | 0.6201 | 35.72 | 74.05 | 16.40 |
| SiN-5 | 14.5 | 0.6147 | 35.37 | 73.30 | 15.94 |
| SiN-5 | 17.0 | 0.6146 | 35.51 | 73.65 | 16.07 |
| SiN-5 | 20.0 | 0.6155 | 35.42 | 73.44 | 16.01 |
| SiN-5 | 116.0 | 0.6177 | 35.65 | 73.41 | 16.16 |
| LID degradation | 116 | −0.0061 | −0.28 | −1.44 | −0.62 |
| delta (X₁₁₆-X₀) | | | | | |
| rel. | | −0.9779 | −0.7793 | −1.9238 | −3.6949 |
| delta(%)_116 h | | | | | |
| rel. | | −1.3306 | −1.4194 | −1.8838 | −4.5888 |
| delta(%)_20 h | | | | | |
| avg (20 h-116 h) | | −1.1542 | −1.0994 | −1.9038 | −4.1418 |
| SiN-7 | 0 | 0.6250 | 35.71 | 76.32 | 17.03 |
| SiN-7 | 0.5 | 0.6235 | 35.55 | 76.51 | 16.96 |
| SiN-7 | 1.5 | 0.6200 | 35.34 | 75.18 | 16.47 |
| SiN-7 | 14.5 | 0.6170 | 35.00 | 75.58 | 16.32 |
| SiN-7 | 17.0 | 0.6154 | 35.01 | 74.55 | 16.06 |
| SiN-7 | 20.0 | 0.6166 | 35.17 | 75.28 | 16.31 |
| SiN-7 | 116.0 | 0.6213 | 35.52 | 75.56 | 16.68 |
| LID degradation | 116 | −0.0037 | −0.19 | −0.76 | −0.35 |
| delta (X₁₁₆-X₀) | | | | | |
| rel. | | −0.5920 | −0.5321 | −0.9958 | −2.0552 |
| delta(%)_116 h | | | | | |
| rel. | | −1.3440 | −1.5122 | −1.3627 | −4.2278 |
| delta(%)_20 h | | | | | |
| avg (20 h-116 h) | | −0.9680 | −1.0221 | −1.1792 | −3.1415 |
| SiN-8 | 0 | 0.6242 | 35.69 | 77.73 | 17.32 |
| SiN-8 | 0.5 | 0.6227 | 35.52 | 77.93 | 17.24 |
| SiN-8 | 1.5 | 0.6198 | 35.40 | 77.35 | 16.97 |
| SiN-8 | 14.5 | 0.6166 | 35.20 | 75.97 | 16.49 |
| SiN-8 | 17.0 | 0.6167 | 35.06 | 76.22 | 16.48 |
| SiN-8 | 20.0 | 0.6172 | 35.26 | 76.58 | 16.66 |
| SiN-8 | 116.0 | 0.6198 | 35.41 | 76.82 | 16.86 |
| LID degradation | 116 | −0.0044 | −0.28 | −0.91 | −0.46 |
| delta (X₁₁₆-X₀) | | | | | |
| rel. | | −0.7049 | −0.7845 | −1.1707 | −2.6559 |
| delta(%)_116 h | | | | | |
| rel. | | −1.1214 | −1.2048 | −1.4795 | −3.8106 |
| delta(%)_20 h | | | | | |
| avg (20 h-116 h) | | −0.9132 | −0.9947 | −1.3251 | −3.2333 |
| SiN-9 | 0.5 | 0.6225 | 35.82 | 75.54 | 16.85 |
| SiN-9 | 0 | 0.6236 | 35.98 | 74.82 | 16.79 |
| SiN-9 | 1.5 | 0.6196 | 35.63 | 74.69 | 16.49 |
| SiN-9 | 14.5 | 0.6147 | 35.32 | 73.95 | 16.05 |
| SiN-9 | 17.0 | 0.6145 | 35.22 | 74.86 | 16.20 |
| SiN-9 | 20.0 | 0.6152 | 35.44 | 74.50 | 16.24 |
| SiN-9 | 116.0 | 0.6187 | 35.79 | 74.09 | 16.41 |
| LID degradation | 116 | −0.0038 | −0.03 | −1.45 | −0.44 |
| delta (X₁₁₆-X₀) | | | | | |
| rel. | | −0.6104 | −0.0838 | −1.9195 | −2.6113 |
| delta(%)_116 h | | | | | |
| rel. | | −1.1727 | −1.0609 | −1.3768 | −3.6202 |
| delta(%)_20 h | | | | | |
| avg (20 h-116 h) | | −0.8916 | −0.5723 | −1.6481 | −3.1157 |

TABLE 13
Results for substrate D wafers

| | illumination | | Jsc | | |
|---|---|---|---|---|---|
| Wafer ID | Time (hr) | Voc (V) | (mA/cm2) | FF (%) | Eff (%) |
| SiCN | 0 | 0.6263 | 34.08 | 75.07 | 16.02 |
| | 5 | 0.6263 | 34.08 | 75.07 | 16.02 |
| | 17 | 0.6209 | 33.71 | 75.51 | 15.81 |
| | 46 | 0.6212 | 33.37 | 74.70 | 15.49 |
| | 70 | 0.6204 | 33.66 | 74.38 | 15.53 |
| | 94 | 0.6223 | 33.80 | 74.70 | 15.70 |
| | rel. delta | −0.0064 | −0.0082 | −0.0049 | −0.0200 |
| SiCN | 0 | 0.6250 | 33.91 | 76.28 | 16.16 |
| | 5 | 0.6218 | 33.61 | 75.90 | 15.86 |
| | 17 | 0.6213 | 33.82 | 76.15 | 16.00 |
| | 46 | 0.6222 | 33.43 | 76.20 | 15.84 |
| | 70 | 0.6245 | 33.76 | 75.79 | 15.98 |
| | 94 | 0.6242 | 33.91 | 76.10 | 16.11 |
| | rel. delta | −0.0013 | 0.0000 | −0.0024 | −0.0031 |
| SiCN | 0 | 0.6252 | 33.70 | 75.66 | 15.94 |
| | 5 | 0.6227 | 33.40 | 75.33 | 15.67 |
| | 17 | 0.6225 | 33.52 | 75.16 | 15.68 |
| | 46 | 0.6237 | 33.13 | 75.40 | 15.58 |
| | 70 | 0.6253 | 33.51 | 74.90 | 15.70 |
| | 94 | 0.6254 | 33.66 | 74.90 | 15.77 |
| | rel. delta | 0.0003 | −0.0012 | −0.0100 | −0.0107 |
| SiN | 0 | 0.6296 | 34.27 | 75.37 | 16.26 |
| | 5 | 0.6188 | 33.63 | 75.03 | 15.61 |
| | 17 | 0.6174 | 33.47 | 74.82 | 15.46 |
| | 46 | 0.6189 | 33.11 | 74.10 | 15.18 |
| | 70 | 0.6193 | 33.48 | 74.74 | 15.50 |
| | 94 | 0.6223 | 33.65 | 74.95 | 15.69 |
| | rel. delta | −0.0116 | −0.0181 | −0.0056 | −0.0351 |
| SiN | 0 | 0.6297 | 33.91 | 76.77 | 16.39 |
| | 5 | 0.6191 | 33.08 | 76.6 | 15.68 |
| | 17 | 0.6133 | 32.54 | 76.55 | 15.28 |
| | 46 | 0.6152 | 32.42 | 76.1 | 15.18 |
| | 70 | 0.6147 | 32.52 | 76.09 | 15.21 |
| | 94 | 0.615 | 32.57 | 76.8 | 15.39 |
| | rel. delta | −0.0233 | −0.0395 | 0.0004 | −0.0610 |

TABLE 14a
Summary of LID observation for different Cz-Si wafers

| | | | | | Eff. loss |
|---|---|---|---|---|---|
| | | | bulk resistivity | emitter sheet | due to LID |
| Film | precursor | wafer | (Ohm · cm) | rho (Ohm/sq) | (%. rel) |
| SiN | SiH4 | A | ~2 | 60 | 1.9 |
| SiN | SiH4 | A | ~2 | 60 | 1.6 |
| SiN | SiH4 | B | 0.9 | 60 | 2.1 |
| SiCN | pdms | A | ~2 | 60 | 0.8 |
| SiCN | pdms | A | ~2 | 60 | 0.7 |
| SiCN | pdms | A | ~2 | 60 | 0.2 |
| SiCN | pdms | A | ~2 | 60 | 0.5 |
| SiCN | pdms | B | 0.9 | 60 | 0.4 |
| SiN | SiH4 | C | 3~6 | 65 | 2.1 |
| SiN | SiH4 | C | 3~6 | 65 | 0.8 |
| SiN | SiH4 | C | 3~6 | 65 | 4.1 |
| SiN | SiH4 | C | 3~6 | 65 | 3.2 |
| SiN | SiH4 | C | 3~6 | 65 | 3.1 |
| SiCN | pdms | C | 3~6 | 65 | 0.7 |
| SiCN | pdms | C | 3~6 | 65 | 0.3 |
| SiCN | pdms | C | 3~6 | 65 | 1.7 |
| SiCN | pdms | C | 3~6 | 65 | 0.8 |
| SiCN | pdms | C | 3~6 | 65 | 1.2 |
| SiN | SiH4 | D | ~1.5 | 72 | 3.5 |
| SiN | SiH5 | D | ~1.5 | 72 | 6.1 |
| SiCN | 3MS + Ar | D | ~1.5 | 72 | 2.0 |
| SiCN | 3MS + Ar | D | ~1.5 | 72 | 0.3 |
| SiCN | 3MS | D | ~1.5 | 72 | 1.1 |
| SiN | SiH4 | E | 3.8 | 73 | 1.2 |
| SiCN | 4MS | E | 3.8 | 73 | 1.6 |
| SiCN | 4MS | E | 3.8 | 73 | 0.7 |

TABLE 14b
Boron and Oxygen concentrations vs. LID

| | [B] Bulk | [O] | | Eff. Loss |
|---|---|---|---|---|
| | resistivity | (ppm) SIMS | [B] (ppm) | (% rel) |
| Substrate type | (Ohm · cm) | (1σ = 0.04) | ICP-MS | of SiCN/SiN |
| Wafer A | 2 | 22.4 | N/A | 0.6/1.8 |
| Wafer D | ~1.5 | 26.8 | 0.12 | 1.1/4.8 |
| Wafer E | 3.8 | 17.3 | 0.02 | 1.1/1.2 |

### Example 9

Solar cells were prepared and exposed to light illumination for set periods. Solar cell performance was measured.

Material: silicon solar cells created on various p-type Cz wafers. Multiple wafers of the same type were prepared to obtain averaged values.

Film: SiCN and SiN deposited at SEMCO PECVD with various precursors
Light illumination: an array of six 500 W lamps was used to illuminate the cells from a distance of about 50 cm, exposing them to a light intensity ˜1000W/m² and heating to around 48° C. (cells are placed directly on grid)
Metrics: Solar cells I-V Curve tester from PV Measurements, Inc, model IV16, with solar simulation non-uniformity better than +/−5% over 16×16 cm region

The influence of light exposure on current-voltage (I-V) solar cell characteristic was investigated. Changes in I-V performance, losses of Voc, Jsc and efficiency are presented below.

TABLE 16
Substrate description

| | | | | | | Abs. | | |
|---|---|---|---|---|---|---|---|---|
| | | | [P] | SIMS | | Voc | | |
| | | | emitter | [O] | | loss | % loss | % loss |
| | [B] Bulk | [B] | sheet | avr | IGA Conc. of | (mV) | of Voc | of Eff |
| | Res. | ppm/ | res. | level | elements | SiCN/ | SiCN/ | SiCN/ |
| Substrate | (Ω · cm) | Z × 10^{y} | (ohm/sq) | (ppm) | (ppm wt) | SiN | SiN | SiN |
| A | 0.96 | N/A | 65 | N/A | N/A | 3.7/3.0 | 0.6/0.5 | 1.6/1.7 |
| B | 5 | 0.02 ppm | 73 | 17.3 | [C]192, [N]34.5, | 0.3/1.5 | 0.05/0.2 | 1.1/1.2 |
| | | wt | | | [O]26.2 | | | |
| | | 2.7 × 10¹⁵ | | | | | | |
| C | 1 | 0.12 ppm | 72 | 26.8 | [C]958, [N]42.7, | 5.1/14.1 | 0.8/2.2 | 2.3/6.9 |
| | | wt | | | [O]29.6 | | | |
| | | 1.6 × 10¹⁶ | | | | | | |
| D | ~3 | N/A | 52 | 24.2 | N/A | 3.1/6.0 | 0.5/1.0 | 1.5/2.7 |
| E | N/A | N/A | 60 | N/A | N/A | 2.8/3.4 | 0.5/0.6 | 1.7/1.2 |
| F | N/A | N/A | 65 | N/A | N/A | 4.0/7.6 | 0.7/1.2 | 2.3/4.5 |
| G | ~3 | N/A | 45 | N/A | N/A | 2.2/4.1 | 0.4/0.7 | 1.9/3.4 |

TABLE 17
Wafer oxygen concentration

| | D | C | B |
|---|---|---|---|
| average | 1.21 × 10¹⁸ | 1.34 × 10¹⁸ | 8.65 × 10¹⁷ |
| std dev | 2 × 10¹⁶ | 2 × 10¹⁶ | 2 × 10¹⁶ |
| average | 24.20 | 26.80 | 17.30 |
| ppm | | | |
| std dev | 0.05 | 0.04 | 0.03 |
| ppm | | | |

Wafer C has 1.6×10¹⁶ B (=0.12 ppm) and has a resistivity of 1 Ohm cm. Wafers A and B have 2.7×10¹⁵ B (=0.02 ppm) and have a resistivity of 5 Ohm cm. The ppm values represent parts per million by weight. The analysis was performed using glow discharge mass spectrometry.

Plots of Voc and Efficiency losses for various substrates are shown as follows:

The LID processes were carried out on solar cells, within a substrate group, with initial efficiency values that varied slightly but that were as close as possible. The absolute change in efficiency after the light illumination for selected groups is plotted in FIG. 17. The first two columns are for substrate C, the two middle columns are for substrate D, and the last two columns are for substrate B.

In FIG. 17, we compared three types of substrate with nominally the same SiCN film with a carbon concentration of about 7%, measured by Auger.

If the emitter has a high resistivity and the bulk resistivity is low (e.g. substrate A) then Voc is expected to be high and passivation requirements are demanding. Under such circumstances the initial efficiency of the solar cells is low for SiCN coated cells as compared to SiN coated cells. When such wafers also have a high oxygen content then there is a significant loss in efficiency during exposure to light.

If the cells have reduced boron concentration i.e. higher bulk resistivity and reduced oxygen concentration then the LID is similar for both SiCN and SiN.

Substrate D represents an intermediate case where the oxygen content is high, the emitter has a lower resistivity (passivation requirements reduced) and the bulk is about 3 Ohm cm i.e. boron concentration between substrate C and substrate B. Even though the initial efficiency is less for SiCN the post LID efficiency is similar.

It is to be noted that the initial efficiency depends on the combination of good passivation to maximise Voc, good optical properties to maximise Jsc, and good contacting technology to maximise fill factor. These parameters are determined by other process conditions determined by the way the cells are prepared and also by the method of depositing the films (e.g. remote plasma tools versus direct plasma tools). With the information provided it now becomes possible to deliberately engineer a solar cell manufacturing process that may take advantage of the LID benefits that can be obtained by using SiCN films.

To further demonstrate the impact on Voc as an indicator of how surface passivation requirements can vary with differing solar cell structures, the following plots on Voc under LID testing were prepared.

In terms of Voc, the absolute loss (median values) is plotted in FIG. 18. In the Figure, the first two columns are for substrate C, the two middle columns are for substrate D, and the last two columns are for substrate B.

In terms of Voc, the absolute loss (all values) is plotted in FIG. 19. In the Figure, the first two columns are for substrate C, the two middle columns are for substrate D, and the last two columns are for substrate B.

### Example 10

The light induced degradation of solar cells prepared with different PE-CVD apparatus, and the resulting solar cells were studied. Cells were prepared from both direct plasma and microwave remote plasma apparatus.

The solar cells prepared with the remote plasma were observed, in comparison with the cells prepared with direct plasma, to have a lower passivation performance, a lower film density, a higher carbon film composition, a lower passivation performance, a lower lifetime (before and after firing), a lower Voc and a lower Jsc. A comparison of the Voc and Jsc for cells prepared by MW and RF plasma apparatus are provided in FIG. 20. Photographs showing the pinhole surfaces of some of the prepared films are shown in FIGS. 11a-d, wherein FIGS. 21a and 21b represent two SiCxNy layers, FIG. 21c represents a SiNx layer, and FIG. 21d represents a SiCxNy layer prepared with the remote microwave plasma apparatus.

### Example 11

Solar cells with different SiCxNy antireflective and passivation coatings were prepared using different gaseous sources during the PECVD of the coatings.

Antireflective and passivation coatings were prepared with methylsilane (MS), dimethylsilane (2MS), trimethylsilane (3MS), tetramethylsilane (4MS), and a gas mixture obtained from the pyrolysis of a solid polydimethylsilane source. The MS, 2MS, 3MS and mixture precursors are in a gaseous state at standard temperature and pressure. 4MS was vaporized prior to deposition by PE-CVD.

The antireflective coatings were deposited on both monocrystalline (Cz) and multicrystalline (mc) silicon substrates, and solar cells were prepared there from.

A comparative solar cell was also prepared with a SiNx antireflective coating.

Table 17 provides a summary of the elemental composition of the obtained antireflective coatings. SiCxNy films deposited from 3MS and 4MS were shown to provide carbon-lean SiCxNy films compared to other precursors comprising Si and C atoms.

Tables 18 to 21 provide the differences in Voc, Jsc, FF and efficiency characteristics for the SiCxNy solar cells, in comparison with the corresponding value obtained for a solar cell with a SiNx antireflective coating.

Generally, the Cz wafers were less influenced by the passivation quality than the mc wafers and ΔVoc (Cz) was seen to be lower than ΔVoc (mc). In addition, at a higher sheet resistivity, ΔVoc was enlarged, i.e. the ΔVoc for the low sheet resistivity emitter was lower than the ΔVoc for the high sheet resistivity emitter.

Of the sources used, 3MS and 4MS were seen to provide a passivation quality similar to that of SiNx films. For these, the Voc difference, ΔVoc, was less than 1 mV even at a high sheet resistivity Cz emitter (73 Ω/sq) for 3MS. For 4MS, the ΔVoc was only 1 mV for the multi-crystalline 45 Ohm/sq emitter.

Jsc is largely affected by passivation quality according to the relationship, Voc=kT/q*ln(Jsc/Joe+1). However, ΔJsc can be partly compensated by tuning the optical properties such as refractive index (R.I.) and thickness of the film. There is therefore more opportunity to options for increasing Jsc than there are for Voc. Film uniformity over the whole area of the solar cell wafer is also important to obtain a higher Jsc value.

FF is also partly influenced by passivation quality, i.e., FF0=(voc−ln(voc+0.72))/(voc+1) where voc=Voc/(nkT/q). However, FF is also a function of shunt resistance, rsh, by FF=FF0(1−(voc+0.7)/voc*FF0/rsh).

With the prepared cells, higher shunt behaviour was not observed but FF was seen to be dependent on the carbon content, with a higher carbon content deteriorating FF. However, no substantial difference in FF between the SiNx and SiCxNy cells was observed for the solar cell prepared from 4MS. This may be because 4MS coated SiCxNy films contain the lowest carbon concentration (in comparison to the other SiCxNy films).

SiCxNy coated solar cells with the ARC prepared from 3MS and 4MS were observed to provide a comparable efficiency to SiNx coated solar cells, even for the high sheet (72 Ω/sq) resistivity Cz and multi-crystalline emitters.

Table 23 provides the deposition rate and dilution ratios for the deposition of the antireflective coatings. The deposition of 3MS and 4MS was seen to require less NH3 dilution to produce a comparable film in terms of optical properties and passivation. Preparation of a carbon-lean SiCxNy film, however, was realized by reducing the deposition rate.

It may be possible to increase the deposition rate e.g. by increasing the PECVD power and/or by changing other plasma parameters. In another embodiment, the lower deposition rate for 3MS and 4MS can be counterbalanced by preparing a multilayer ARC, one layer being thinner (˜less than 30 nm) and deposited to act as a surface passivating layer (SPL), and a further thicker layer (˜50 nm), prepared from MS, 2MS or the gas mixture, deposited on the top of the SPL.

TABLE 17
Antireflective coating composition

| Composition | | | Mixture | | | |
|---|---|---|---|---|---|---|
| (at. %) | MS | 2MS | (PDMS) | 3MS | 4MS | SiH4 |
| [C] | ~25 | ~16.1 | ~15 | ~7.0 | ~7.2 | 0 |
| [Si] | ~31 | ~32.9 | ~31 | ~33.2 | ~34.4 | ~36 |
| [N] | ~42 | ~49.3 | ~51 | ~58.8 | ~56.6 | ~60 |
| [O] | ~2 | ~1.7 | ~2 | ~1.0 | ~1.8 | ~2 |

TABLE 18
Change in Voc (open circuit voltage)

| Cell | | | | Mixture | | |
|---|---|---|---|---|---|---|
| parameter | Wafer/emitter | MS | 2MS | (PDMS) | 3MS | 4MS |
| ΔVoc (mV) | Cz, 60 Ω/sq | ~8.6 | — | ~3.0 | — | — |
| compared to | Cz, 73 Ω/sq | — | ~6.2 | ~3.6 | ~0.9 | — |
| SiNx | mc, 45 Ω/sq | — | — | ~5.8 | — | ~1.0 |
| | mc, 55 Ω/sq | — | — | ~8.6 | — | — |

TABLE 19
Change in Jsc (short circuit current)

| Cell | | | | Mixture | | |
|---|---|---|---|---|---|---|
| parameter | Wafer/emitter | MS | 2MS | (PDMS) | 3MS | 4MS |
| ΔJsc | Cz, 60 Ω/sq | ~0.10 | — | ~0.25 | — | — |
| (mA/cm2) | Cz, 73 Ω/sq | — | ~0.39 | ~0.29 | ~0.21 | — |
| compared to | mc, 45 Ω/sq | — | — | ~0.40 | — | ~0.37 |
| SiNx | mc, 55 Ω/sq | — | — | ~0.48 | — | — |

TABLE 20
Change in FF (Fill Factor)

| Cell | | | | Mixture | | |
|---|---|---|---|---|---|---|
| parameter | Wafer/emitter | MS | 2MS | (PDMS) | 3MS | 4MS |
| ΔFF (%) | Cz, 60 Ω/sq | ~2.4 | — | ~0.5 | — | — |
| compared to | Cz, 73 Ω/sq | — | ~5.1 | ~1.8 | ~0.3 | — |
| SiNx | mc, 45 Ω/sq | — | — | ~0.8 | — | ~0.0 |
| | mc, 55 Ω/sq | — | — | ~0.7 | — | — |

TABLE 21
Change in Efficiency

| Cell | | | | Mixture | | |
|---|---|---|---|---|---|---|
| parameter | Wafer/emitter | MS | 2MS | (PDMS) | 3MS | 4MS |
| Δη (%) | Cz, 60 Ω/sq | ~0.77 | — | ~0.47 | — | — |
| compared to | Cz, 73 Ω/sq | — | ~1.37 | ~0.56 | ~0.17 | — |
| SiNx | mc, 45 Ω/sq | — | — | ~0.46 | — | ~0.20 |
| | mc, 55 Ω/sq | — | — | ~0.56 | — | — |

TABLE 22
Deposition rate and NH3 dilution ratio

| | | | Mixture | | | |
|---|---|---|---|---|---|---|
| | MS | 2MS | (PDMS) | 3MS | 4MS | SiH4 |
| Dep. Rate | ~2.5 | ~1.4 | ~1.9 | ~0.9 | ~1.0 | ~3.3 |
| (A/s) | | | | | | |
| NH3/gas | 23 | 80 | 10 | 227 | 32 | 6 |
| ratio | | | | | | |

### Example 12

Silicon solar cells were prepared with SiCxNy front-side passivation and anti-reflection coatings obtained by PE-CVD of trimethylsilane (3MS).

Table 23 provides the cell parameters obtained following illumination of the solar cells, which parameters are graphed in FIGS. 22a-f.

TABLE 23
Post-illumination solar cell parameters

| | light- | | | | | | |
|---|---|---|---|---|---|---|---|
| | illumina- | | Jsc | | | R | R |
| Wafer | tion | | (mA/ | FF | Eff | shunt | series |
| ID | Time (hr) | Voc (V) | cm2) | (%) | (%) | (Ohm) | (Ohm) |
| 3MS + Ar | 0 | 0.6263 | 34.08 | 75.07 | 16.02 | 19.2 | 0.01043 |
| (A) | 5 | 0.6263 | 34.08 | 75.07 | 16.02 | 19.2 | 0.01043 |
| | 17 | 0.6209 | 33.71 | 75.51 | 15.81 | 13.6 | 0.00924 |
| | 46 | 0.6212 | 33.37 | 74.70 | 15.49 | 14.5 | 0.01070 |
| | 70 | 0.6204 | 33.66 | 74.38 | 15.53 | 23.5 | 0.01116 |
| | 94 | 0.6223 | 33.80 | 74.70 | 15.70 | 24.0 | 0.01020 |
| 3MS + Ar | 0 | 0.6250 | 33.91 | 76.28 | 16.16 | 20.5 | 0.00860 |
| (B) | 5 | 0.6218 | 33.61 | 75.90 | 15.86 | 19.9 | 0.00910 |
| | 17 | 0.6213 | 33.82 | 76.15 | 16.00 | 21.2 | 0.00901 |
| | 46 | 0.6222 | 33.43 | 76.20 | 15.84 | 17.6 | 0.00885 |
| | 70 | 0.6245 | 33.76 | 75.79 | 15.98 | 11.9 | 0.00938 |
| | 94 | 0.6242 | 33.91 | 76.10 | 16.11 | 23.7 | 0.00881 |
| 3MS | 0 | 0.6252 | 33.70 | 75.66 | 15.94 | 14.0 | 0.00932 |
| (C) | 5 | 0.6227 | 33.40 | 75.33 | 15.67 | 16.5 | 0.00951 |
| | 17 | 0.6225 | 33.52 | 75.16 | 15.68 | 13.7 | 0.01001 |
| | 46 | 0.6237 | 33.13 | 75.40 | 15.58 | 16.8 | 0.00968 |
| | 70 | 0.6253 | 33.51 | 74.90 | 15.70 | 24.2 | 0.00983 |
| | 94 | 0.6254 | 33.66 | 74.90 | 15.77 | 15.3 | 0.01010 |
| SiN (D) | 0 | 0.6296 | 34.27 | 75.37 | 16.26 | 5.2 | 0.01024 |
| | 5 | 0.6188 | 33.63 | 75.03 | 15.61 | 14.9 | 0.01000 |
| | 17 | 0.6174 | 33.47 | 74.82 | 15.46 | 17.8 | 0.01043 |
| | 46 | 0.6189 | 33.11 | 74.10 | 15.18 | 10.2 | 0.01150 |
| | 70 | 0.6193 | 33.48 | 74.74 | 15.50 | 18.7 | 0.01029 |
| | 94 | 0.6223 | 33.65 | 74.95 | 15.69 | 39.2 | 0.00980 |
| SiN (E) | 0 | 0.6297 | 33.91 | 76.77 | 16.39 | 13.5 | 0.00761 |
| | 5 | 0.6191 | 33.08 | 76.6 | 15.68 | 8.7 | 0.00774 |
| | 17 | 0.6133 | 32.54 | 76.55 | 15.28 | 18.2 | 0.00791 |
| | 46 | 0.6152 | 32.42 | 76.1 | 15.18 | 15.6 | 0.00827 |
| | 70 | 0.6147 | 32.52 | 76.09 | 15.21 | 20.2 | 0.00851 |
| | 94 | 0.615 | 32.57 | 76.8 | 15.39 | 30.3 | 0.00695 |

### Example 13

Silicon carbonitride antireflective coatings were deposited on amorphous silicon wafers from organosilane sources to study the effect of carbon concentration on the resulting ARC.

Table 24 provides a comparison of carbon content in the SiCxNy films prepared with different processes, the film density and the relative passivation performance (Voc) for various films. From the table, it can be seen that a lower carbon concentration provides for a higher mass density of the prepared film, and also provides better passivation characteristics (less relative Voc loss).

TABLE 24
Carbon content in SiCxNy films vs. passivation performance
(Voc) vs. mass density

| ARC | SiNx | SiCN1 | SiCN2 | SiCN3 |
|---|---|---|---|---|
| [C] content in | 0 | 7 | 16 | 23 |
| the film (%) | | | | |
| Relative Voc | 0 | −0.85 | −2.65 | −9.3 |
| (mV) | | | | |
| Mass density | 2.8-2.9 | 2.88 | 2.5-2.7 | 2.43 |
| (g/cc) | | | | |

The carbon and hydrogen concentrations of a number of ARCs were also measured and compared, the results being found in FIG. 23. From the figure, it can be seen that the hydrogen concentration in the coating is reduced as the carbon concentration lowered.

### Example 14

Solar cells were prepared on monocrystalline Cz—Si wafers, the SiCN ARCs being deposited by low frequency direct PECVD or dual mode (RF+MW) PECVD. Various ratios of silane and methane were deposited to give varying concentrations of carbon in the ARC. Deposition information and results are provided in Table 25.

TABLE 25

| | CH4/SiH4 | Density | [C] | [N] | [O] | [Si] |
|---|---|---|---|---|---|---|
| PECVD | ratio | (g/cm³) | at. % | at. % | at. % | at. % |
| Dual mode | 0 | 2.54 | 0.01 | 60.9 | 0.1 | 39 |
| Dual mode | 0.19 | 2.76 | 3.7 | 57.8 | 0.06 | 38.5 |
| Dual mode | 0.38 | 2.65 | 6.7 | 55.4 | 0.08 | 37.8 |
| Dual mode | 0.57 | 2.55 | 9.4 | 53.5 | 0.05 | 37 |
| Dual mode | 0.94 | 2.65 | 13.4 | 50.4 | 0.09 | 36.1 |
| Dual mode | 1.89 | 2.65 | 20.7 | 44.6 | 0.04 | 34.7 |
| Low freq. | 0.94 | N/A | 4.8 | 57.3 | 0.26 | 37.6 |
| direct | | | | | | |
| Low freq. | 0.4 | N/A | 2.5 | 58.6 | 0.29 | 38.6 |
| direct | | | | | | |

### Example 15

Various SiN and SiCN films were deposited on Si—Cz wafers to study the effect of carbon concentration on the refractive index of the resulting film, along with the lifetime measurements pre- and post-rapid thermal anneal (RTA).

The SiN and SiCN films were deposited using silane, methane and ammonia gases in varying ratios. All depositions were carried out at a RF power of 300 W, with a deposition time of 55 seconds. The flows of silane and ammonia were maintained at 53 and 123 sccm, respectively, and the flow of methane was varied as set out in the Table 26. The table also provides further process characteristics, along with the characterization of the obtained films. The refractive index and lifetime measurements given in Table 26 are displayed graphically in FIGS. 24 and 25.

TABLE 26
Deposition parameters and post deposition analysis

| | | Total | | | | Refractive | | | Post RTA |
|---|---|---|---|---|---|---|---|---|---|
| CH4 | Gas | gas | Substrate | Vbias | Thickness | Index | Deposition | Life time | Life time |
| (sccm) | Ratio | (sccm) | Temp (° C.) | (V) | (A) | @ 630 nm | Rate | (us) | (us) |
| 0 | 0.00 | 176 | 310 | 225 | 776.0 | 2.055 | 14.1 | 504 | 411 |
| 0 | 0.00 | 176 | 309 | 223 | 807.0 | 2.054 | 14.7 | 506 | 404 |
| 10 | 0.19 | 186 | 312 | 210 | 776.0 | 2.064 | 14.1 | 420 | 198 |
| 10 | 0.19 | 186 | 304 | 208 | 774.0 | 2.065 | 14.1 | 428 | 196 |
| 20 | 0.38 | 196 | 302 | 198 | 756.0 | 2.066 | 13.7 | 610 | 450 |
| 20 | 0.38 | 196 | 297 | 196 | 786.0 | 2.067 | 14.3 | 626 | 476 |
| 30 | 0.57 | 206 | 298 | 192 | 788.0 | 2.066 | 14.3 | 445 | 255 |
| 30 | 0.57 | 206 | 293 | 190 | 785.0 | 2.069 | 14.3 | 439 | 267 |
| 50 | 0.94 | 226 | 308 | 180 | 722.0 | 2.07 | 13.1 | 288 | 143 |
| 50 | 0.94 | 226 | 294 | 178 | 747.0 | 2.071 | 13.6 | 270 | 144 |
| 100 | 1.89 | 276 | 299 | 166 | 717.0 | 2.089 | 13.0 | 263 | 196 |
| 100 | 1.89 | 276 | 306 | 165 | 776.0 | 2.076 | 14.1 | 267 | 194 |

### Example 16

To study the LID characteristics in terms of the precursor used, the wafer stock was fixed and comparison was made between SiCN films made from methylsilane gases and silane plus methane.

Solar cells with SiCN films deposited with SiH₄ and CH₄ precursors (identified as SiCN*) were investigated. The substrate used had a bulk resistivity of about 3 (cm and an emitter sheet resistance of about 52 Ohm/sq. Results of LID losses are plotted in FIGS. 26 and 27, and are compared with reference SiN—SiH4 based film and SiCN film prepare from other precursors. The SiCN* group, in terms of LID losses, falls between methylsilane based SiCN films, and reference SiN films. The carbon presence in the SiCN* film is thus reducing the LID effect, but to a lesser extent than with SiCN films prepared from methylsilanes.

### Example 17

Solar cells were prepared with 5″ (149 cm²) monocrystalline 2.1 Ω·cm Cz—Si wafers with 60 Ohm/sq n+POCL emitters. The front contacts of the solar cell were formed with a commercially available silver paste (e.g. Five Star 173B).

Cells were made with single layer SiCN ARCs prepared from a liquid precursor (4MS) or a solid precursor (PDMS), and a double layer SiCN ARC prepared from liquid (4MS) and solid (PDMS) precursors. A separate cell was prepared with a SiH₄-based SiNx coatings for comparison purposes.

The depositions conditions for the various cells are provided in Table 27, and the cell measurements are shown in FIGS. 28 a-d.

TABLE 27
Deposition conditions

| | 4MS, | | | | | |
|---|---|---|---|---|---|---|
| | PDMS | | | | | Thick- |
| | or SiH4 | NH3 | Temp | Pressure | Power | ness |
| ARC | (sccm) | (sccm) | (° C.) | (Torr) | (W) | (nm) |
| SiNx | 300 | 3000 | 425 | 2 | 100 | 78 |
| SiCN | 500/300 | 3750/3750 | 475 | 2 | 250 | 30/50 |
| (4MS/PDMS) | | | | | | |
| SiCN | 500 | 3375 | 475 | 2 | 250 | 80 |
| (4MS:3375 | | | | | | |
| sccm) | | | | | | |
| SiCN | 500 | 3750 | 475 | 2 | 250 | 80 |
| (4MS:3750 | | | | | | |
| sccm) | | | | | | |
| SiCN (PDMS) | 300 | 3750 | 475 | 2 | 250 | 80 |

### Example 18

Solar cells were prepared with 5″ (149 cm²) monocrystalline 2 Ω·cm Cz—Si wafers with 60 Ohm/sq n+POCL emitters. The front contacts of the solar cell were formed with a commercially available silver paste (e.g. Five Star S546D).

Cells were made with single layer SiCN ARCs prepared from a liquid precursor (4MS), and a double layer SiCN ARC prepared from liquid (4MS) and solid (PDMS) precursors. A separate cell was prepared with a SiH₄-based SiNx coatings for comparison purposes.

The depositions conditions for the various cells are provided in Table 28, and the cell measurements are shown in FIGS. 29a-d.

The emitter saturation current (Joe) of the solar cells prepared with the SiCN (LP) and SiNx ARCs were measured before and after the firing step that is part of the solar cell making process. The results of these measurements are provided in

FIG. 31e. From the figure, it can be seen that the Joe (LP)<Joe (SiNx) when as deposited, but that the Joe (LP)>Joe (SiNx) after firing. Without being bound by theory, it is believed that this result indicates that the LP layer alone does not provide sufficient hydrogen during firing to achieve optimal passivation.

TABLE 28
Deposition conditions

| | 4MS, | | | | | |
|---|---|---|---|---|---|---|
| | PDMS | | | Pres- | | Thick- |
| | or SiH4 | NH3 | Temp | sure | Power | ness |
| ARC | (sccm) | (sccm) | (° C.) | (Torr) | (W) | (nm) |
| SiNx | 300 | 3000 | 425 | 2 | 100 | 78 |
| SiCN | 500/300 | 4500/3750 | 500 | 2 | 250 | 20/60 |
| (4MS/PDMS) | | | | | | |
| SiCN | 500 | 4000 | 500 | 2 | 250 | 80 |
| (4MS:4000 | | | | | | |
| sccm) | | | | | | |
| SiCN | 500 | 4250 | 500 | 2 | 250 | 80 |
| (4MS:4250 | | | | | | |
| sccm) | | | | | | |
| SiCN | 500 | 4500 | 500 | 2 | 250 | 80 |
| (4MS:4500 | | | | | | |
| sccm) | | | | | | |

### Example 19

Solar cells were prepared with 5″ (149 cm²) monocrystalline 1.8 Ω·cm Cz—Si wafers with 60 Ohm/sq n+POCL emitters. The front contacts of the solar cell were formed with a commercially available silver paste (Dupont).

Cells were made with single layer SiCN ARCs prepared from a liquid precursor (4MS) or a solid precursor (PDMS), or with double layer SiCN ARC prepared from liquid (4MS) and solid (PDMS) precursors, or from silane and a liquid precursor (4MS). A separate cell was prepared with a SiH₄-based SiNx coatings for comparison purposes.

The depositions conditions for the various cells are provided in Table 29, and the cell measurements are shown in FIGS. 30 a-d.

TABLE 29
Deposition conditions

| | 4MS, PDMS | | | | | | |
|---|---|---|---|---|---|---|---|
| | or SiH4 | NH3 | Temp | Pressure | Power | Refractive | Thickness |
| ARC | (sccm) | (sccm) | (° C.) | (Torr) | (W) | Index | (nm) |
| SiNx | 300 | 3000 | 425 | 2 | 100 | 2 | 78 |
| SiCN (4MS) | 500 | 4500 | 500 | 2 | 250 | 1.95 | 80 |
| SiCN (4MS/ | 500/300 | 4500/3750 | 500 | 2 | 250 | 1.96 | 20/60 |
| PDMS) | | | | | | | |
| SiCN | 300 | 3750 | 475 | 2 | 250 | 1.95 | 80 |
| (PDMS) | | | | | | | |
| SiCN | 100/400 | 4500 | 475 | 2 | 250 | 1.95 | 20 |
| (SiH4 + | 500 | | | | | | 60 |
| 4MS) | | | | | | | |

### Example 20

Solar cells were prepared with 6″ monocrystalline Cz—Si wafers with 55 Ohm/sq n+POCL emitters. Cells were made with double layer ARCs prepared from liquid precursors (4MS) and solid precursors (PDMS). Separate cells were prepared with SiH₄-based SiNx coatings for comparison purposes. Front contacts were formed with a commercially available silver paste (Five star), and the peak temperature for contact formation was 760° C.

Six solar cells were prepared for each ARC variation, and the individual results are provided in Table 30. The results are also displayed in FIGS. 31 a-f.

TABLE 30
Double layer ARC solar cell measurements

| | | Jsc | FF | Eff | Rshunt | Rseries |
|---|---|---|---|---|---|---|
| ARC | Voc (V) | (mA/cm2) | (%) | (%) | (Ohmcm2) | (Ohmcm2) |
| SiN | 0.6179 | 34.69 | 75.65 | 16.21 | 1338 | 1.22 |
| | 0.6180 | 34.73 | 75.92 | 16.30 | 1530 | 1.22 |
| | 0.6173 | 34.58 | 75.96 | 16.22 | 1721 | 1.25 |
| | 0.6186 | 34.59 | 76.19 | 16.30 | 1816 | 1.21 |
| | 0.6169 | 34.48 | 75.96 | 16.16 | 1673 | 1.23 |
| | 0.6181 | 33.49 | 74.06 | 15.33 | 1506 | 1.10 |
| Group 1 | 0.6058 | 34.17 | 66.32 | 13.73 | 96 | 1.42 |
| (4MS | 0.6141 | 34.24 | 76.39 | 16.06 | 2151 | 1.23 |
| 20 nm, | 0.6135 | 34.25 | 75.97 | 15.96 | 1458 | 1.25 |
| 1.98 + | 0.6146 | 34.32 | 76.35 | 16.11 | 2079 | 1.23 |
| PDMS | 0.6137 | 34.15 | 76.02 | 15.93 | 2510 | 1.26 |
| 60 nm, 1.98) | 0.6151 | 34.45 | 76.54 | 16.22 | 2725 | 1.21 |
| Group 2 | 0.6155 | 34.75 | 76.12 | 16.28 | 2462 | 1.29 |
| (4MS | 0.6159 | 34.80 | 75.92 | 16.27 | 2868 | 1.35 |
| 30 nm, | 0.6161 | 34.66 | 75.88 | 16.20 | 2772 | 1.28 |
| 1.98 + | 0.6168 | 34.58 | 75.73 | 16.15 | 2390 | 1.32 |
| PDMS | 0.6159 | 34.83 | 75.89 | 16.28 | 2629 | 1.35 |
| 50 nm, 1.98) | 0.6176 | 34.71 | 75.99 | 16.29 | 2940 | 1.31 |
| Group 3 | 0.6146 | 34.24 | 75.99 | 15.99 | 2438 | 1.30 |
| (4MS | 0.6147 | 34.37 | 76.53 | 16.17 | 3250 | 1.22 |
| 20 nm, | 0.6155 | 34.20 | 76.27 | 16.05 | 3155 | 1.21 |
| 2.00 + | 0.6151 | 34.42 | 76.37 | 16.17 | 2390 | 1.23 |
| PDMS | 0.6144 | 34.35 | 76.30 | 16.10 | 3083 | 1.25 |
| 60 nm, 1.98) | 0.6152 | 34.40 | 76.40 | 16.17 | 2796 | 1.24 |
| Group 4 | 0.6143 | 34.48 | 75.98 | 16.09 | 1745 | 1.29 |
| (4MS | 0.6141 | 34.55 | 76.14 | 16.15 | 2103 | 1.32 |
| 30 nm, | 0.6153 | 34.39 | 76.22 | 16.13 | 2223 | 1.25 |
| 2.00 + | 0.6134 | 34.36 | 76.02 | 16.02 | 1649 | 1.29 |
| PDMS | 0.6150 | 34.34 | 76.27 | 16.11 | 2677 | 1.24 |
| 50 nm, 1.98) | | | | | | |

### Example 21

Solar cells (2 bus-bar type) were prepared with 5″ (125×125 mm) monocrystalline Cz—Si wafers with 45 and 60 Ohm/sq n+POCL emitters. Cells were made with a double layer ARC prepared from a liquid precursor (4MS), the carbon concentration in the 2^{nd} layer being greater that the first. Separate cells were prepared with SiH₄-based SiNx coatings for comparison purposes.

The obtained cells were characterized before and after light exposure to asses the LID characteristics of the cells, which results are found in Tables 31 and 32.

TABLE 31
Efficiency and Voc for 60 Ω/sq emitter

| Bulk | | SiNx | | | | SiCxNy (LP/LP) | | | |
|---|---|---|---|---|---|---|---|---|---|
| resistivity | | Eff. | Voc | Jsc | FF | Eff. | Voc | Jsc | FF |
| (Ω · cm) | LID | (%) | (mV) | (mA/cm2) | (%) | (%) | (mV) | (mA/cm2) | (%) |
| 2.48 | Before | 17.61 | 621.6 | 36.23 | 78.2 | 17.56 | 617.4 | 36.37 | 78.2 |
| 2.48 | After | 17.42 | 621.6 | 36.10 | 77.6 | 17.56 | 617.2 | 36.22 | 78.6 |

TABLE 32
Efficiency and Voc for 45 Ω/sq emitter

| Bulk | | SiNx | | | | SiCxNy (LP/LP) | | | |
|---|---|---|---|---|---|---|---|---|---|
| resistivity | | | Voc | Jsc | FF | Eff. | Voc | Jsc | FF |
| (Ω · cm) | LID | Eff.(%) | (mV) | (mA/cm2) | (%) | (%) | (mV) | (mA/cm2) | (%) |
| 2.2 | Before | 17.23 | 612.6 | 35.51 | 79.2 | 17.20 | 612.7 | 35.29 | 79.6 |
| 2.2 | After | 16.98 | 611.0 | 35.13 | 79.1 | 17.03 | 611.7 | 35.09 | 79.4 |

### Example 22

Solar cells (3 bus-bar type) were prepared with 6″ (156×156 mm) monocrystalline Cz—Si wafers with 60 Ohm/sq n+POCL emitters. Cells were made with a single or a double layer ARC prepared from a liquid precursor (4MS). For the double layer ARC, the carbon concentration in the 2^{nd} layer was greater that the first. Separate cells were prepared with SiH₄-based SiNx coatings for comparison purposes.

The obtained cells were characterized before and after light exposure to asses the LID characteristics of the cells, which results are found in Tables 33 and 34.

TABLE 33
Cell measurements for SiN and SiCN (4MS) single layers

| Bulk | | SiNx | | | | SiCxNy (LP) | | | |
|---|---|---|---|---|---|---|---|---|---|
| resistivity | | Eff. | Voc | Jsc | FF | Eff. | Voc | Jsc | FF |
| (Ω · cm) | LID | (%) | (mV) | (mA/cm2) | (%) | (%) | (mV) | (mA/cm2) | (%) |
| 2.62 | Before | 18.10 | 622.1 | 36.83 | 79.0 | 17.88 | 618.9 | 36.56 | 79.0 |
| 2.62 | After | 17.88 | 620.5 | 36.69 | 78.5 | 17.90 | 618.7 | 36.52 | 79.2 |

TABLE 34
Cell measurements for SiN and for SiCN (4MS) double layer

| Bulk | | SiNx | | | | SiCxNy (LP/LP) | | | |
|---|---|---|---|---|---|---|---|---|---|
| resistivity | | Eff. | Voc | Jsc | FF | Eff. | Voc | Jsc | FF |
| (Ω · cm) | LID | (%) | (mV) | (mA/cm2) | (%) | (%) | (mV) | (mA/cm2) | (%) |
| 3.5 | Prior | 18.16 | 626.6 | 36.87 | 78.6 | 18.06 | 622.6 | 36.86 | 78.7 |
| 3.5 | After | 18.16 | 626.3 | 36.72 | 79.0 | 18.16 | 622.6 | 36.83 | 79.2 |

### Example 23

Five groups of solar cells and test wafers were prepared using double layer ARCs of varying composition. A single layer SiN layer was also prepared for comparative purposes. A summary of the variations is provided in Table 35, which table identifies the precursors used for preparing the different layers of the ARCs, along with refractive index and thickness of each respective layer.

TABLE 35

| | precursor 1 | | precursor 2 | |
|---|---|---|---|---|
| Group | (+NH3) | 1^{st} layer | (+NH3) | 2^{nd} layer |
| 1 | SiH4 | n = 2.05, d = 80 nm | na | na |
| 2 | 4MS | n = 1.98, d = 10 nm | SiH4 | n = 2.05, |
| | | | | d = 70 nm |
| 3 | 4MS + CH4 | n = 1.98, d = 10 nm | SiH4 | n = 2.05, |
| | | | | d = 70 nm |
| 4 | 4MS | n = 1.98, d = 20 nm | SiH4 | n = 2.05, |
| | | | | d = 60 nm |
| 5 | SiH4 | n = 2.05, d = 30 nm | 4MS | n = 1.98, |
| | | | | d = 50 nm |

Prior to the depositions, each wafer was subjected to a wet chemical process, i.e. a dip in 5% HF solution for 90s. The experimental deposition conditions are presented in Table 36:

TABLE 36
Deposition conditions

| | Plasma peak | Pressure | gas rate flow 4MS | Temperature |
|---|---|---|---|---|
| Group | power (kW) | (torr) | or SiH₄/NH₃ (sccm) | (° C.) |
| G1 | 2.6 | 1.6 | 320/2300 | 450 |
| G2 | 3.6 & 2.6* | 1.8 & 1.6 | 200/900 & 320/2300 | 450 |
| G3 | 3.6 & 2.6 | 1.8 & 1.6 | 200 + 21/900 & | 450 |
| | | | 320/2300 | |
| G4 | 3.6 & 2.6 | 1.8 & 1.6 | 200/900 & 320/2300 | 450 |
| G5 | 2.6 & 3.6 | 1.6 & 1.8 | 320/2300 & 200/900 | 450 |

*Note: Shown deposition conditions for each layer.

Test wafers were prepared to measure the physical ARC characteristics. These consisted of ARC films as described above deposited on silicon wafers.

Spectroscopic ellipsometry measurements were performed to measure the refractive index (n), absorption coefficient (k), thickness and surface roughness (s) of each ARC. Results are compiled in Table 37 below, and the refractive index and absorption co-efficient curves are plotted in FIG. 32.

TABLE 37
Spectroscopic ellipsometry measurements

| | thickness | | n | k |
|---|---|---|---|---|
| Group # | (nm) | s (nm) | (@630 nm) | (@300 nm) |
| 1 | 102 | 3.4 | 2.04 | 0.030 |
| 2 | 103 | 7.0 | 2.04 | 0.011 |
| 3 | 115 | 8.2 | 1.97 | 0.011 |
| 4 | 106 | 5.6 | 2.02 | 0.000 |
| 5 | 118 | 3.5 | 1.99 | 0.027 |
| 5 | 90 | 4.2 | 1.98 | 0.000 |

Note:
Group 3 - results for single layer of SiCN based on 4MS plus CH₄

The target refractive index was 1.98 for SiCN film and 2.05 for SiN reference at wavelength 630 nm. The absorption of the SiCN films was found to be low: k<0.01 at 300 nm. In the reference SiN film the absorption increased (k<0.03 at 300 nm).

The film surface, for films deposited at a temperature 450° C., was found to be from 3.5-8 nm. Film mass density was found to vary from ˜2.5 to ˜3.0 g/cm³, while the mass density for a single SiN reference film is usually ˜2.5 g/cm³. The mass density results are shown in Table 38.

TABLE 38
Film mass density

| | Group # | | | | | |
|---|---|---|---|---|---|---|
| | 1 | 2 | 3 | 4 | 5 | 5 |
| Density (g/cm³) | 2.54 | 2.99 | 2.54 | 2.76 | 2.55 | 2.76 |

Note:
Group 3 results for single layer of SiCN based on 4MS plus CH₄

The SiCN film composition was measured by Auger technique. The average concentration calculation is compiled in Table 39.

TABLE 39
Auger measurements

| Film | Group | Layer | [C] | [N] | [O] | [Si] |
|---|---|---|---|---|---|---|
| SiCN(4MS) | G5 | top | 10.6 | 54.0 | 1.3 | 34.1 |
| SiCN(4MS) | G5 | top | 9.9 | 55.1 | 1.3 | 33.8 |
| SiCN(4MS) | G4 | bottom | 9.8 | 54.1 | 1.9 | 34.2 |
| SiCN(4MS) | G2 | bottom | 9.8 | 53.9 | 2.0 | 34.3 |
| SiCN(4MS + CH₄)/SiN | G3 | single | 9.6 | 54.9 | 1.7 | 33.8 |
| | | bottom | | | | |
| SiN(SiH₄) | G1 | single | 0.03 | 61.1 | 0.1 | 38.7 |
| SiN(SiH₄) | G5 | bottom | 0.08 | 60.8 | 0.3 | 38.8 |
| SiN(SiH₄) | G5 | bottom | 0.06 | 61.1 | 0.3 | 38.6 |
| SiN(SiH₄) | G4 | top | 0.03 | 60.5 | 0.2 | 39.2 |
| SiN(SiH₄) | G2 | top | 0.02 | 61.1 | 0.2 | 38.7 |

A total 45 solar cells were created in this experiment; five per each group. The cells were prepared on p-type (boron doped) Cz, 5″ pseudo-square wafers with emitter sheet resistances of 72 ohm/sq (SC30) or 45 ohm/sq (SC40). The metallization/firing processes and I-V characterization were done under the same conditions for all groups. The I-V performance of the cells was measured and values obtained (Voc, Jsc, and Eff.) are plotted in FIGS. 33a-c. A fill factor median value of ˜76% was measured for all groups.

The solar cells were illuminated with an array of six 500 W lamps from a distance of about 50 cm, exposing them to a light intensity ˜1 sun and heating to around 48° C. I-V measurements were made with a Solar cells I-V Curve tester from PV Measurements, Inc, model IV16, with solar simulation non-uniformity better than +/−5% over 16×16 cm region.

Solar cells based on the SC30 substrate were found to manifest high losses of electrical performance after exposure to light illumination. These silicon materials have a high oxygen concentration and a bulk resistivity ˜3 Ω·cm.

The Voc, Jsc, Efficiency, and Fill Factor (SC30 only) measurements, during illumination, are plotted in FIGS. 34a-d (SC30) and FIGS. 35a-c (SC40).

From the results, it is seen that the light degradation effect is more visible on cells with the SC30 substrate. Within those groups, the highest loss of relative efficiency is for cell with SiN film (˜7.8%) and the lower for cells with double layer of SiCN 20 nm/SiN 60 nm (˜4.7%). The other tested groups, within SC40 material, show lower losses of performance during LID process (relative efficiency loss ˜1.6%).

### Example 24

Solar cells were prepared with different SiN and SiCN front-side passivation and anti-reflective coatings (ARC). The solar cells were prepared on boron doped p-type CZ (Czochralski) mono-crystalline Si solar cells with 60, 63, 64 or 70 Ohm/sq n+POCL emitters.

The various deposition procedures are set out in Tables 40 and 42. The SiN films were prepared with mixtures of silane, methane and ammonia, the “Hybrid” films were prepared with mixtures of silane, tetramethylsilane (4MS), and ammonia, and the SiCN films were prepared with mixtures of 4MS and ammonia. For the SiCN films, a number of films were prepared as single layers (SL), while others were prepared as double layers (DL) of SiCN films having different characteristics (e.g. chemical composition and refractive index).

In Table 41, the results of chemical analysis (Auger and ERD) of the ARC layers deposited as per the parameters set out in Table 40 are provided, along with the Voc measurements for the solar cells prepared. From the Voc results, it can be seen that use of an ARC prepared by the hybrid process, or an double layer ARC prepared with 4MS, provides a quality of passivation that is lower than, but similar to, that of SiN.

Table 43 tabulates the chemical analysis results (carbon and hydrogen concentration) for the ARCs prepared as per the parameters set out in Table 42. The respective refractive index for each prepared ARC layer is also provided.

From the results summarized in Table 43, the relationship between carbon concentration and refractive index is shown in FIG. 36. From the figure, it can be seen that the ARC prepared with the hybrid process provides a higher refractive index at a lower carbon concentration. For the ARC prepared with 4MS alone, it can be seen that refractive index is somewhat proportional to the carbon concentration.

In FIG. 37, the relationship between the carbon concentration, and the hydrogen concentration, with the refractive index is shown. From the figure, it can be seen that the hybrid process provides for a higher hydrogen concentration in the ARC, compared to a film prepared with 4MS alone, particularly at low carbon concentrations. This relationship is further emphasized in FIG. 38, where it is clear that the hybrid process provides for a higher hydrogen concentration, at similar carbon concentrations, than the ARCs prepared with 4MS alone.

TABLE 40
ARC deposition parameters

| | deposition | Total | Si-vapour Flow | | | | | | | Si-containing |
|---|---|---|---|---|---|---|---|---|---|---|
| | pressure | deposition | (SiH4 or 4MS) | | NH3 flow | Peak power | | Refractive | Deposition | Gas or Gas |
| Film | [Torr] | time [sec] | [sccm] | Gas Ratio | [sccm] | W(kW/kW) | Thickness[A] | Index | Rate [A/s] | mixture |
| SiN | 1.6 | 400 | 320 (SiH4) | 7.2 | 2300 | 2600 | 954 | 2.05 | 2.39 | Silane |
| Hybrid | 1.6 | 443 | (320 SiH4/ | | 2300 | 2600 | 1023 | 2.05 | 2.31 | Silane + 4MS |
| (0.05) | | | 60 4MS mixture) | | | | | | | |
| SiCN | 1.8 | 1000 | 200 4MS (L1)/ | 9 (L1)/ | 1800 (L1)/ | 3600 | 1021 | 1.98 | 1.02 | 4MS 1.92/1.98 |
| (DL) | | | 200 4MS (L2) | 4.5 (L2) | 900 (L2) | | | | | (DL) |
| SiCN | 1.8 | 833 | 200 4MS (L1)/ | 7 (L1)/ | 1400 (L1)/ | 3600 | 1059 | 2.02 | 1.27 | 4MS |
| (DL) | | | 300 4MS (L2) | 3 (L2) | 900 (L2) | | | | | 1.94/2.00 (DL) |

TABLE 41
ARC layer characteristics and solar cell performance

| | Auger test (atomic %) | | | | | | | | |
|---|---|---|---|---|---|---|---|---|---|
| Recipe | C | N | O | Si | [H] ERD | Voc (70 Ω · cm) | Voc (64 Ω · cm) | Voc (63 Ω · cm) | Voc (60 Ω · cm) |
| SiN | 0.0 | 62.0 | 0.2 | 37.8 | ~14 | 627 | 626 | 628 | 616 |
| Hybrid | 4.3 | 58.0 | 0.3 | 37.4 | 16.1 | 623 | 623 | | |
| (0.05) | | | | | | | | | |
| DL 4MS | 5.9 | 58.6 | 1.6 | 33.9 | 11.5 | 617 | 621 | 625 | 603 |
| 1.92/1.98 | | | | | | | | | |
| DL 4MS | 11.8 | 53.6 | 1.1 | 33.5 | 13.7 | | | | |
| 1.92/1.98 | | | | | | | | | |
| DL 4MS | 7.0 | 58.0 | 1.6 | 33.3 | 13.0 | na | 622 | 625 | na |
| 1.94/2.00 | | | | | | | | | |
| DL 4MS | 17.6 | 48.7 | 0.9 | 32.8 | 16.0 | | | | |
| 1.94/2.00 | | | | | | | | | |

TABLE 42
ARC deposition parameters

| | Boat | deposition | Total | Si-vapour | | | Peak | | | | |
|---|---|---|---|---|---|---|---|---|---|---|---|
| | Temp | pressure | deposition | Flow (SiH4 | Gas | NH3 flow | power | Thickness | R.I. @ | Deposition | Si-contain Gas or |
| Film | [° C.] | [Torr] | time [sec] | or 4MS) [sccm]] | Ratio | [sccm] | W(kW/kW) | [A] | 630 nm | Rate [A/s] | Gas mix |
| SiN | 450 | 1.6 | 400 | 320 | 7.2 | 2300 | 2600 | 940 | 2.04 | 2.35 | Silane |
| Hybrid | 450 | 1.6 | 380 | (320 SiH4/240 | | 2300 | 2600 | 888 | 2.11 | 2.34 | Silane + 4MS |
| | | | | 4MS mixture) | | | | | | | |
| SiCN | 425 | 1.8 | 920 | 200 4MS | 4.5 | 900 | 2600 | 1177 | 1.98 | 1.28 | 4MS |
| (SL) | | | | | | | | | | | |
| SiCN | 475 | 1.8 | 900 | 200 4MS | 6.5 | 1300 | 2600 | 964 | 1.97 | 1.07 | 4MS |
| (SL) | | | | | | | | | | | |
| SiCN | 450 | 1.8 | 1200 | 200 4MS | 9 | 1800 | 3600 | 1064 | 1.92 | 0.89 | 4MS |
| (SL) | | | | | | | | | | | |
| SiCN | 450 | 1.8 | 833 | 200 4MS (L1)/ | 7 (L1)/ | 1400 (L1)/ | 3600 | 1059 | 2.02 | 1.27 | 4MS 1.94/2.00 |
| (DL) | | | | 300 4MS (L2) | 3 (L2) | 900 (L2) | | | | | (DL) |
| SiCN | 450 | 1.8 | 1000 | 200 4MS (L1)/ | 9 (L1)/ | 1800 (L1)/ | 3600 | 1115 | 1.97 | 1.12 | 4MS 1.92/1.98 |
| (DL) (1) | | | | 200 4MS (L2) | 4.5(L2) | 900 (L2) | | | | | (DL) |
| SiCN | 450 | 1.8 | 1008 | 400 4MS (L1)/ | 9 (L1)/ | 3600 (L1)/ | 3600 | 1188 | 1.97 | 1.18 | 4MS 1.92/1.98 |
| (DL) (2) | | | | 400 4MS (L2) | 4.5(L2) | 1800 (L2) | | | | | (DL) |

TABLE 43
ARC Characterisation

| | Refractive | | |
|---|---|---|---|
| | Index | [C] Auger | [H] ERD |
| Recipe | @630 nm | (atomic %) | (atomic %) |
| SiN (Silane) | 2.05 | 0.01 | |
| SiN (Silane) | 2.03 | 0.01 | 14.37 |
| Single Layer (4MS) | 1.91 | 6.02 | |
| Single Layer (4MS) | 1.98 | 7.72 | |
| Single Layer (4MS) | 1.98 | 8.58 | |
| Single Layer (4MS) | 1.98 | 9.28 | |
| Single Layer (4MS) | 1.96 | 7.42 | 10.11 |
| Single Layer (4MS) | 1.97 | 6.84 | 11.70 |
| Double Layer (4MS) | 2.00 | 17.40 | 13.63 |
| Double Layer (4MS) | 1.92 | 5.80 | 14.05 |
| Double Layer (4MS) | 1.92 | 5.87 | |
| Double Layer (4MS) | 1.92 | 5.84 | |
| Double Layer (4MS) | 1.92 | 5.78 | |
| Double Layer (4MS) | 1.92 | 6.10 | |
| Double Layer (4MS) | 1.98 | 11.84 | |
| Double Layer (4MS) | 1.98 | 11.48 | |
| Double Layer (4MS) | 1.98 | 11.78 | |
| Double Layer (4MS) | 1.98 | 11.98 | |
| Double Layer (4MS) | 1.94 | 7.04 | 12.99 |
| Double Layer (4MS) | 2.00 | 17.61 | 16.03 |
| Double Layer (4MS) | 1.92 | 5.59 | 11.48 |
| Double Layer (4MS) | 1.98 | 10.86 | 13.73 |
| Double Layer (4MS) | 1.92 | 5.59 | |
| Double Layer (4MS) | 1.98 | 10.80 | |
| Double Layer (4MS) (mod) | 1.92 | 5.48 | |
| Double Layer (4MS) (mod) | 1.98 | 11.61 | |
| Double Layer (4MS) (mod) | 1.92 | 5.41 | |
| Double Layer (4MS) (mod) | 1.98 | 11.56 | |
| Hybrid 0.05 | 2.04 | 4.30 | 16.09 |
| Hybrid 0.1 | 2.09 | 7.60 | 15.93 |
| Hybrid 0.2 | 2.10 | 12.95 | 18.59 |

### Example 25

Four groups of solar cells on boron doped p-type CZ mono-crystalline Si wafers were prepared with SiCN ARCs (two cells per group). Two different cell groups were prepared with double layer SiCN ARCs prepared from 4MS and ammonia, while a further cell group was prepared with a single layer hybrid layer prepared from silane, 4MS, and ammonia. A further cell was prepared with a SiN ARC for comparative purposes.

The I-V characteristics of the as-prepared solar cells were measured and are presented in Table 44.

TABLE 44
Pre-illumination I-V characteristics

| | Voc | Jsc | | | | Rseries | Rshunt |
|---|---|---|---|---|---|---|---|
| ARC | (mV) | (mA/cm²) | FF | Eff (%) | n factor | (Ω · cm²) | (Ω · cm²) |
| SiNx | 624.2 | 36.0 | 0.789 | 17.73 | 1.13 | 0.483 | 4795 |
| | 623.0 | 36.1 | 0.786 | 17.65 | 1.15 | 0.470 | 3677 |
| 4MS/4MS | 614.2 | 34.8 | 0.783 | 16.73 | 1.27 | 0.314 | 15976 |
| (1.92/1.98) | 616.5 | 35.3 | 0.784 | 17.06 | 1.21 | 0.393 | 28454 |
| 4MS/4MS | 617.3 | 35.2 | 0.783 | 17.00 | 1.22 | 0.412 | 7314 |
| (1.94/2.00) | 617.4 | 35.2 | 0.784 | 17.04 | 1.22 | 0.411 | 29148 |
| Hybrid | 623.4 | 36.3 | 0.791 | 17.89 | 1.11 | 0.481 | 7661 |
| (SiH4 + | 622.0 | 36.0 | 0.789 | 17.68 | 1.12 | 0.481 | 10267 |
| 4MS + NH3) | | | | | | | |

The prepared cells were then subject to illumination for 24 hours at a temperature of 40° C., at which point the I-V characteristics were re-measured. The post-illumination measurements are presented in Table 45.

TABLE 45
Post-illumination I-V characteristics

| | Voc | Jsc | | Eff | n | Rseries | Rshunt |
|---|---|---|---|---|---|---|---|
| ARC | (mV) | (mA/cm²) | FF | (%) | factor | (Ω · cm²) | (Ω · cm²) |
| SiNx | 619.8 | 36.0 | 0.786 | 17.54 | 1.14 | 0.492 | 4382 |
| | 619.5 | 36.0 | 0.783 | 17.47 | 1.15 | 0.505 | 3136 |
| 4MS/4MS | 612.0 | 34.9 | 0.781 | 16.67 | 1.25 | 0.341 | 15743 |
| (1.92/1.98) | 613.9 | 35.2 | 0.783 | 16.92 | 1.20 | 0.423 | 28451 |
| 4MS/4MS | 614.0 | 35.2 | 0.782 | 16.89 | 1.20 | 0.426 | 7417 |
| (1.94/2.00) | 614.2 | 35.2 | 0.782 | 16.93 | 1.20 | 0.423 | 29725 |
| Hybrid | 619.5 | 36.3 | 0.789 | 17.75 | 1.11 | 0.508 | 7362 |
| (SiH4 + 4MS + NH3) | 619.0 | 36.0 | 0.788 | 17.55 | 1.11 | 0.508 | 10373 |

The variation in I-V characteristics between the pre- and post-illuminated cells are summarized in Tables 46, 47 and 48 below.

TABLE 46
Efficiency variations due to LID

Efficiency (%) @
Illumination time

| ARC | 0 Hr | 24 Hr | Delta |
|---|---|---|---|
| SiNx | 17.73 | 17.54 | 0.19 |
| | 17.65 | 17.47 | 0.18 |
| Average | | | 0.19 |
| 4MS/4MS | 16.73 | 16.67 | 0.06 |
| (1.92/1.98) | 17.06 | 16.92 | 0.14 |
| Average | | | 0.10 |
| 4MS/4MS | 17.00 | 16.89 | 0.11 |
| (1.94/2.00) | 17.04 | 16.93 | 0.11 |
| Average | | | 0.11 |
| Hybrid | 17.89 | 17.75 | 0.14 |
| | 17.68 | 17.55 | 0.13 |

| | |
|---|---|
| Average | 0.14 |

TABLE 47
Voc variations due to LID

Voc @ Illumination
time

| ARC | 0 Hr | 24 Hr | Delta |
|---|---|---|---|
| SiNx | 624.2 | 619.8 | 4.4 |
| | 623.0 | 619.5 | 3.5 |
| Average | | | 4.0 |
| 4MS/4MS | 614.2 | 612.0 | 2.2 |
| (1.92/1.98) | 616.5 | 613.9 | 2.6 |
| Average | | | 2.4 |
| 4MS/4MS | 617.3 | 614.0 | 3.3 |
| (1.94/2.00) | 617.4 | 614.2 | 3.2 |
| Average | | | 3.2 |
| Hybrid | 623.4 | 619.5 | 3.9 |
| | 622.0 | 619.0 | 3.0 |

| | |
|---|---|
| Average | 3.4 |

TABLE 48
Jsc variations due to LID

Jsc @ Illumination
time

| ARC | 0 Hr | 24 Hr | Delta |
|---|---|---|---|
| SiNx | 36.0 | 36.0 | 0.0 |
| | 36.1 | 36.0 | 0.0 |
| Average | | | 0.0 |
| 4MS/4MS | 34.8 | 34.9 | −0.1 |
| (1.92/1.98) | 35.3 | 35.2 | 0.1 |
| Average | | | 0.0 |
| 4MS/4MS | 35.2 | 35.2 | 0.0 |
| (1.94/2.00) | 35.2 | 35.2 | 0.0 |
| Average | | | 0.0 |
| Hybrid | 36.3 | 36.3 | 0.0 |
| | 36.0 | 36.0 | 0.0 |

| | |
|---|---|
| Average | 0.0 |

### Example 26

SiCxNy front-side passivation and anti-reflection coatings (ARC) on textured CZ (Czochralski) mono-crystalline Si solar cells were deposited, along with a standard SiH₄-based SiNx coatings, on 600hm/sq n+POOL emitter. The coated solar cells were tested for dark I-V measurement vis-à-vis the SiNx coated solar cells.

5″ CZ mono-crystalline silicon solar cells with n-type POOL emitter of 60 Ohm/sq were tested at PV measurement system for dark current-voltage (I-V) characteristics. For reverse saturation current measurement, two bias voltages were selected, namely, −5 V and −12 V.

The parameters of the obtained solar cells are provided in Table 49, while the Dark I-V characteristics are shown in FIG. 39 and Table 50.

The SiCxNy coated solar cells were observed to have advantageous dark I-V characteristics with a lower reverse leakage current compared to SiNx coated solar cells.

Based on dark I-V measurement at reverse bias, the solar cells deposited the SiCxNy passivation and ARC had a lower reverse saturation (leakage) current (about 0.06 A at a negative bias of −12V), by one order of magnitude, than those deposited with SiH₄-based SiNx coatings (about 0.5-0.6 A at a negative bias of −12V).

The lower value of reverse leakage current for SiCxNy deposited solar cells is an advantage in field applications of photovoltaic systems, especially for a reduction in the formation of hot-spot in the module. These characteristics become gain greater importance when the cell is driven into reverse by a solar module that is generating sufficient power to overheat the cell, eventually leading to module degradation.

TABLE 49
Solar cell parameters for SiCN coated and SiN coated cells

| Cell | Area | | Jsc | | | n | Rseries | Rshunt | Voc* |
|---|---|---|---|---|---|---|---|---|---|
| Name | (cm²) | Voc (V) | (mA/cm²) | FF % | Eff (%) | factor | (Ω · cm²) | (Ω · cm²) | Jsc |
| SiCN-4 | 149 | 0.6166 | 36.23 | 77.8 | 17.37 | 0.99 | 0.8872 | 31176 | 22.34 |
| SiCN-2 | 149 | 0.6156 | 36.33 | 77.9 | 17.43 | 0.99 | 0.8903 | 26422 | 22.36 |
| SiN-3 | 149 | 0.6210 | 36.53 | 77.1 | 17.50 | 1.01 | 0.9859 | 2308 | 22.69 |
| SiN-5 | 149 | 0.6204 | 36.39 | 77.0 | 17.39 | 1.00 | 1.0418 | 1962 | 22.58 |

TABLE 50
Reverse saturation current (Irev1 at −5 V, Irev2 at −12 V)

| Cell name | I_{dark} @ −5 V (A) | I_{dark} @ −12 V (A) |
|---|---|---|
| SiCN-4 | 0.026 | 0.066 |
| SiCN-2 | 0.025 | 0.063 |
| SiN-3 | 0.313 | 0.630 |
| SiN-5 | 0.250 | 0.480 |

### Example 27

SEM observations were made for solar cells prepared by firing an Ag-based paste on 60 Ohm/sq SiCN coated and SiN coated Cz—Si emitters.

FIGS. 40a and 40b show cross-sectional SEM pictures which show a formation of a thin glass layer between Ag and a Si emitter. This layer is believed to be a mixture of glass frit and the ARC (SiCxNy for FIG. 40a or SiNx for FIG. 40b). Further SEM images of an SiCxNy coated solar cell and of an SiNx coated solar cell are provided in FIGS. 40c and 40d, respectively.

From the figures, it appears that the layer thickness may depend on the ARC used, i.e., the layer thickness for SiCxNy coated cell appears to be thinner than that of the SiNx coated cell. This may be related to the following redox reaction of Ag paste:

### (1) for SiCxNy Coated Cell:

Ag₂O (in glass)+SiCxNy (film)→Ag+SiO₂ (in glass)+CO₂ (g)+N₂ (g)

### (2) for SiNx Coated Cell:

Ag₂O (in glass)+SiCNx (film)→Ag+SiO₂ (in glass)+N₂ (g)

It may be that the formation of the glass layer (SiOx) is reduced by reaction with carbon for SiCxNy coated cell. The carbon in the SiCxNy film may thus play a role of reducer during the chemical etching of the layer by Ag contact fire-thought.

The formation of Ag crystallites with different size and number above this layer can be observed in FIGS. 40a and 40b. A finer distribution of small Ag precipitates was observed near the Si surface for SiCxNy coated cell. However, a bigger and uneven distribution of Ag particles is observed for the SiNx coated cell.

It is believed that the distribution and size of the Ag crystallites formed at the Si emitter interface affect the quality of the Ohmic contacts with the emitters. A uniform distribution of a large number of small Ag crystallites is believed to be desirable, particularly for shallow emitter contacts, since Ag crystallites overgrown into the emitter may cause junction shunting.

These SEM observations are in line with the solar cell parameters obtained for SiCxNy coated cells in comparison with SiNx coated cells. For SiCxNy coated cell, a one order of magnitude higher Rsh (shunt resistance), better Rs (series resistance) and better FF (Fill Factor) were observed.

The present observations suggest the chemistry of Ag crystallite formation and glass frit during the firing process may be influenced by the nature of the ARC layer on the top of the solar cell, for example the carbon in a SiCxNy ARC.

### Example 28

Ohmic metal-semiconductor contacts were made to both the n-type and p-type sides of SiCxNy solar cells. Silver-based pastes were used on the front of the cell, and Aluminum based pastes were used for the back of the cell.

The printing parameter for the Al and Ag pastes are shown in Tables 51 and 52.

A conventional IR furnace possessing six heating zones and one longer cooling zone was used for the formation of the contacts. The firing profile can be achieved by independently tuning the heating set-point of the six zones, and by changing the belt speed. Table 51 provides a typical firing profile for Cz 6 inch wafers. The burnout temperature is 470° C. during 12 seconds and the peak temperature is 760° C. Graphical representation of the firing profile can be observed in FIG. 41.

TABLE 51
Aluminum paste printing parameters

| Screen | mesh count | | [#/in] | 200 |
|---|---|---|---|---|
| | wire diameter | | [μm] | 25 |
| | Mesh opening | | [μm] | 67 |
| | mesh angle | | [deg.] | 45 |
| | emulsion | | [μm] | 6 |
| | thickness | | | |
| | mesh tension | | [N/cm] | 30~36 |
| | Screen width | | [in × in] | 12 × 12 |
| | Photoplot | | [dpi] | 8,000 |
| | resolution | | | |
| Squeegee | squeegee durometer | | — | 70 |
| | squeegee length | | [in] | 8.6 |
| | Length relative to frame size | | | 63% |
| | (>50%) | | | |
| | overhang over print area | | [mm] | 32.8 |
| | (>5 mm) | | | |
| | overhang over substrate | | [mm] | 31.3 |
| | (>5 mm) | | | |
| | snap off | | [mm] | 1.5~1.8 |
| Printing | print speed | | [mm/sec] | 40 |
| Parameters | | | | |
| | | | [in/sec] | 1.6 |
| | squeegee | (in front of wafer) | [mm] | ~20 |
| | travel | (after end of | [mm] | ~30 |
| | | wafer) | | |
| | | (front + back) | [mm] | ~50 |
| | <60 mm | | | |
| Paste | Product | | — | Ferro 53-101 |
| | Viscosity | | [Pa · s] | 35.58 |
| | Solid content | | [%] | 77.4 |
| | Resistivity | | mOhm/sq | 6.58 |
| | Dryer speed | | [in/min] | 15 |
| Drying | Temperature | (Preheat-Soak- | [deg.] | 265-275-255 |
| parameters | setpoints | Reflow) | | |
| | Dryer length | | [inch] | 65 |
| | Travel time | | [min.] | ~4 |

TABLE 52
Silver paste printing parameters

| Screen | mesh count | | [#/in] | 280 |
|---|---|---|---|---|
| | wire diameter | | [μm] | 25 |
| | Mesh opening | | [μm] | 67 |
| | mesh angle | | [deg.] | 22.5 |
| | emulsion thickness | | [μm] | 20 |
| | Finger count | | — | 65 |
| | Finger line width | | [μm] | 90 |
| | mesh tension | | [N/cm] | 22~25 |
| | Screen width | | [in × in] | 12 × 12 |
| | Photoplot resolution | | [dpi] | 16,000 |
| Squeegee | squeegee durometer | | — | 80 |
| | squeegee length | | [in] | 8.6 |
| | Length relative to frame size | | | 63% |
| | (>50%) | | | |
| | overhang over print area | | [mm] | 32.8 |
| | (>5 mm) | | | |
| | overhang over substrate | | [mm] | 31.3 |
| | (>5 mm) | | | |
| | snap off | | [mm] | 1.2~1.5 |
| Printing | print speed | | [mm/sec] | 25 |
| Parameters | | | [in/sec] | 1.0 |
| | squeegee | (in front of wafer) | [mm] | ~20 |
| | travel | (after end of | [mm] | ~30 |
| | | wafer) | | |
| | | (front + back) | [mm] | ~50 |
| | <60 mm | | | |
| Paste | Product | | — | Five Star |
| | | | S-540 | |
| | Viscosity | | [Pa · s] | 95.2 |
| | Solid content | | [%] | ~85 |
| | Resistivity | | mOhm/sq | 1.41 |
| Drying | Dryer speed | | [in/min] | 15 |
| parameters | Temperature | (Preheat-Soak- | [deg.] | 265-275-255 |
| | setpoints | Reflow) | | |
| | Dryer length | | [inch] | 65 |
| | Travel time | | [min.] | ~4 |

TABLE 53
Firing profile

| | | | | | | Zone | Cooling |
|---|---|---|---|---|---|---|---|
| | Zone 1 | Zone 2 | Zone 3 | Zone 4 | Zone 5 | 6 | zone |
| Length | 60 | 40 | 40 | 40 | 24 | 23 | 170 |
| (cm) | | | | | | | |
| Heating | 575 | 545 | 485 | 485 | 600 | 725 | |
| setpoint | | | | | | | |
| (deg.) | | | | | | | |

| | |
|---|---|
| Belt | 200 inch/minute |
| speed | |

All publications, patents and patent applications cited in this specification are herein incorporated by reference as if each individual publication, patent or patent application were specifically and individually indicated to be incorporated by reference. The citation of any publication is for its disclosure prior to the filing date and should not be construed as an admission that the present invention is not entitled to antedate such publication by virtue of prior invention.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

It must be noted that as used in this specification and the appended claims, the singular forms “a”, “an”, and “the” include plural reference unless the context clearly dictates otherwise. Unless defined otherwise all technical and scientific terms used herein have the same meaning as commonly understood to one of ordinary skill in the art to which this invention belongs.

1-14. (canceled)

15. A solar cell comprising:
a silicon substrate comprising boron, oxygen, and carbon; and
an antireflective and passivation layer comprising at least one silicon carbonitride layer adjacent to the substrate, the at least one silicon carbonitride layer having a carbon concentration of from 1 to 10 at. %, an oxygen concentration of less than 3 at. %, and a hydrogen concentration greater than 10 at. %.

16. The solar cell of claim 15, wherein the hydrogen concentration is greater than 14.5 at. %.

17. The solar cell of claim 15, wherein the at least one silicon carbonitride layer has a silicon concentration greater than 37 at. %.

18. The solar cell of claim 15, wherein the antireflective and passivation layer further comprises a second layer located on the silicon carbonitride layer opposite the silicon substrate, the second layer comprising silicon nitride or silicon carbonitride with a carbon concentration which is lower than the carbon concentration in the at least one silicon carbonitride layer and/or a silicon concentration that is higher than a silicon concentration in the at least one silicon carbonitride layer.

19. The solar cell of claim 15, wherein the antireflective and passivation layer further comprises a second layer located on the silicon carbonitride layer opposite the silicon substrate, the second layer being a hydrogen-containing silicon-based film.

20. The solar cell of claim 15, wherein the antireflective and passivation layer further comprises a second layer located on the silicon carbonitride layer opposite the silicon substrate, the second layer comprising silicon carbide, silicon carbonitride, silicon oxycarbide, or silicon oxycarbonitride, the carbon concentration in the second layer being greater than the carbon concentration in the silicon carbonitride layer.

21. The solar cell of claim 15, wherein the silicon carbonitride layer has a graded carbon concentration with an increasing carbon concentration with increasing distance from the silicon substrate, the silicon carbonitride layer having an average carbon concentration of less than 10 at. % within the first 30 nm adjacent to the silicon substrate.

22. The solar cell of claim 15, wherein the silicon substrate has two major surfaces, the antireflective and passivation layer being adjacent to one or both of the two major surfaces, the concentration of carbon in the silicon substrate being greater at the major surface adjacent to the antireflective and passivation layer than it is at a depth within the silicon substrate equidistant from both major surfaces.

23. The solar cell of claim 15, wherein the solar cell manifests a reduction from original Internal Quantum Efficiency (IQE), at any given wavelength between 400 and 1000 nm, of no greater than about 5% following illumination of the solar cell for 72 hours at about 1000 W/m².

24. A method for preparing a silicon solar cell having a silicon substrate comprising boron, oxygen, and carbon, the method comprising depositing on the silicon substrate an antireflective and passivation layer comprising silicon and carbon and diffusing carbon from the antireflective and passivation layer into the silicon substrate.

25. The method of claim 24, wherein the antireflective and passivation layer further comprises oxygen, nitrogen, or both oxygen and nitrogen.

26. The method of claim 24, wherein the amount of carbon diffused into the silicon substrate is sufficient to reduce formation of boron-oxygen complexes in the silicon substrate following illumination of the silicon substrate at about 1000 W/m².

27. The method of claim 24, wherein the antireflective and passivation layer is deposited by PECVD of a gaseous mixture comprising a) one or more gaseous mono-silicon organosilanes and b) a nitrogen containing gas.

28. The method of claim 27, wherein the one or more gaseous mono-silicon organosilanes is selected from the group consisting of methylsilane, dimethylsilane, trimethylsilane, tetramethylsilane, and combinations thereof.

29. The method of claim 27, wherein the gaseous mixture comprises from 1 to 5 wt. % methylsilane, from 40 to 70 wt. % dimethylsilane, from 1 to 5 wt. % trimethylsilane, from 30 to 70 wt. % hydrogen, and from 5 to 15 wt. % methane.

30. The method of claim 27, wherein the gaseous mixture further comprises gaseous organic di-silicon species.

31. The method of claim 30, wherein the gaseous organic di-silicon species are selected from the group consisting of polydimethylsilane, polycarbomethylsilane, triphenylsilane, nonamethyltrisilazane, and combinations thereof.

32. The method of claim 27, wherein the nitrogen containing gas is NH₃ or N₂.

33. The method of claim 24, wherein the diffusing step is achieved by heating the silicon substrate and the antireflective and passivation layer to a temperature of from about 450° C. to about 1,000° C.

34. The method of claim 24, wherein the heating is maintained for at least one minute.
